(19) United States
(12) Patent Application Publication
(10) Pub. No.: US 2025/0232713 A1
(43) Pub. Date: Jul. 17, 2025

(54) DRIVER CIRCUIT AND SEMICONDUCTOR DEVICE

(71) Applicant: Semiconductor Energy Laboratory Co., Ltd., Atsugi-shi (JP)

(72) Inventors: Atsushi UMEZAKI, Isehara (JP); Kazunori WATANABE, Machida (JP)

(21) Appl. No.: 19/008,707

(22) Filed: Jan. 3, 2025

(30) Foreign Application Priority Data
Jan. 12, 2024 (JP) 2024-003156
Feb. 21, 2024 (JP) 2024-024282
Feb. 28, 2024 (JP) 2024-028509

(51) Int. Cl. G09G 3/32; G09G 3/3266

(52) U.S. Cl. CPC G09G 3/32; G09G 3/3266; G09G 2310/0267; G09G 2330/021

(57) ABSTRACT

To provide a novel semiconductor device. A first terminal of a first transistor is connected to a first terminal of a second transistor, a first terminal of a third transistor, a first terminal of a first capacitor, and a first terminal of a second capacitor; a gate of the first transistor is connected to a second terminal of the first capacitor; a second terminal of the third transistor is connected to a first terminal of a fourth transistor and a gate of the fourth transistor; a gate of the third transistor is connected to a second terminal of the fourth transistor, a first terminal of a fifth transistor, and a second terminal of the second capacitor; and a gate of the fifth transistor is connected to a second terminal of the first transistor or the gate of the first transistor.

### BACKGROUND OF THE INVENTION

### 1. Field of the Invention

One embodiment of the present invention relates to a driver circuit and a semiconductor device.

Note that one embodiment of the present invention is not limited to the above technical field. The technical field of one embodiment of the invention disclosed in this specification and the like relates to an object, a method, a driving method, or a manufacturing method. One embodiment of the present invention relates to a process, a machine, manufacture, or a composition of matter. Specific examples of the technical field of one embodiment of the present invention disclosed in this specification and the like include a semiconductor device, a display apparatus, a light-emitting device, a power storage device, an optical device, an image capturing device, a lighting device, a projecting device, an electrooptical device, a light-receiving device, a detection device, a power source device, a communication device, an information processing device, an arithmetic device, a control device, a memory device, an input device, an output device, an input/output device, a signal processing device, an arithmetic processing device, an electronic computer, an electronic device, a system including any of them, a method for driving any of them, and a method for manufacturing any of them.

### 2. Description of the Related Art

Display apparatuses have been applied to a variety of uses. Usage examples of large-sized display apparatuses include a television device for home use and a public information display (PID) for digital signage. Usage examples of small-sized display apparatuses include portable information terminals such as a smartphone and a tablet terminal and wearable devices such as a virtual reality (VR) device and an augmented reality (AR) device. Furthermore, functions other than a displaying function have been added to display apparatuses, so that the display apparatuses have achieved higher functionality and higher added value. For example, a display apparatus having a touch panel function has been developed.

A circuit for driving a display apparatus has been developed. Patent Document 1 discloses an example of a driver circuit that can be used in a display apparatus.

### REFERENCE

### Patent Document

[Patent Document 1] Japanese Published Patent Application No. 2008-122939

### SUMMARY OF THE INVENTION

An active-matrix display apparatus includes a driver circuit (sometimes referred to as a gate driver) that selects a pixel to which data is to be written and a driver circuit (sometimes referred to as a source driver) that supplies data to the selected pixel.

Along with increases in functionality and added value of display apparatuses, higher functionality and higher added value of driver circuits have also been required. For example, a function of not only sequentially driving a matrix of pixels row by row but also concurrently driving the pixels in all rows has been required.

An object of one embodiment of the present invention is to provide a driver circuit with an increased operating speed or a semiconductor device including the driver circuit. Another object of one embodiment of the present invention is to provide a driver circuit with reduced power consumption or a semiconductor device including the driver circuit. Another object of one embodiment of the present invention is to provide a driver circuit with a reduced footprint or a semiconductor device including the driver circuit. Another object of one embodiment of the present invention is to provide a highly reliable driver circuit or a semiconductor device including the driver circuit. Another object of one embodiment of the present invention is to provide a driver circuit capable of improving the performance of a display apparatus, or a semiconductor device including the driver circuit. Another object of one embodiment of the present invention is to provide a driver circuit capable of improving the performance of an image capturing device, or a semiconductor device including the driver circuit. Another object of one embodiment of the present invention is to provide a novel driver circuit or a semiconductor device including the driver circuit.

Note that the above objects do not preclude the existence of other objects. Those skilled in the art can naturally derive and extract other objects from the description of this specification, the drawings, the claims, and the like. Note that one embodiment of the present invention does not necessarily achieve all of these objects (the above objects and the other objects).

(1)

One embodiment of the present invention is a driver circuit including a first circuit and a second circuit. The first circuit includes a first transistor, a second transistor, and a first capacitor; the second circuit includes a third transistor, a fourth transistor, a fifth transistor, and a second capacitor; a first terminal of the first transistor is electrically connected to a first terminal of the second transistor, a first terminal of the third transistor, a first terminal of the first capacitor, a first terminal of the second capacitor, and a first signal line; a second terminal of the first transistor is electrically connected to a second signal line; a gate of the first transistor is electrically connected to a second terminal of the first capacitor and a first wiring; a second terminal of the second transistor is electrically connected to a second wiring; a gate of the second transistor is electrically connected to a third wiring; a second terminal of the third transistor is electrically connected to a first terminal of the fourth transistor, a gate of the fourth transistor, and a third signal line; a gate of the third transistor is electrically connected to a second terminal of the fourth transistor, a first terminal of the fifth transistor, and a second terminal of the second capacitor; a second terminal of the fifth transistor is electrically connected to a fourth wiring; and a gate of the fifth transistor is electrically connected to the second signal line or the gate of the first transistor.

(2)

In (1), the gate of the fifth transistor may be electrically connected to the second signal line.

(3)

In (1), the gate of the fifth transistor may be electrically connected to the gate of the first transistor.

(4)

In (2), the first circuit may be configured to supply a first potential from the second signal line to the first signal line, and the second circuit may be configured to supply a second potential from the third signal line to the first signal line in a period different from a period in which the first potential is supplied.

(5)

In (3), the first circuit may be configured to supply a first potential from the second signal line to the first signal line, and the second circuit may be configured to supply a second potential from the third signal line to the first signal line in a period different from a period in which the first potential is supplied.

(6)

In any one of (1) to (5), a channel width of the third transistor may be larger than a channel width of the fourth transistor.

(7)

In any one of (1) to (5), a channel width of the first transistor may be larger than a channel width of the fifth transistor.

(8)

In any one of (1) to (5), a width of the third signal line may be larger than a width of the second signal line.

(9)

Another embodiment of the present invention is a semiconductor device including the driver circuit in (4) or (5) and a pixel. The pixel includes a sixth transistor and a functional element; a gate of the sixth transistor is electrically connected to the first signal line; a first terminal of the sixth transistor is electrically connected to the functional element; a second terminal of the sixth transistor is electrically connected to a fourth signal line; and the first potential and the second potential are each capable of turning on the sixth transistor.

(10)

In (9), the functional element may be a liquid crystal element.

(11)

One embodiment of the present invention is a driver circuit including m first circuits (m is an integer greater than or equal to two) and m second circuits. The m first circuits each include a first transistor, a second transistor, and a first capacitor; the m second circuits each include a third transistor, a fourth transistor, a fifth transistor, and a second capacitor; a first terminal of the first transistor is electrically connected to a first terminal of the second transistor, a first terminal of the third transistor, a first terminal of the first capacitor, a first terminal of the second capacitor, and a first signal line; a second terminal of the first transistor is electrically connected to a second signal line; a gate of the first transistor is electrically connected to a second terminal of the first capacitor and a first wiring; a second terminal of the second transistor is electrically connected to a second wiring; a gate of the second transistor is electrically connected to a third wiring; a second terminal of the third transistor is electrically connected to a first terminal of the fourth transistor, a gate of the fourth transistor, and a third signal line; a gate of the third transistor is electrically connected to a second terminal of the fourth transistor, a first terminal of the fifth transistor, and a second terminal of the second capacitor; a second terminal of the fifth transistor is electrically connected to a fourth wiring; a gate of the fifth transistor is electrically connected to the second signal line or the gate of the first transistor; the m first circuits are configured to sequentially supply a first potential from the second signal lines to which the m first circuits are electrically connected to m of the first signal lines to which the m first circuits are electrically connected; and the m second circuits are configured to concurrently supply a second potential from the third signal line to which the m first circuits are electrically connected to the m first signal lines to which the m first circuits are electrically connected, in a period different from a period in which the first potential is sequentially supplied.

(12)

In (11), the gate of the fifth transistor may be electrically connected to the second signal line.

(13)

In (11), the gate of the fifth transistor may be electrically connected to the gate of the first transistor.

(14)

In any one of (11) to (13), a channel width of the third transistor may be larger than a channel width of the fourth transistor.

(15)

In any one of (11) to (13), a channel width of the first transistor may be larger than a channel width of the fifth transistor.

(16)

In any one of (11) to (13), a width of the third signal line may be larger than a width of the second signal line.

(17)

Another embodiment of the present invention is a semiconductor device including the driver circuit in any one of (11) to (13) and m pixels. Them pixels each include a sixth transistor and a functional element; a gate of the sixth transistor is electrically connected to the first signal line; a first terminal of the sixth transistor is electrically connected to the functional element; a second terminal of the sixth transistor is electrically connected to a fourth signal line; and the first potential and the second potential are each capable of turning on the sixth transistor.

(18)

In (17), the functional element may be a liquid crystal element.

According to one embodiment of the present invention, a driver circuit with an increased operating speed or a semiconductor device including the driver circuit can be provided. According to another embodiment of the present invention, a driver circuit with reduced power consumption or a semiconductor device including the driver circuit can be provided. According to another embodiment of the present invention, a driver circuit with a reduced footprint or a semiconductor device including the driver circuit can be provided. According to another embodiment of the present invention, a highly reliable driver circuit or a semiconductor device including the driver circuit can be provided. According to another embodiment of the present invention, a driver circuit capable of improving the performance of a display apparatus, or a semiconductor device including the driver circuit can be provided. According to another embodiment of the present invention, a driver circuit capable of improving the performance of an image capturing device, or a semiconductor device including the driver circuit can be provided. According to another embodiment of the present invention, a novel driver circuit or a semiconductor device including the driver circuit can be provided.

Note that the above effects do not preclude the existence of other effects. Those skilled in the art can naturally derive and extract other effects from the description of this specification, the drawings, the claims, and the like. Note that one embodiment of the present invention does not necessarily have all of these effects (the above effects and the other effects).

### BRIEF DESCRIPTION OF THE DRAWINGS

FIG. 1 is a circuit diagram illustrating a structure example of a driver circuit.

FIGS. 2A and 2B are circuit diagrams each illustrating a structure example of a driver circuit.

FIG. 3 is a timing chart illustrating an operation example of a driver circuit.

FIG. 4 is a circuit diagram illustrating an operation example of a driver circuit.

FIG. 5 is a circuit diagram illustrating an operation example of a driver circuit.

FIG. 6 is a circuit diagram illustrating an operation example of a driver circuit.

FIG. 7 is a circuit diagram illustrating an operation example of a driver circuit.

FIG. 8 is a circuit diagram illustrating an operation example of a driver circuit.

FIG. 9 is a circuit diagram illustrating an operation example of a driver circuit.

FIG. 10 is a circuit diagram illustrating an operation example of a driver circuit.

FIG. 11 is a circuit diagram illustrating an operation example of a driver circuit.

FIG. 12 is a circuit diagram illustrating an operation example of a driver circuit.

FIG. 13 is a circuit diagram illustrating an operation example of a driver circuit.

FIG. 14 is a circuit diagram illustrating a structure example of a driver circuit.

FIG. 15 is a circuit diagram illustrating a structure example of a driver circuit.

FIG. 16 is a circuit diagram illustrating a structure example of a driver circuit.

FIG. 17 is a circuit diagram illustrating a structure example of a driver circuit.

FIG. 18 is a circuit diagram illustrating a structure example of a driver circuit.

FIG. 19A is a block diagram illustrating a structure example of a semiconductor device.

FIG. 19B is a circuit diagram illustrating the structure example of the semiconductor device.

FIG. 20 is a circuit diagram illustrating a structure example of a semiconductor device.

FIGS. 21A to 21C are circuit diagrams illustrating a structure example of a semiconductor device.

FIG. 22 is a circuit diagram illustrating a structure example of a semiconductor device.

FIG. 23 is a timing chart illustrating an operation example of a semiconductor device.

FIG. 24 is a circuit diagram illustrating a structure example of a semiconductor device.

FIG. 25 is a circuit diagram illustrating a structure example of a semiconductor device.

FIG. 26 is a circuit diagram illustrating a structure example of a semiconductor device.

FIG. 27 is a circuit diagram illustrating a structure example of a semiconductor device.

FIG. 28 is a circuit diagram illustrating a structure example of a semiconductor device.

FIGS. 29A and 29B are block diagrams each illustrating a structure example of a semiconductor device.

FIG. 30A is a top view illustrating a structure example of a transistor. FIGS. 30B and 30C are cross-sectional views illustrating the structure example of the transistor.

FIG. 31A is a top view illustrating a structure example of a transistor. FIGS. 31B and 31C are cross-sectional views illustrating the structure example of the transistor.

FIG. 32A is a top view illustrating a structure example of a transistor. FIG. 32B is a cross-sectional view illustrating the structure example of the transistor.

FIG. 33A is a top view illustrating a structure example of a transistor. FIGS. 33B and 33C are cross-sectional views illustrating the structure example of the transistor.

FIG. 34A is a top view illustrating a structure example of a transistor. FIGS. 34B and 34C are cross-sectional views illustrating the structure example of the transistor.

FIGS. 35A to 35D are cross-sectional views illustrating an example of a method for forming a film of a metal oxide.

FIGS. 36A to 36D are cross-sectional views illustrating an example of a method for forming a film of a metal oxide.

FIG. 37 is a top view illustrating a structure example of a semiconductor device.

FIGS. 38A and 38B are cross-sectional views illustrating a structure example of a semiconductor device.

FIG. 39A is a perspective view illustrating a structure example of a display apparatus.

FIGS. 39B to 39F are top views illustrating examples of pixel arrangement.

FIG. 40 is a cross-sectional view illustrating a structure example of a display apparatus.

FIGS. 41A and 41B are cross-sectional views each illustrating a structure example of a display apparatus.

FIGS. 42A and 42B are cross-sectional views each illustrating a structure example of a display apparatus.

FIGS. 43A and 43B are cross-sectional views each illustrating a structure example of a display apparatus.

FIGS. 44A to 44C are cross-sectional views illustrating a structure example of an image capturing device.

FIG. 45 is a perspective view illustrating a structure example of a display apparatus.

FIG. 46 is a cross-sectional view illustrating a structure example of a display apparatus.

FIGS. 47A to 47D illustrate examples of electronic devices.

FIGS. 48A to 48F illustrate examples of electronic devices.

FIGS. 49A to 49G illustrate examples of electronic devices.

FIGS. 50A1 to 50A7 and FIGS. 50B1 to 50B6 each illustrate electrical connection.

FIG. 51 is a circuit diagram illustrating a structure example of a driver circuit.

FIG. 52A is a block diagram illustrating a structure example of a semiconductor device.

FIG. 52B is a circuit diagram illustrating the structure example of the semiconductor device.

FIG. 53 is a top view illustrating a structure example of a semiconductor device.

FIG. 54 is a top view illustrating a structure example of a semiconductor device.

### DETAILED DESCRIPTION OF THE INVENTION

In this specification and the like, a semiconductor device means a device that utilizes semiconductor characteristics, and refers to a circuit including a semiconductor element (e.g., a transistor or a diode), a device including the circuit, and the like. The semiconductor device also means devices that can function by utilizing semiconductor characteristics. For example, an electronic circuit including a semiconductor element, a chip provided with an electronic circuit, an electronic component including a packaged chip, and an electronic device provided with an electronic component are examples of a semiconductor device. For example, a display apparatus, a light-emitting device, a power storage device, an optical device, an image capturing device, a lighting device, a projecting device, an electrooptical device, a light-receiving device, a detection device, a power source device, a communication device, an information processing device, an arithmetic device, a control device, a memory device, an input device, an output device, an input/output device, a signal processing device, an arithmetic processing device, an electronic computer, an electronic device, and the like themselves might be semiconductor devices, or might include semiconductor devices.

Hereinafter, embodiments will be described with reference to the drawings. However, embodiments can be implemented with various modes. Thus, it will be readily understood by those skilled in the art that the embodiments and their details can be modified in various ways without departing from the spirit and scope of the present invention. Thus, the present invention should not be interpreted as being limited to the following description of the embodiments.

In this specification and the like, the structure described in each embodiment can be combined with the structures described in the other embodiments as appropriate to constitute one embodiment of the present invention. Furthermore, in the case where a plurality of structures are described in one embodiment, the structures can be combined as appropriate to constitute one embodiment.

Note that the same portions or portions having similar functions in the structures of the invention are denoted by the same reference numerals in different drawings illustrating the embodiments, and the description of such portions is not repeated in some cases. In drawings, for example, the same hatching pattern is used for portions having similar functions, and the portions are not denoted by specific reference numerals in some cases. Moreover, some components may be omitted in a perspective view, a top view (also referred to as a “plan view”), and the like for easy understanding of the drawings. In drawings, some hidden lines or the like might be omitted. In drawings, a hatching pattern or the like might be omitted.

In the drawings, sizes, layer thicknesses, regions, or the like are sometimes exaggerated for clarity. Thus, the drawings are not limited to the drawings with the illustrated size, aspect ratio, and the like, for example. Note that the drawings are schematics for easy understanding of the present invention, and embodiments of the present invention are not limited to shapes or values shown in the drawings, for example. For example, in the actual manufacturing process, a layer, a resist mask, or the like might be unintentionally reduced in size by treatment such as etching, which is not shown in the drawings in some cases for easy understanding. For example, in the actual circuit operation, a fluctuation in voltage, current, or the like might be caused by noise, difference in timing, or the like, which is not shown in some cases for easy understanding.

In this specification, drawings, and the like, components are classified on the basis of the functions and shown as components independent of each other in some cases. However, it may be difficult to separate components on the basis of the functions, so that one component may be associated with a plurality of functions or several components may be associated with one function. Accordingly, the components presented in this specification, drawings, and the like are not limited to the descriptions thereof and can be described with other terms as appropriate.

In this specification, drawings, and the like, when a plurality of components are denoted by the same reference numerals, and, particularly when they need to be distinguished from each other, identification signs such as “A”, “b”, “_1”, “[n]”, or “[m,n]” is sometimes added to the reference numerals, for example. When matters common to a plurality of components with identification signs are described or they do not need to be distinguished from each other, no identification sign is added in some cases.

In this specification and the like, a “conduction state” or an “on state” of a transistor refers to a state where a source and a drain of the transistor can be regarded as being electrically short-circuited, a state where a current can be made to flow between the source and the drain (or a state where a current can flow therebetween), or the like. The “conduction state” or the “on state” may refer to the state of an n-channel transistor where the voltage between its gate and source is higher than the threshold voltage or the state of a p-channel transistor where the voltage between its gate and source is lower than the threshold voltage, for example. Furthermore, a “non-conduction state”, a “cutoff state”, or an “off state” of a transistor refers to a state where a source and a drain of the transistor can be regarded as being electrically disconnected. For example, the “non-conduction state”, the “cutoff state”, or the “off state” may refer to the state of an n-channel transistor where the voltage between its gate and source is lower than the threshold voltage or the state of a p-channel transistor where the voltage between its gate and source is higher than the threshold voltage.

In this specification and the like, a “gate voltage” refers to the voltage between a gate and a source (with the potential of the source regarded as a reference, unless otherwise specified), a “drain voltage” refers to the voltage between a drain and a source (with the potential of the source regarded as a reference, unless otherwise specified), and a “back gate voltage” refers to the voltage between a back gate and a source (with the potential of the source regarded as a reference, unless otherwise specified) in some cases. In addition, a “drain current” refers to a current flowing between a drain and a source in some cases (unless otherwise specified, the direction from the drain to the source is a positive direction). The expressions “high gate voltage”, “high drain voltage”, “high back gate voltage”, and the like for an n-channel transistor can be replaced with the expressions “low gate voltage”, “low drain voltage”, “low back gate voltage”, and the like for a p-channel transistor, respectively, as appropriate. The expressions “low gate voltage”, “low drain voltage”, “low back gate voltage”, and the like for an n-channel transistor can be replaced with the expressions “high gate voltage”, “high drain voltage”, “high back gate voltage”, and the like for a p-channel transistor, respectively, as appropriate.

In this specification and the like, an “off-state current” of a transistor refers to a drain current of the transistor in an off state unless otherwise specified. Note that an off-state current and a current that flows between a gate and a source or a drain (also referred to as a gate leakage current) are collectively referred to as a leakage current in some times in this specification and the like.

In this specification and the like, one of a source and a drain (also referred to as two input/output terminals) of a transistor may be referred to as a first terminal and the other of the source and the drain of the transistor may be referred to as a second terminal. That is, the transistor includes at least a gate (also referred to as a gate terminal), a first terminal, and a second terminal. One terminal (also referred to as one of a pair of terminals) of a capacitor may be referred to as a first terminal, and the other terminal (also referred to as the other of the pair of terminals) of the capacitor may be referred to as a second terminal. One terminal of a display element may be referred to as a first terminal, and the other terminal of the display element may be referred to as a second terminal. One terminal of a liquid crystal element may be referred to as a first terminal, and the other terminal of the liquid crystal element may be referred to as a second terminal. One terminal of a light-emitting element may be referred to as a first terminal, and the other terminal of the light-emitting element may be referred to as a second terminal. One terminal of a light-receiving element may be referred to as a first terminal, and the other terminal of the light-receiving element may be referred to as a second terminal. One of an anode and a cathode (also referred to as one of a pair of terminals) of a diode may be referred to as a first terminal, and the other of the anode and the cathode (also referred to as the other of the pair of terminals) of the diode may be referred to as a second terminal.

### Embodiment 1

A driver circuit of one embodiment of the present invention will be described with reference to drawings. At least part of the driver circuit of one embodiment of the present invention can be used for a semiconductor device such as a display apparatus or an image capturing device.

### <Structure Example of Driver Circuit>

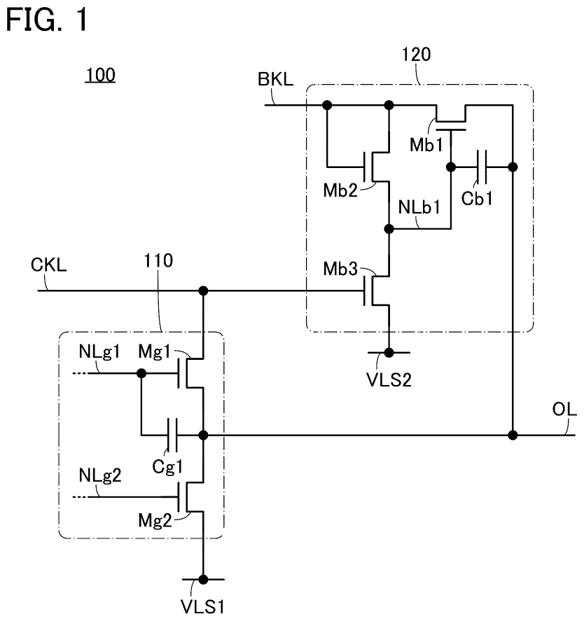

FIG. 1 is a circuit diagram illustrating a driver circuit of one embodiment of the present invention.

As illustrated in FIG. 1, a driver circuit 100 includes a first circuit 110 and a second circuit 120. The first circuit 110 includes a transistor Mg1 and a transistor Mg2. The first circuit 110 may include a capacitor Cg1. The second circuit 120 includes a transistor Mb1, a transistor Mb2, and a transistor Mb3. The second circuit 120 may include a capacitor Cb1.

Note that in the driver circuit 100, the transistors (the transistors Mg1, Mg2, Mb1, Mb2, and Mb3) are n-channel transistors or p-channel transistors. Here, the description is given on the assumption that the transistors are n-channel transistors. An n-channel transistor has a higher on-state current than a p-channel transistor. Thus, the use of n-channel transistors can improve the operation speed of the driver circuit 100. An n-channel transistor needs a smaller channel width than a p-channel transistor in obtaining substantially the same on-state current. Thus, the use of n-channel transistors can reduce the footprint of the driver circuit 100.

In the case where p-channel transistors are used as the transistors, whether a voltage is positive or negative, the magnitude relationship between potentials, and the like in the following description may be read in a different way as appropriate. For example, a “high potential” can be read as a “low potential” as appropriate, and a “low potential” can be read as a “high potential” as appropriate. For example, “increase the potential” can be read as “decrease the potential” as appropriate, and “decrease the potential” can be read as “increase the potential” as appropriate.

As illustrated in FIG. 1, one of a source and a drain of the transistor Mg1 is connected to one of a source and a drain of the transistor Mg2, one of a source and a drain of the transistor Mb1, one terminal of the capacitor Cg1, one terminal of the capacitor Cb1, and a wiring OL. The other of the source and the drain of the transistor Mg1 is connected to a gate of the transistor Mb3 and a wiring CKL. A gate of the transistor Mg1 is connected to the other terminal of the capacitor Cg1 and a wiring NLg1. The other of the source and the drain of the transistor Mg2 is connected to a wiring VLS1. A gate of the transistor Mg2 is connected to a wiring NLg2. The other of the source and the drain of the transistor Mb1 is connected to one of a source and a drain of the transistor Mb2, a gate of the transistor Mb2, and a wiring BKL. A gate of the transistor Mb1 is connected to the other of the source and the drain of the transistor Mb2, one of a source and a drain of the transistor Mb3, and the other terminal of the capacitor Cb1. The other of the source and the drain of the transistor Mb3 is connected to a wiring VLS2.

Note that one embodiment of the present invention includes a structure in which at least one of a gate, a source, and a drain of one or more transistors is connected to nothing or a given wiring. One embodiment of the present invention includes a structure in which nothing or a given signal or potential is input to one or more wirings.

In the driver circuit 100, the first circuit 110 has a function of supplying a given potential from the wiring CKL to the wiring OL. For example, when the transistor Mg1 is in an on state, a potential H (here, a potential capable of turning on a transistor when supplied to a gate of the transistor) supplied to the wiring CKL can be transmitted to the wiring OL through the transistor Mg1. Here, when the wiring NLg1 is brought into a floating state and the capacitor Cg1 functions as a bootstrap capacitor, the voltage between the gate and the source (hereinafter, simply referred to as gate voltage in some cases) of the transistor Mg1 is maintained. Thus, for example, when the potential of the wiring OL increases, the potential of the wiring NLg1 also increases. Accordingly, the potential H can be transmitted without a decrease in potential due to the threshold voltage of the transistor Mg1. In addition, the time it takes for the potential of the wiring OL to reach the potential H (rise time) can be short. Note that the capacitor Cg1 may be parasitic capacitance between the wiring NLg1 and the wiring OL.

The first circuit 110 has a function of supplying a given potential from the wiring VLS1 to the wiring OL. For example, when the transistor Mg2 is in an on state, a potential L (here, a potential capable of turning off a transistor when supplied to a gate of the transistor) supplied to the wiring VLS1 can be transmitted to the wiring OL through the transistor Mg2.

The second circuit 120 has a function of supplying a given potential from the wiring BKL to the wiring OL. For example, a potential H supplied to the wiring BKL can be transmitted to the wiring OL through the transistor Mb1. Here, when a wiring NLb1 is brought into a floating state and the capacitor Cb1 functions as a bootstrap capacitor, the gate voltage of the transistor Mb1 is maintained. Thus, for example, when the potential of the wiring OL increases, the potential of the wiring NLb1 also increases. Accordingly, the potential H can be transmitted without a decrease in potential due to the threshold voltage of the transistor Mb1. In addition, the time it takes for the potential of the wiring OL to reach the potential H (rise time) can be short. Note that the capacitor Cb1 may be parasitic capacitance between the wiring NLb1 and the wiring OL.

Note that the one of the source and the drain of the transistor Mg1 and the one of the source and the drain of the transistor Mg2 can be regarded as corresponding to an output of the first circuit 110. The one of the source and the drain of the transistor Mb1 can be regarded as corresponding to an output of the second circuit 120.

In this specification and the like, the potential L and the potential H are supplied to each wiring for easy understanding; however, the potentials supplied may differ between wirings.

In an operation of the driver circuit 100, supply of the potential H from the wiring CKL to the wiring OL by the first circuit 110, supply of the potential L from the wiring VLS1 to the wiring OL by the first circuit 110, and supply of the potential H from the wiring BKL to the wiring OL by the second circuit 120 are preferably performed in different periods. In other words, the first circuit 110 has a function of supplying the potential H from the wiring CKL to the wiring OL in a period different from a period in which the potential H is supplied from the wiring BKL to the wiring OL and a function of supplying the potential L from the wiring VLS1 to the wiring OL in a period different from the period in which the potential H is supplied from the wiring BKL to the wiring OL, and the second circuit 120 has a function of supplying the potential H from the wiring BKL to the wiring OL in a period different from both the period in which the potential H is supplied from the wiring CKL to the wiring OL and the period in which the potential L is supplied from the wiring VLS1 to the wiring OL.

Here, it is preferable that in the driver circuit 100 of one embodiment of the present invention, a potential L be supplied from the wiring VLS2 to the wiring NLb1 by turning on the transistor Mb3 at the time when the first circuit 110 supplies the potential H from the wiring CKL to the wiring OL. This can prevent the capacitor Cb1 from functioning as a bootstrap capacitor so as not to turn on the transistor Mb1 and not to establish a conduction state between the wiring OL and the wiring BKL.

In the driver circuit 100, the on-state current of each of the transistor Mg1, the transistor Mg2, and the transistor Mb1 is preferably higher than the on-state current of each of the transistor Mb2 and the transistor Mb3. For this reason, the channel width of each of the transistor Mg1, the transistor Mg2, and the transistor Mb1 may be larger than the channel width of each of the transistor Mb2 and the transistor Mb3, for example. The channel length of each of the transistor Mg1, the transistor Mg2, and the transistor Mb1 may be smaller than the channel length of each of the transistor Mb2 and the transistor Mb3.

For example, when the on-state current of each of the transistor Mg1, the transistor Mg2, and the transistor Mb1 is high, the time required for changing the potential of the wiring OL (i.e., rise time and fall time) can be shortened. Consequently, the operation speed can be increased.

For example, the channel width of each of the transistor Mb2 and the transistor Mb3 may be small. In that case, the transistors can have reduced footprints and sizes.

In one embodiment of the present invention, for example, a transistor whose channel formation region includes a single crystal semiconductor, a polycrystalline semiconductor, a microcrystalline semiconductor, or an amorphous semiconductor can be used as the transistors included in the driver circuit 100. Examples of the semiconductor that can be used include compound semiconductors (e.g., silicon germanium or gallium arsenide) and oxide semiconductors in addition to semiconductors including a single element (e.g., silicon or germanium) as a main component.

For example, as the transistors included in the driver circuit 100, a transistor (Si transistor) whose channel formation region includes silicon, a transistor (OS transistor) whose channel formation region includes an oxide semiconductor, or both a Si transistor and an OS transistor may be used.

As the transistors included in the driver circuit 100, any of a variety of transistors can be used. For example, a MOS field-effect transistor, a junction field-effect transistor, a bipolar transistor, or the like can be employed.

As the transistors included in the driver circuit 100, transistors with various structures can be used. For example, transistors with various structures such as a top-gate type (e.g., a planar type and a staggered type), a bottom-gate type (e.g., an inverted planar type and an inverted staggered type), a dual-gate type (a structure in which gates are provided on both sides of (e.g., above and below) a channel formation region), a FIN-type, a TRI-GATE-type, and a gate-all-around-type (GAA-type) structures can be used. For example, a vertical transistor (a transistor whose channel length direction is in the vertical direction (also referred to as a height direction or a direction perpendicular to a formation surface)) can be used.

Note that structure examples of transistors that can be used in the driver circuit 100 will be described later in Embodiment 2.

### Specific Example

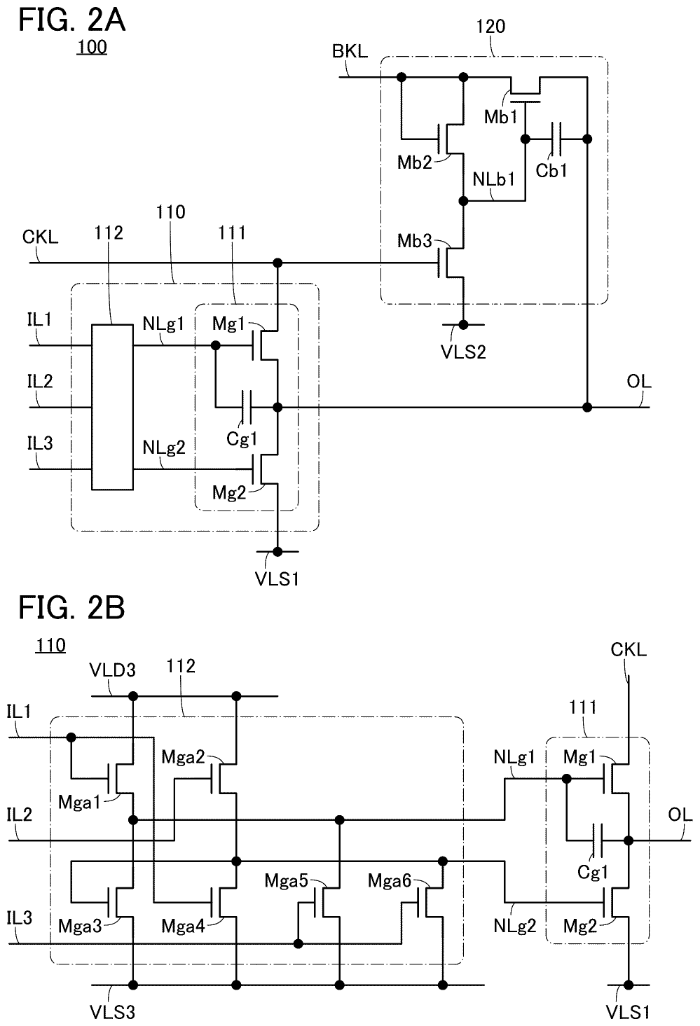

FIGS. 2A and 2B are circuit diagrams each illustrating a specific structure example of the first circuit 110 included in the driver circuit 100.

In the structure example of the first circuit 110 shown in FIG. 2A, a structure in which the transistor Mg1, the transistor Mg2, and the capacitor Cg1 illustrated in FIG. 1 are connected to each other is a buffer portion 111, and a register portion 112 is also shown. In other words, the first circuit 110 includes the buffer portion 111 and the register portion 112, for example.

The register portion 112 has a function of supplying given potentials to the wiring NLg1 and the wiring NLg2 in accordance with the potentials supplied to a wiring IL1, a wiring IL2, and a wiring IL3, and a function of bringing each of the wiring NLg1 and the wiring NLg2 into a floating state in accordance with the potentials supplied to the wiring IL1, the wiring IL2, and the wiring IL3. For example, the register portion 112 has a function of setting the potential of the wiring NLg1 to a potential H and setting the potential of the wiring NLg2 to a potential L in response to supply of a potential H to the wiring IL1. Accordingly, the transistor Mg1 can be turned on and the transistor Mg2 can be turned off. For example, the register portion 112 has a function of setting the potential of the wiring NLg1 to a potential L and setting the potential of the wiring NLg2 to a potential H in response to supply of a potential H to the wiring IL2. Accordingly, the transistor Mg1 can be turned off and the transistor Mg2 can be turned on. For example, the register portion 112 has a function of setting the potential of each of the wiring NLg1 and the wiring NLg2 to the potential L in response to supply of a potential H to the wiring IL3. Accordingly, the transistor Mg1 and the transistor Mg2 can be turned off. For example, the register portion 112 has a function of bringing each of the wiring NLg1 and the wiring NLg2 into a floating state in response to supply of a potential L to each of the wiring IL1, the wiring IL2, and the wiring IL3.

In the structure example of the register portion 112 illustrated in FIG. 2B, a transistor Mga1, a transistor Mga2, a transistor Mga3, a transistor Mga4, a transistor Mga5, and a transistor Mga6 are provided. In other words, the register portion 112 includes the transistor Mga1, the transistor Mga2, the transistor Mga3, the transistor Mga4, the transistor Mga5, and the transistor Mga6, for example.

One of a source and a drain of the transistor Mga1 is connected to one of a source and a drain of the transistor Mga3, one of a source and a drain of the transistor Mga5, and the wiring NLg1. One of a source and a drain of the transistor Mga2 is connected to a gate of the transistor Mga3, one of a source and a drain of the transistor Mga4, one of a source and a drain of the transistor Mga6, and the wiring NLg2. The other of the source and the drain of the transistor Mga1 is connected to the other of the source and the drain of the transistor Mga2 and a wiring VLD3. The other of the source and the drain of the transistor Mga3 is connected to the other of the source and the drain of the transistor Mga4, the other of the source and the drain of the transistor Mga5, the other of the source and the drain of the transistor Mga6, and a wiring VLS3. A gate of the transistor Mga1 is connected to a gate of the transistor Mga4 and the wiring IL1. A gate of the transistor Mga2 is connected to the wiring IL2. A gate of the transistor Mga5 is connected to a gate of the transistor Mga6 and the wiring IL3.

In the register portion 112, for example, when the potential H is supplied to the wiring IL1, the transistor Mga1 and the transistor Mga4 may be turned on, a potential H may be supplied from the wiring VLD3 to the wiring NLg1, and a potential L may be supplied from the wiring VLS3 to the wiring NLg2. In that case, the transistor Mg1 is turned on, and the transistor Mg2 is turned off. For example, when the potential H is supplied to the wiring IL2, the transistor Mga2 may be turned on and a potential H may be supplied from the wiring VLD3 to the wiring NLg2. Furthermore, the transistor Mga3 may be turned on and a potential L may be supplied from the wiring VLS3 to the wiring NLg1. In that case, the transistor Mg1 is turned off, and the transistor Mg2 is turned on. For example, when the potential H is supplied to the wiring IL3, the transistor Mga5 and the transistor Mga6 may be turned on and the potential L may be supplied from the wiring VLS3 to each of the wiring NLg1 and the wiring NLg2. In that case, the transistor Mg1 and the transistor Mg2 are turned off. For example, when the potential L is supplied to each of the wiring IL1, the wiring IL2, and the wiring IL3, the transistors Mga1 to Mga6 may be turned off and the wiring NLg1 and the wiring NLg2 may be brought into a floating state. In that case, the transistor Mg1 and the transistor Mg2 keep an on state or an off state.

### Operation Example

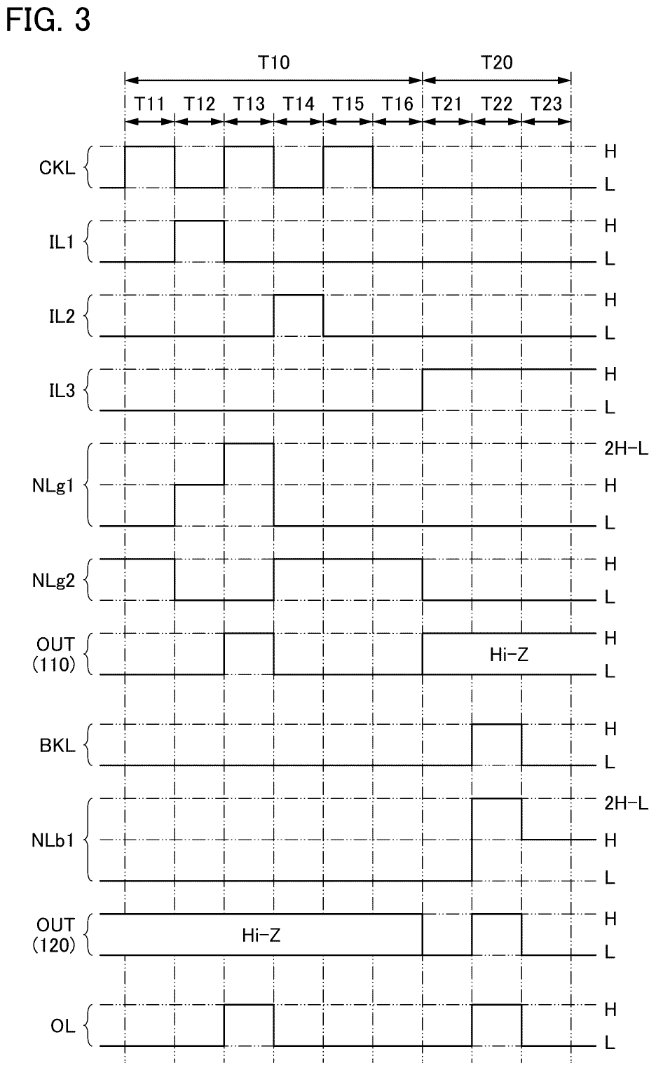

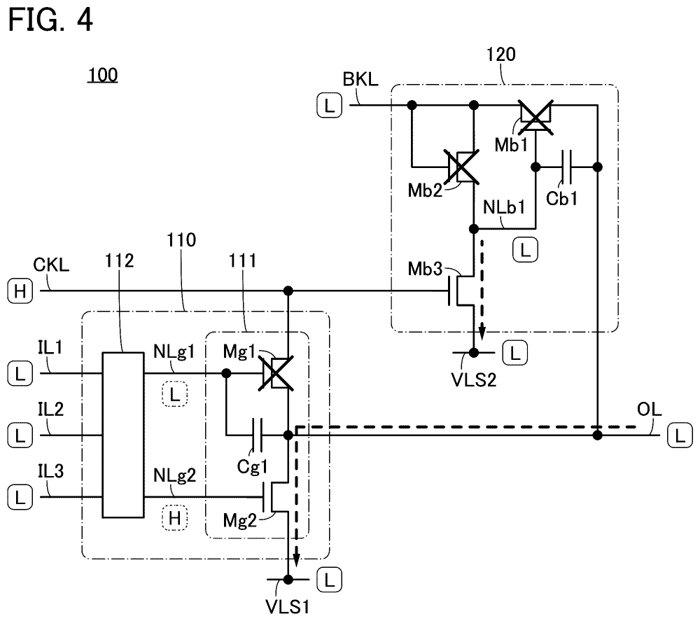

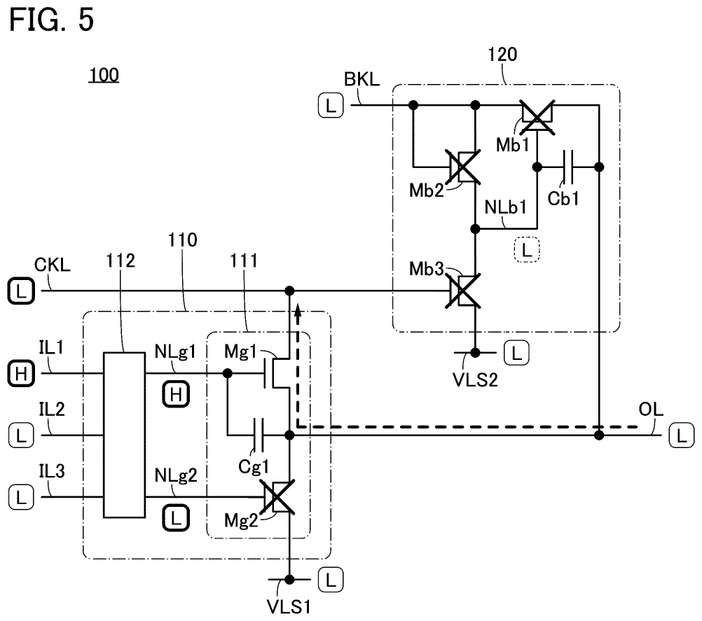

FIG. 3 is a timing chart illustrating an operation example of the driver circuit 100. FIG. 4 to FIG. 13 are circuit diagrams illustrating the operation example of the driver circuit 100. Here, an operation of the driver circuit 100 shown in FIG. 2A is described as an example.

In the driver circuit 100, the wiring CKL and the wiring BKL each function as a signal line. The signals supplied to the wiring CKL and the wiring BKL have a potential L (simply referred to as “L” in some cases) or the potential H (simply referred to as “H” in some cases) higher than the potential L. Here, the difference between the potential H and the potential L is larger than the threshold voltage of a transistor. Note that the potential L may be a ground potential, for example.

The wiring VLS1 and the wiring VLS2 each function as a power supply line. Here, the potential L is supplied to each of the wiring VLS1 and the wiring VLS2.

Note that different potentials may be supplied to the wiring VLS1 and the wiring VLS2. A signal may be supplied to at least one of the wiring VLS1 and the wiring VLS2. That is, at least one of the wiring VLS1 and the wiring VLS2 can also function as a signal line.

In the operation described below, a rise time and a fall time sometimes occur at the time of potential change owing to a load on a wiring (parasitic capacitance and parasitic resistance), for example. Furthermore, for example, two different operations that appear to occur at the same timing do not necessarily occur at exactly the same timing. The operations can be sometimes considered to occur at the same timing even though a signal delay of a wiring or the like causes a slight time lag between the operations, for example.

The periods that are shown with the same length in the timing chart for easy understanding of the description may have different lengths of time.

The timing chart in FIG. 3 shows the potentials supplied to the wiring CKL, the wiring BKL, the wiring IL1, the wiring IL2, and the wiring IL3 in each period of the operation. The timing chart also shows changes in the potentials of the wiring NLg1, the wiring NLg2, and the wiring NLb1. The timing chart also shows the potential H, potential L, and high impedance (denoted as “Hi-Z” in the drawing) for each of the output of the first circuit 110 (denoted as “OUT(110)” in the drawing) and the output of the second circuit 120 (denoted as “OUT(120)” in the drawing). The timing chart also shows a change in the potential of the wiring OL.

Each of FIG. 4 to FIG. 13 shows the potentials of the wiring CKL, the wiring BKL, the wiring IL1, the wiring IL2, the wiring IL3, the wiring VLS1, the wiring VLS2, the wiring NLg1, the wiring NLg2, the wiring NLb1, and the wiring OL at each timing in the operation. A symbol indicating a potential (also referred to as a potential symbol), such as “H” or “L”, surrounded by a line is written near some wirings. Specifically, thick surrounding lines are used to indicate a potential change, and dotted surrounding lines are used to indicate a floating state. Furthermore, a symbol “x” is sometimes superimposed on a transistor in an off state. A dashed arrow indicating the direction in which a current flows (in other words, the direction in which positive electric charge moves) is added along some wirings.

For easy understanding, the influence of parasitic capacitance is not taken into account in some descriptions of a change in potential by capacitive coupling of a capacitor.

In Period T10 (Periods T11 to T16), the first circuit 110 supplies the potential L or the potential H to the wiring OL. In Period T20 (Periods T21 to T23), the second circuit 120 supplies the potential L or the potential H to the wiring OL.

In Period T11, the potential H is supplied to the wiring CKL and the potential L is supplied to the wiring BKL. Thus, the transistor Mb2 is in an off state, and the transistor Mb3 is in an on state. Accordingly, the potential of the wiring NLb1 is the potential L, and the transistor Mb1 is in an off state. The potential L is supplied to each of the wiring IL1, the wiring IL2, and the wiring IL3. Thus, the wiring NLg1 and the wiring NLg2 are each in a floating state. At this time, the potential of the wiring NLg1 is the potential L, and the potential of the wiring NLg2 is the potential H. Thus, the transistor Mg1 is in an off state, and the transistor Mg2 is in an on state. Accordingly, the potential of the wiring OL is the potential L. FIG. 4 illustrates the potentials of the wirings at this time. Note that in the following description, unless otherwise specified, the immediately preceding state is maintained.

In Period T12, the potential L is supplied to the wiring CKL. Then, the transistor Mb3 is turned off, and the wiring NLb1 is brought into a floating state. At this time, the potential of the wiring NLb1 is the potential L, and the transistor Mb1 remains in an off state. The potential H is supplied to the wiring IL1. Accordingly, the potential of the wiring NLg1 becomes the potential H, and the potential of the wiring NLg2 becomes the potential L. As a result, the transistor Mg1 is turned on, and the transistor Mg2 is turned off. At this time, the potential L is supplied to the wiring CKL, so that the potential of the wiring OL remains the potential L. FIG. illustrates the potentials of the wirings at this time.

In Period T13, the potential H is supplied to the wiring CKL. Then, a current flows from the wiring CKL to the wiring OL through the transistor Mg1, and the potential of the wiring OL increases. The potential L is supplied to the wiring IL1. Accordingly, the wiring NLg1 and the wiring NLg2 are brought into a floating state. Thus, when the potential of the wiring OL increases, the state where “the potential H−the potential L” is applied as the gate voltage of the transistor Mg1 (here, the voltage between the gate and the one of the source and the drain of the transistor Mg1) is maintained owing to capacitive coupling of the capacitor Cg1, and the potential of the wiring NLg1 increases as much as the increase in the potential of the wiring OL. Finally, the potential of the wiring NLg1 becomes “2×the potential H−the potential L (2H−L)”, and the potential of the wiring OL becomes the potential H.

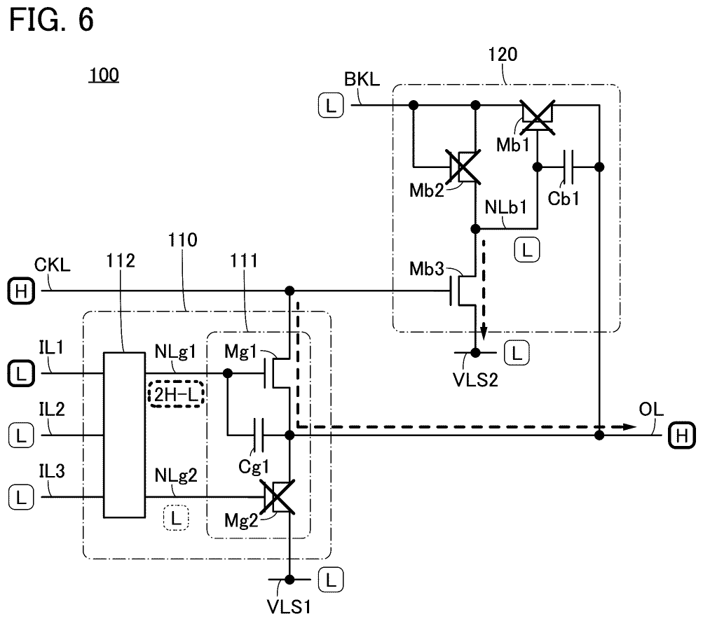

At this time, the transistor Mb3 is turned on, and the potential of the wiring NLb1 becomes the potential L. Thus, the transistor Mb1 can be prevented from being turned on because of an increase in the potential of the wiring NLb1 due to capacitive coupling of the capacitor Cb1. Accordingly, the off state of the transistor Mb1 is maintained, preventing a conduction state from being established between the wiring OL that is supplied with the potential H from the wiring CKL through the transistor Mg1 and the wiring BKL that is supplied with the potential L. FIG. 6 illustrates the potentials of the wirings at this time.

Note that the timing at which the potential of the wiring CKL becomes the potential H is earlier than the timing at which the potential of the wiring OL becomes the potential H, because of a load on the wiring OL. Since such a wiring CKL is connected to the gate of the transistor Mb3, the potential of the wiring OL can become the potential H after the transistor Mb3 is turned on. Thus, the potential of the wiring OL can be prevented from becoming the potential H before the transistor Mb3 is turned on.

Here, the gate capacitance of the transistor Mb3 is preferably small in order that the transistor Mb3 can be turned on before the potential of the wiring OL becomes the potential H. For example, the gate capacitance of the transistor Mb3 is preferably smaller than that of the transistor Mg1. For example, the channel area (i.e., channel length×channel width) of the transistor Mb3 is preferably smaller than that of the transistor Mg1. For example, the channel length of the transistor Mb3 is preferably smaller than that of the transistor Mg1. For example, the channel width of the transistor Mb3 is preferably smaller that of the transistor Mg1. In that case, the operation can be stabilized.

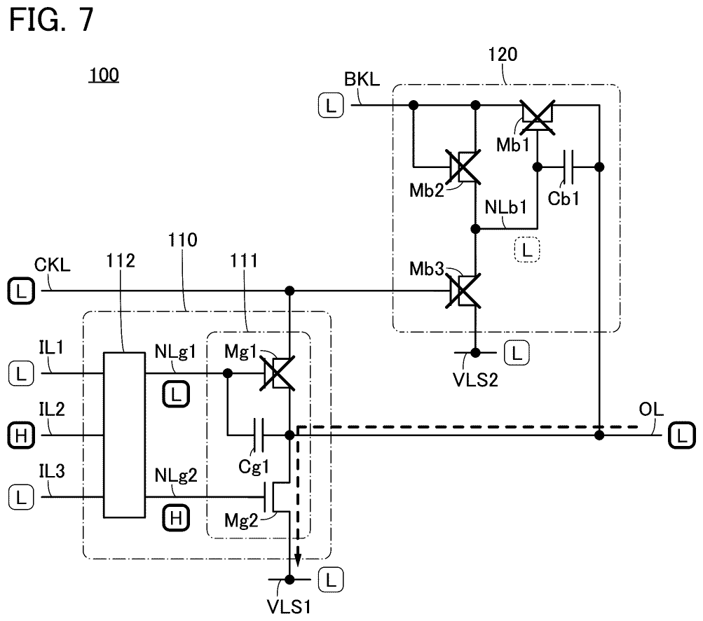

In Period T14, the potential L is supplied to the wiring CKL. Then, the transistor Mb3 is turned off, and the wiring NLb1 is brought into a floating state. At this time, the potential of the wiring NLb1 is the potential L, and the transistor Mb1 remains in an off state. The potential H is supplied to the wiring IL2. Accordingly, the potential of the wiring NLg1 becomes the potential L, and the potential of the wiring NLg2 becomes the potential H. As a result, the transistor Mg1 is turned off, and the transistor Mg2 is turned on. Then, a current flows from the wiring OL to the wiring VLS1 through the transistor Mg2, and the potential of the wiring OL decreases. Accordingly, the potential of the wiring OL becomes the potential L. FIG. 7 illustrates the potentials of the wirings at this time.

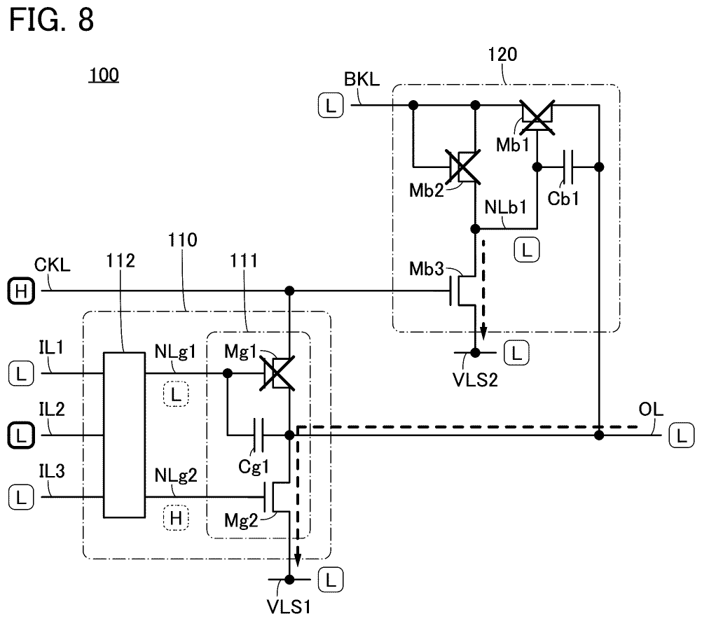

In Period T15, the potential H is supplied to the wiring CKL. Thus, the transistor Mb3 is turned on, and the potential of the wiring NLb1 becomes the potential L. Thus, the transistor Mb1 remains in an off state. The potential L is supplied to the wiring IL2. Accordingly, the wiring NLg1 and the wiring NLg2 are brought into a floating state. Thus, the transistor Mg1 remains in an off state, and the transistor Mg2 remains in an on state. Accordingly, the potential of the wiring OL remains the potential L. FIG. 8 illustrates the potentials of the wirings at this time.

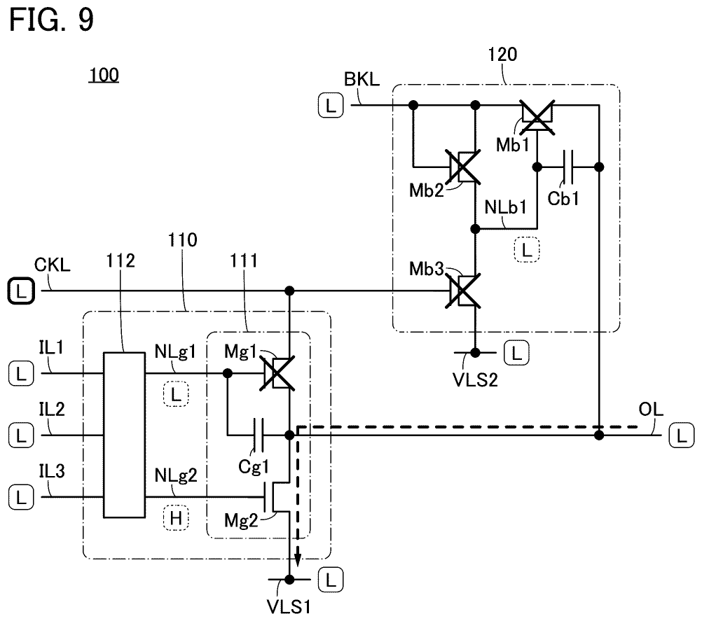

In Period T16, the potential L is supplied to the wiring CKL. Then, the transistor Mb3 is turned off, and the wiring NLb1 is brought into a floating state. At this time, the potential of the wiring NLb1 is the potential L, and the transistor Mb1 remains in an off state. The transistor Mg1 remains in an off state, and the transistor Mg2 remains in an on state. Accordingly, the potential of the wiring OL remains the potential L. FIG. 9 illustrates the potentials of the wirings at this time.

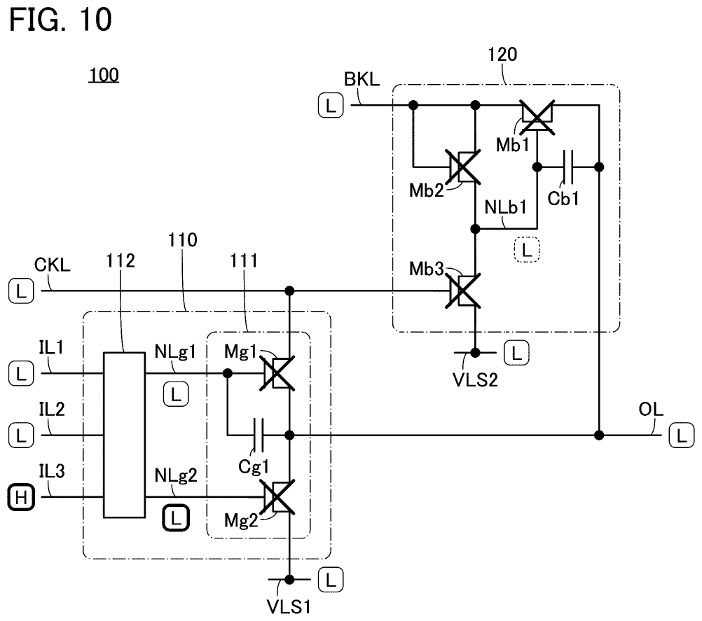

In Period T21, the potential H is supplied to the wiring IL3. Accordingly, the potentials of the wiring NLg1 and the wiring NLg2 each become the potential L. Then, the transistor Mg1 and the transistor Mg2 are turned off, and the wiring OL is brought into a floating state. At this time, the potential of the wiring OL remains the potential L. FIG. 10 illustrates the potentials of the wirings at this time.

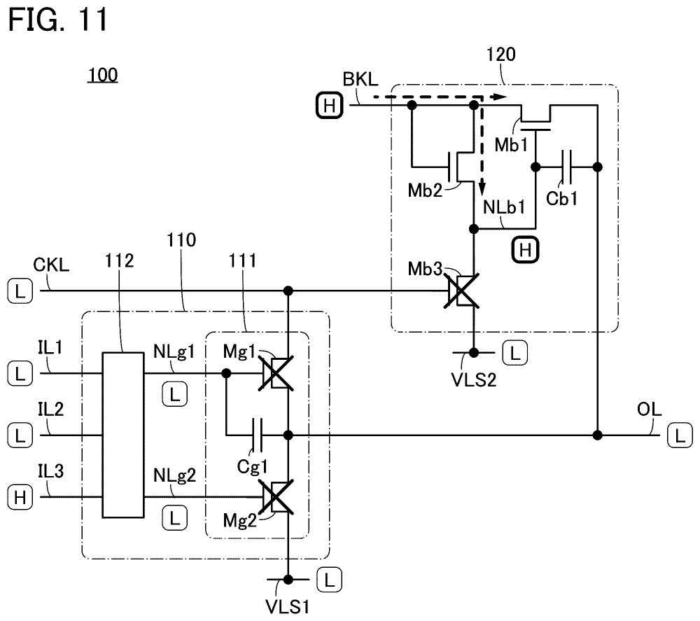

In Period T22, the potential H is supplied to the wiring BKL. Then, a current first flows from the wiring BKL to the wiring NLb1 through the transistor Mb2, and the potential of the wiring NLb1 becomes a potential H. As a result, the transistor Mb1 is turned on. The potential of the wiring NLb1 becomes “the potential H−the threshold voltage of the transistor Mb2”; here, to simplify the description, the threshold voltage of the transistor Mb2 is assumed to be 0 V. FIG. 11 illustrates the potentials of the wirings at this time.

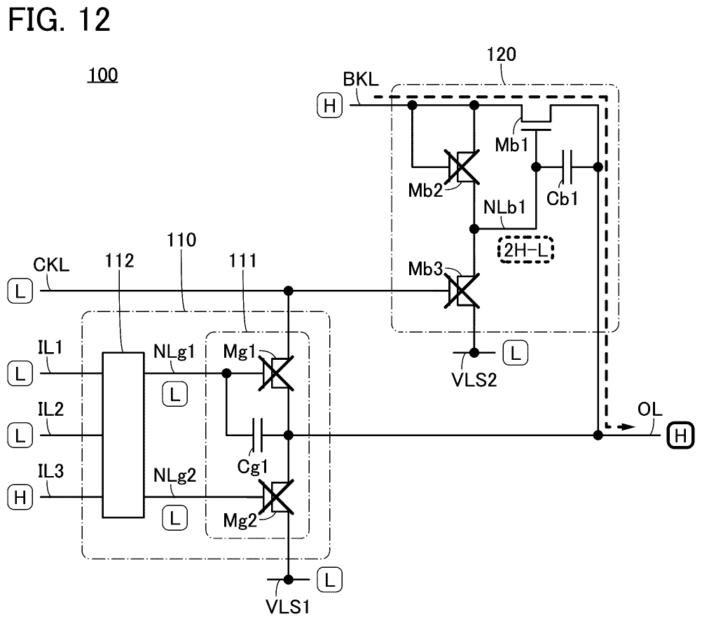

After that, a current flows from the wiring BKL to the wiring OL through the transistor Mb1, and the potential of the wiring OL increases. Here, in the transistor Mb2, no current flows from the other of the source and the drain (i.e., a terminal connected to the wiring NLb1) to the one of the source and the drain (i.e., a terminal connected to the wiring BKL). Accordingly, when the potential of the wiring NLb1 becomes higher than that of the wiring BKL, the wiring NLb1 is brought into a floating state. Thus, when the potential of the wiring OL increases, the state where “the potential H−the potential L” is applied as the gate voltage of the transistor Mb1 (here, the voltage between the gate and the one of the source and the drain of the transistor Mb1) is maintained owing to capacitive coupling of the capacitor Cb1, and the potential of the wiring NLb1 increases as much as the increase in the potential of the wiring OL. Finally, the potential of the wiring NLb1 becomes “2×the potential H−the potential L”, and the potential of the wiring OL becomes the potential H. FIG. 12 illustrates the potentials of the wirings at this time.

Here, the gate capacitance of the transistor Mb2 is preferably small in order that the potential of the wiring NLb1 can become the potential H before the potential of the wiring OL becomes the potential H. For example, the gate capacitance of the transistor Mb2 is preferably smaller than that of the transistor Mb1. For example, the channel area (i.e., channel length×channel width) of the transistor Mb2 is preferably smaller than that of the transistor Mb1. For example, the channel length of the transistor Mb2 is preferably smaller than that of the transistor Mb1. For example, the channel width of the transistor Mb2 is preferably smaller that of the transistor Mb1. In that case, the operation can be stabilized.

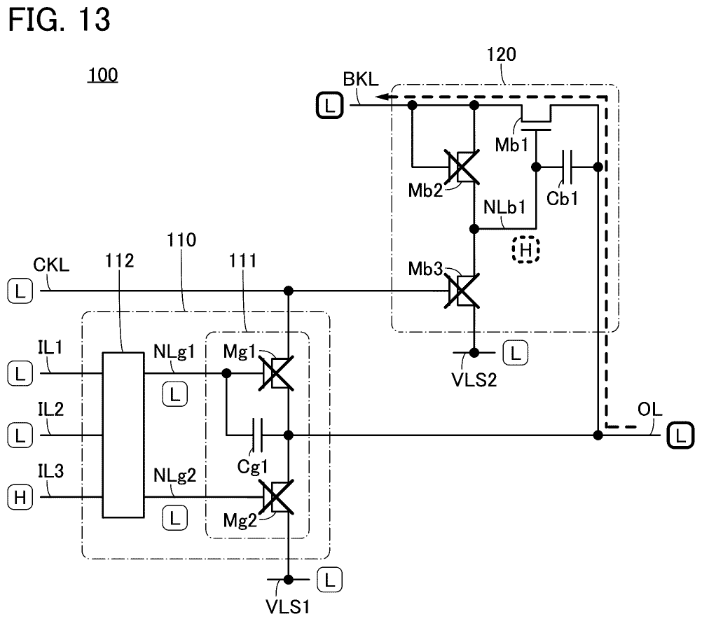

In Period T23, the potential L is supplied to the wiring BKL. Then, a current flows from the wiring OL to the wiring BKL through the transistor Mb1, and the potential of the wiring OL decreases. The potential of the wiring NLb1 also decreases owing to capacitive coupling of the capacitor Cb1. Accordingly, the potential of the wiring NLb1 becomes the potential H, and the potential of the wiring OL becomes the potential L. FIG. 13 illustrates the potentials of the wirings at this time.

Here, the second circuit 120 may be replaced with a structure in which the transistor Mb2, the transistor Mb3, and the capacitor Cb1 are omitted and the gate of the transistor Mb1 is connected to the other of the source and the drain of the transistor Mb1 and the wiring BKL, for example. However, in that case, when the potential H is supplied to the wiring BKL as in the operation in Period T22, the potential of the wiring OL becomes “the potential H− the threshold voltage of the transistor Mb1” because of a voltage drop due to the threshold voltage of the transistor Mb1. That is, in order that the potential of the wiring OL can become the potential H, the wiring BKL needs to be supplied with “the potential H+the threshold voltage of the transistor Mb1”, for example, which would increase power consumption.

In one embodiment of the present invention, the structure of the second circuit 120 makes it possible that the potential H is supplied from the wiring BKL to the wiring OL without a voltage drop due to the threshold voltage of the transistor Mb1 in the operation in Period T22. Accordingly, an increase in power consumption can be inhibited. Moreover, the gate voltage of the transistor Mb1 is maintained, shortening the time it takes for the potential of the wiring OL to reach the potential H (also referred to as rise time). Consequently, the operation speed can be increased.

### <Other Structure Examples of Driver Circuit>

The driver circuit of one embodiment of the present invention is not limited to the above-described structure example.

### Variation Example 1

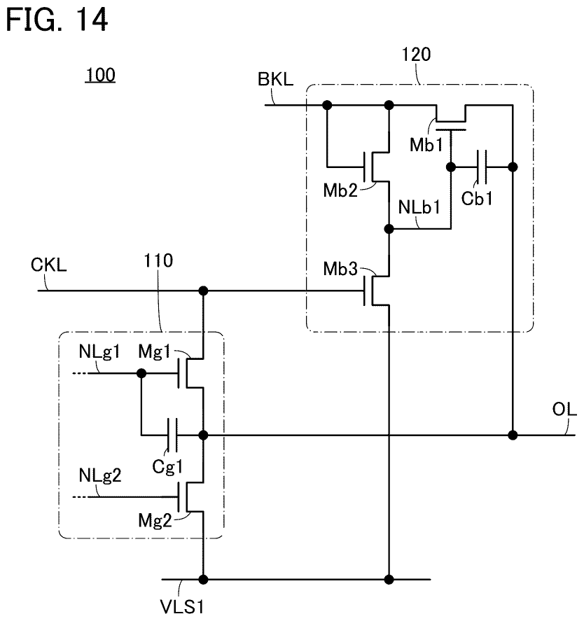

FIG. 14 is a circuit diagram illustrating a variation example of the driver circuit 100. The driver circuit 100 illustrated in FIG. 14 is different from the driver circuit 100 illustrated in FIG. 1 in that the other of the source and the drain of the transistor Mg2 is connected to the other of the source and the drain of the transistor Mb3 and the wiring VLS1.

Employing such a structure can omit the wiring VLS2. That is, the number of wirings can be reduced. Thus, the footprint of the driver circuit 100 can be reduced. Consequently, for example, a display apparatus or the like that includes the driver circuit can have a reduced bezel width.

### Variation Example 2

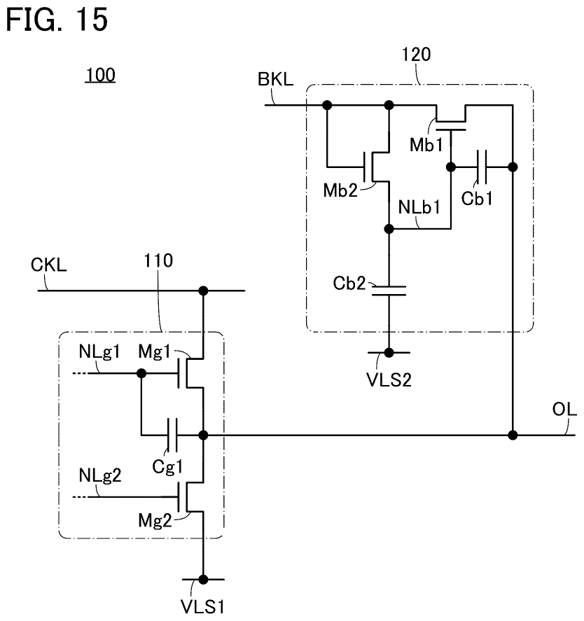

FIG. 15 is a circuit diagram illustrating a variation example of the driver circuit 100. The driver circuit 100 illustrated in FIG. 15 is different from the driver circuit 100 illustrated in FIG. 1 in including a capacitor Cb2 instead of the transistor Mb3 in the second circuit 120. One terminal of the capacitor Cb2 is connected to the gate of the transistor Mb1, the other of the source and the drain of the transistor Mb2, the other terminal of the capacitor Cb1, and the wiring NLb1, and the other terminal of the capacitor Cb2 is connected to the wiring VLS2.

In the driver circuit 100 illustrated in FIG. 15, the amount of increase in the potential of the wiring NLb1 in Period T13 is “the amount of increase in the potential of the wiring OL×the capacitance of the capacitor Cb1/(the capacitance of the capacitor Cb1+the capacitance of the capacitor Cb2)”. That is, when the capacitance of the capacitor Cb2 is high, the amount of increase in the potential of the wiring NLb1 in Period T13 can be small. Here, for example, the capacitance of the capacitor Cb2 is preferably so high that the gate voltage of the transistor Mb1 does not exceed the threshold voltage owing to an increase in the potential of the wiring NLb1. For example, when the capacitance of the capacitor Cb2 is higher than “the capacitance of the capacitor Cb1×(the amount of increase in the potential of the wiring OL/the threshold voltage of the transistor Mb1−1)”, the transistor Mb1 can be prevented from being turned on in Period T13.

Employing such a structure can omit the transistor Mb3. This can inhibit an increase in power consumption due to repetition of the on state and the off state of the transistor Mb3. Consequently, for example, a display apparatus or the like that includes the driver circuit can have reduced power consumption.

### Variation Example 3

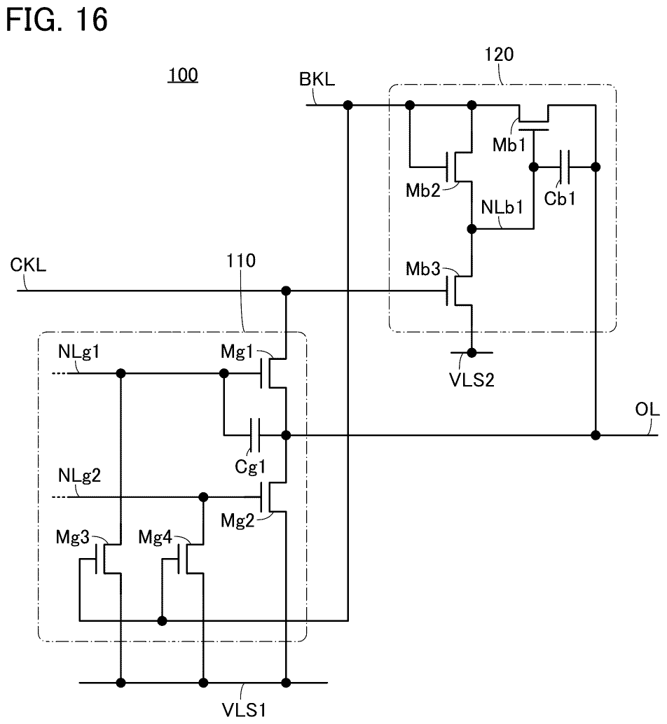

FIG. 16 is a circuit diagram illustrating a variation example of the driver circuit 100. The driver circuit 100 illustrated in FIG. 16 is different from the driver circuit 100 illustrated in FIG. 1 in including a transistor Mg3 and a transistor Mg4 in the first circuit 110. One of a source and a drain of the transistor Mg3 is connected to the wiring NLg1. One of a source and a drain of the transistor Mg4 is connected to the wiring NLg2. The other of the source and the drain of the transistor Mg3 is connected to the other of the source and the drain of the transistor Mg4 and the wiring VLS1. A gate of the transistor Mg3 is connected to a gate of the transistor Mg4 and the wiring BKL.

Note that the first circuit 110 illustrated in FIG. 16 corresponds to a structure in which the wiring IL3 in the first circuit 110 illustrated in FIG. 2B is connected to the wiring BKL, for example. In this case, the transistor Mg3 corresponds to the transistor Mga5, and the transistor Mg4 corresponds to the transistor Mga6.

In the driver circuit 100 illustrated in FIG. 16, when the potential H is supplied from the wiring BKL to the wiring NLb1 through the transistor Mb2 and the potential H is then supplied from the wiring BKL to the wiring OL through the transistor Mb1 as in Period T22 described above, the transistor Mg3 and the transistor Mg4 are turned on. Accordingly, the potentials of the wiring NLg1 and the wiring NLg2 each become the potential L, so that the transistor Mg1 and the transistor Mg2 can be turned off.

Here, because of the load on the wiring OL, the potential of the wiring OL becomes the potential H after the potential of the wiring BKL becomes the potential H. Thus, the potential of the wiring OL can become the potential H after the transistor Mg3 and the transistor Mg4 are turned on with the potential of the wiring BKL. In this manner, since the wiring BKL is connected to the gate of the transistor Mg3 and the gate of the transistor Mg4, the potential of the wiring OL can be prevented from becoming the potential H before the transistor Mg3 and the transistor Mg4 are turned on. Accordingly, the operation can be stabilized.

Note that the transistor Mg3 may be omitted in FIG. 16. Alternatively, the transistor Mg4 may be omitted in FIG. 16.

### Variation Example 4

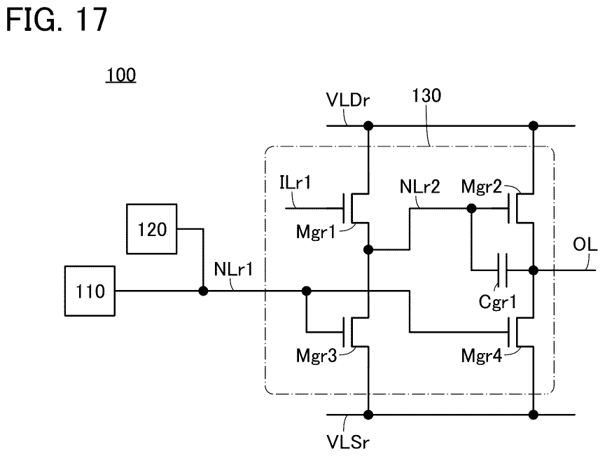

FIG. 17 is a circuit diagram illustrating a variation example of the driver circuit 100. The driver circuit 100 illustrated in FIG. 17 further includes an inverter circuit 130. Note that in the driver circuit 100 illustrated in FIG. 17, the first circuit 110 and the second circuit 120 are each denoted by a circuit block, and the output of the first circuit 110 and the output of the second circuit 120 are connected to a wiring NLr1. Note that the wiring NLr1 corresponds to an input of the inverter circuit 130, and the wiring OL corresponds to an output of the inverter circuit 130.

The inverter circuit 130 includes a transistor Mgr1, a transistor Mgr2, a transistor Mgr3, a transistor Mgr4, and a capacitor Cgr1. One of a source and a drain of the transistor Mgr1 is connected to a gate of the transistor Mgr2, one of a source and a drain of the transistor Mgr3, and one terminal of the capacitor Cgr1. One of a source and a drain of the transistor Mgr2 is connected to one of a source and a drain of the transistor Mgr4, the other terminal of the capacitor Cgr1, and the wiring OL. The other of the source and the drain of the transistor Mgr1 is connected to the other of the source and the drain of the transistor Mgr2 and a wiring VLDr. The other of the source and the drain of the transistor Mgr3 is connected to the other of the source and the drain of the transistor Mgr4 and a wiring VLSr. A gate of the transistor Mgr1 is connected to a wiring ILr1. A gate of the transistor Mgr3 is connected to a gate of the transistor Mgr4 and the wiring NLr1.

The inverter circuit 130 has a function of outputting a potential L to the wiring OL when a potential H is input to the wiring NLr1. In addition, the inverter circuit 130 has a function of outputting a potential H to the wiring OL when a potential L is input to the wiring NLr1.

Here, for example, a potential H is supplied to the wiring VLDr, and a potential L is supplied to the wiring VLSr. To the wiring ILr1, either a constant potential H or a signal that has the potential H at a given timing may be supplied.

Note that in the case where a signal that has the potential H at a given timing is supplied to the wiring ILr1, a potential L may be supplied to the wiring ILr1 when the potential H is supplied to the wiring NLr1, and the potential H may be supplied to the wiring ILr1 when the potential L is supplied to the wiring NLr1.

### Variation Example 5

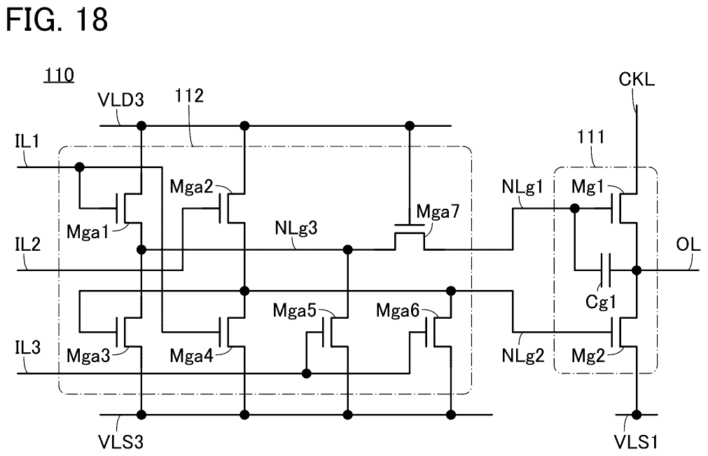

FIG. 18 is a circuit diagram illustrating a variation example of the first circuit 110. The first circuit 110 illustrated in FIG. 18 is different from the first circuit 110 illustrated in FIG. 2B in including a transistor Mga7 and in the connection of the wiring NLg1. One of a source and a drain of the transistor Mga7 is connected to the gate of the transistor Mg1, the one terminal of the capacitor Cg1, and the wiring NLg1. The other of the source and the drain of the transistor Mga7 is connected to the one of the source and the drain of the transistor Mga1, the one of the source and the drain of the transistor Mga3, and the one of the source and the drain of the transistor Mga5. A gate of the transistor Mga7 is connected to the wiring VLD3.

In the driver circuit 100 illustrated in FIG. 18, when the potential of the wiring NLg1 increases in Period T13 described above, the transistor Mga7 is turned off, so that an increase in the potential of a wiring NLg3 can be inhibited. This can inhibit, for example, an increase in drain voltage of each of the transistor Mga3 and the transistor Mga5 and resultant deterioration of the transistor characteristics.

### Variation Example 6

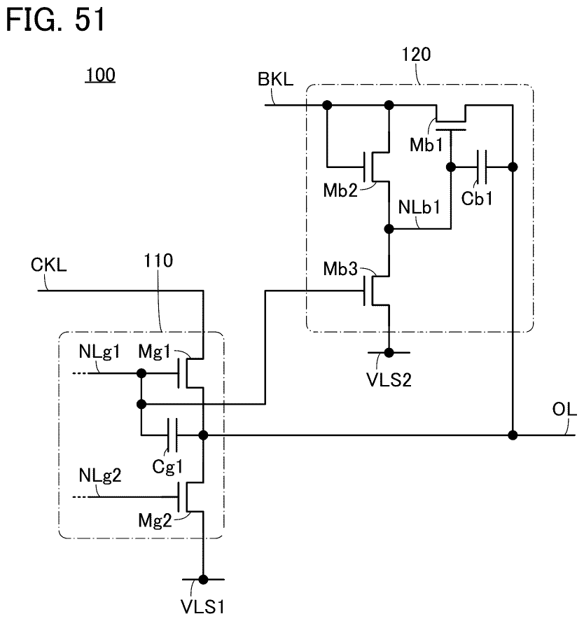

FIG. 51 is a circuit diagram illustrating a variation example of the driver circuit 100. The driver circuit 100 illustrated in FIG. 51 is different from the driver circuit 100 illustrated in FIG. 1 in that the gate of the transistor Mb3 is connected to the gate of the transistor Mg1.

In such a structure, the gate of the transistor Mb3 is not connected to the wiring CKL, and thus, the load on the wiring CKL can be reduced. Accordingly, a current that flows through the wiring CKL when the transistor Mb3 is driven can be low, so that power consumption can be reduced. Furthermore, the wiring CKL can be thin, leading to a smaller footprint.

The gate of the transistor Mg1 is connected to the wiring NLg1, and the potential of the wiring NLg1 becomes the potential H in Period T12. Thus, in Period T12, the transistor Mb3 is in an on state. In Period T13 following Period T12, the transistor Mb3 is also in an on state. In Period T13 following Period T12, in which the transistor Mb3 is in an on state as described above, the potential of the wiring OL can become the potential H. Thus, the potential of the wiring OL can be prevented from becoming the potential H before the transistor Mb3 is turned on, with enough time to spare. Accordingly, the operation can be stabilized.

In the variation example illustrated in FIG. 51, the potential of the wiring OL can be prevented from becoming the potential H before the transistor Mb3 is turned on, with enough time to spare; thus, the transistor Mb3 does not necessarily have lower gate capacitance than the transistor Mg1. Note that the transistor Mg3 may have lower gate capacitance than the transistor Mg1 to further stabilize the operation.

### <Structure Example of Semiconductor Device>

Next, a semiconductor device of one embodiment of the present invention will be described with reference to drawings. At least part of the driver circuit of one embodiment of the present invention can be used for the semiconductor device.

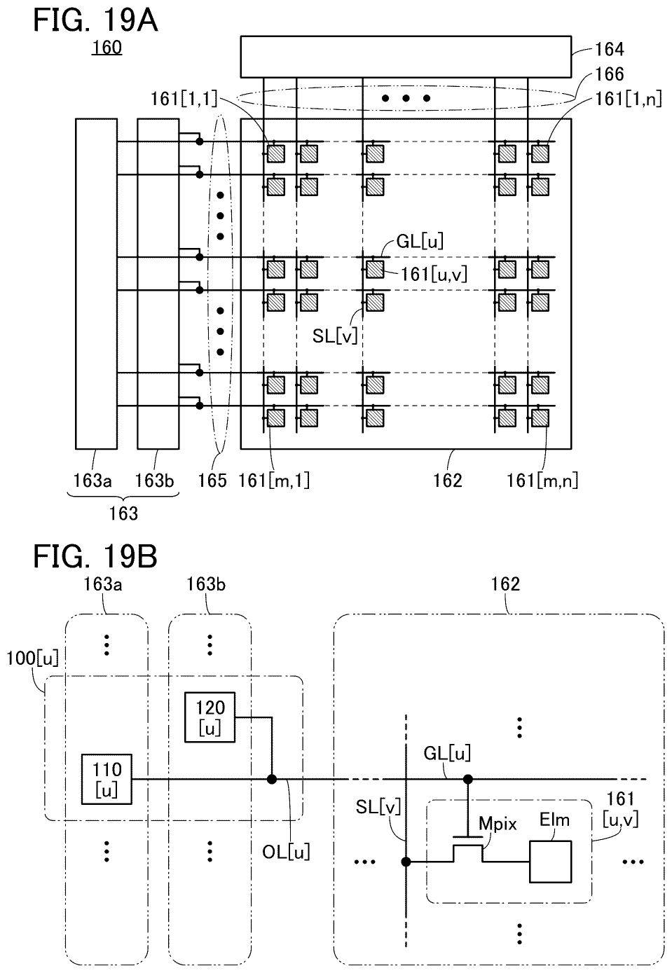

FIG. 19A is a block diagram illustrating a structure example of the semiconductor device of one embodiment of the present invention.

As illustrated in FIG. 19A, a semiconductor device 160 includes a pixel portion 162, a gate driver portion 163, and a source driver portion 164. The pixel portion 162 includes a plurality of pixels 161 arranged in a matrix of m rows and n columns (m is an integer greater than or equal to 2 and n is an integer greater than or equal to 2).

The pixel 161 can include a functional element. Here, in the case where the functional element is a display element such as a liquid crystal element or a light-emitting element, for example, the semiconductor device 160 functions as a display apparatus (also referred to as an output device in some cases). In the case where the functional element is a light-receiving element, for example, the semiconductor device 160 functions as an image capturing device (also referred to as an input device in some cases). Note that the pixel 161 may include both a display element and a light-receiving element. In that case, the semiconductor device 160 functions as both a display apparatus and an image capturing device (also referred to as an input/output device in some cases).

In FIG. 19A, the pixel 161 placed in the first row and the first column is denoted as a pixel 161[1,1], the pixel 161 placed in the first row and the n-th column is denoted as a pixel 161[1,n], the pixel 161 placed in the m-th row and the first column is denoted as a pixel 161[m,1], and the pixel 161 placed in the m-th row and the n-th column is denoted as a pixel 161[m,n]. Note that the pixel 161 placed in the u-th row and the v-th column is denoted as a pixel 161[u,v](u is an integer greater than or equal to 1 and less than or equal to m and v is an integer greater than or equal to 1 and less than or equal to n) in some cases. Note that in the description of matters common to the plurality of pixels 161, identification signs such as “[u,v]” are sometimes omitted.

The semiconductor device 160 includes m gate lines 165 which are arranged parallel to each other and whose potentials are controlled by a circuit included in the gate driver portion 163. The potential of each gate line 165 is supplied to n of the pixels 161 arranged in the row direction. Note that a plurality of wirings may form each gate line 165 depending on the structure of the pixel 161.

The semiconductor device 160 includes n source lines 166 which are arranged parallel to each other and whose potentials are controlled by a circuit included in the source driver portion 164. The potential of each source line 166 is supplied to m of the pixels 161 arranged in the column direction. Note that a plurality of wirings may form each source line 166 depending on the structure of the pixel 161.

The circuit included in the gate driver portion 163 serves as, for example, a scan line driver circuit (sometimes referred to as a gate line driver circuit, a gate driver, a scan driver, or a row driver).

The circuit included in the source driver portion 164 serves as, for example, a signal line driver circuit (sometimes referred to as a source line driver circuit, a source driver, a data driver, or a column driver).

In one embodiment of the present invention, at least part of the driver circuit 100 described above can be used in the gate driver portion 163. FIG. 19A illustrates, as the gate driver portion 163, a sequential driving portion 163a that includes the first circuit 110 of the driver circuit 100 and a concurrent driving portion 163b that includes the second circuit 120 of the driver circuit 100.

FIG. 19B is a circuit diagram illustrating an example in which the driver circuit 100 described above is used in the gate driver portion 163.

FIG. 19B selectively illustrates the pixel 161[u,v] in the u-th row and the v-th column and a driver circuit 100[u] in the u-th row.

A first circuit 110[u] and a second circuit 120[u] included in the driver circuit 100[u] are each denoted by a circuit block. An output of the first circuit 110[u] and an output of the second circuit 120[u] are connected to a wiring OL[u].

As an example of the pixel 161 [u,v], the pixel 161 [u,v] including a transistor Mpix and a functional element Elm is shown. One of a source and a drain of the transistor Mpix is connected to the functional element Elm. The other of the source and the drain of the transistor Mpix is connected to a wiring SL[v], which corresponds to the source line 166. A gate of the transistor Mpix is connected to a wiring GL[u], which corresponds to the gate line 165. Note that the wiring GL[u] is connected to the wiring OL[u].

As the functional element Elm, a liquid crystal element, a light-emitting element, a light-receiving element, or the like can be used.

### [Structure Example of Pixel Including Liquid Crystal Element]

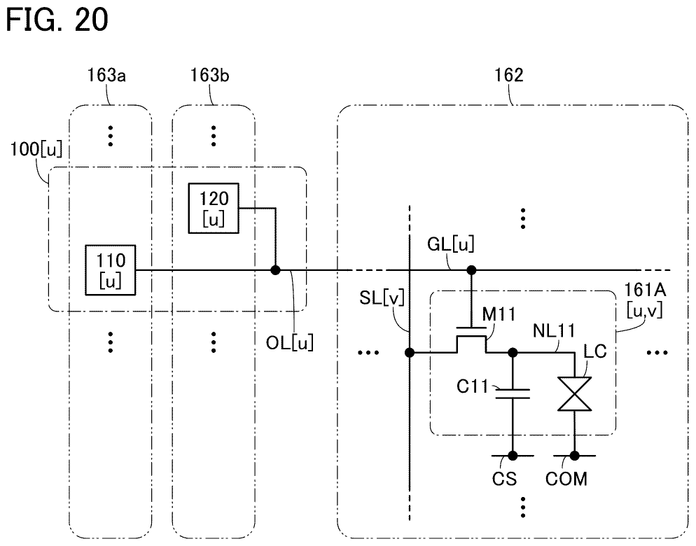

FIG. 20 is a circuit diagram illustrating an example in which a liquid crystal element LC is used as the functional element Elm.

FIG. 20 shows a pixel 161A[u,v] as the pixel 161[u,v]. The pixel 161A[u,v] includes a transistor M11 (corresponding to the transistor Mpix), the liquid crystal element LC, and a capacitor C11.

One of a source and a drain of the transistor M11 is connected to one terminal of the liquid crystal element LC, one terminal of the capacitor C11, and a wiring NL11. The other of the source and the drain of the transistor M11 is connected to the wiring SL[v]. A gate of the transistor M11 is connected to the wiring GL[u]. The other terminal of the liquid crystal element LC is connected to a wiring COM. The other terminal of the capacitor C11 is connected to a wiring CS.

The light transmittance of the liquid crystal element LC changes in accordance with the voltage between its pair of terminals.

The transistor M11 functions as a switch for controlling whether to write a data potential to the pixel 161A[u,v]. The capacitor C11 has a function of retaining the voltage between its pair of terminals.

As operations of the pixel 161A[u,v], a writing operation and a black scanning (also referred to as blacking) operation are described.

In the writing operation, first, a potential H is supplied to the wiring GL[u]. Accordingly, a data potential is supplied from the wiring SL[v] to the wiring NL11. That is, a voltage corresponding to the data potential is applied between the pair of terminals of the liquid crystal element LC. After that, a potential L is supplied to the wiring GL[u], and the voltage is retained in the capacitor C11.

In the black scanning operation, first, the potential H is supplied to the wiring GL[u]. Accordingly, a predetermined potential is supplied from the wiring SL[v] to the wiring NL11. That is, a voltage corresponding to the predetermined potential is applied between the pair of terminals of the liquid crystal element LC. After that, the potential L is supplied to the wiring GL[u], and the voltage is retained in the capacitor C11.

The predetermined potential is the same as the potential of the wiring COM, for example. That is, 0 V is applied between the pair of terminals of the liquid crystal element LC. This can reduce the residual DC of the liquid crystal element LC.

Here, the residual DC refers to a voltage that is induced by electric charge remaining between electrodes (or between alignment films) owing to voltage application to a liquid crystal layer. By the residual DC, an extra voltage is applied between the electrodes in a period in which a voltage is applied to the liquid crystal element. In addition, even in a period in which no voltage is applied to the liquid crystal element, a voltage remains between the electrodes owing to electric charge remaining in the liquid crystal layer. Generation of the residual DC causes the voltage applied to the liquid crystal layer to change even after writing of the data potential is completed, which accordingly changes the transmittance of the liquid crystal element. Moreover, the residual DC makes screen burn-in more likely to occur.

Thus, it is preferable that the black scanning operation be performed to discharge the electric charge remaining in the liquid crystal layer and inhibit the residual DC. The black scanning operation may be performed immediately before the semiconductor device (here, a liquid crystal display apparatus) is shut down, for example.

In one embodiment of the present invention, any of a variety of transistors can be used as the transistor included in the pixel 161A[u,v]. For example, an OS transistor may be used.

An OS transistor has a characteristic of an extremely low off-state current. Thus, when an OS transistor is used as the transistor M11 in the pixel 161A[u,v], for example, the voltage applied between the pair of terminals of the liquid crystal element LC by the writing operation can be retained for a long period. Thus, for example, reducing the frequency of the writing operation can reduce power consumption.

At this time, reducing the frequency of the writing operation elongates the period in which a constant voltage is continuously applied to the liquid crystal element, making residual DC likely to be generated. Thus, the black scanning operation is preferably performed to inhibit the residual DC.

### [Specific Example of Gate Driver Portion]

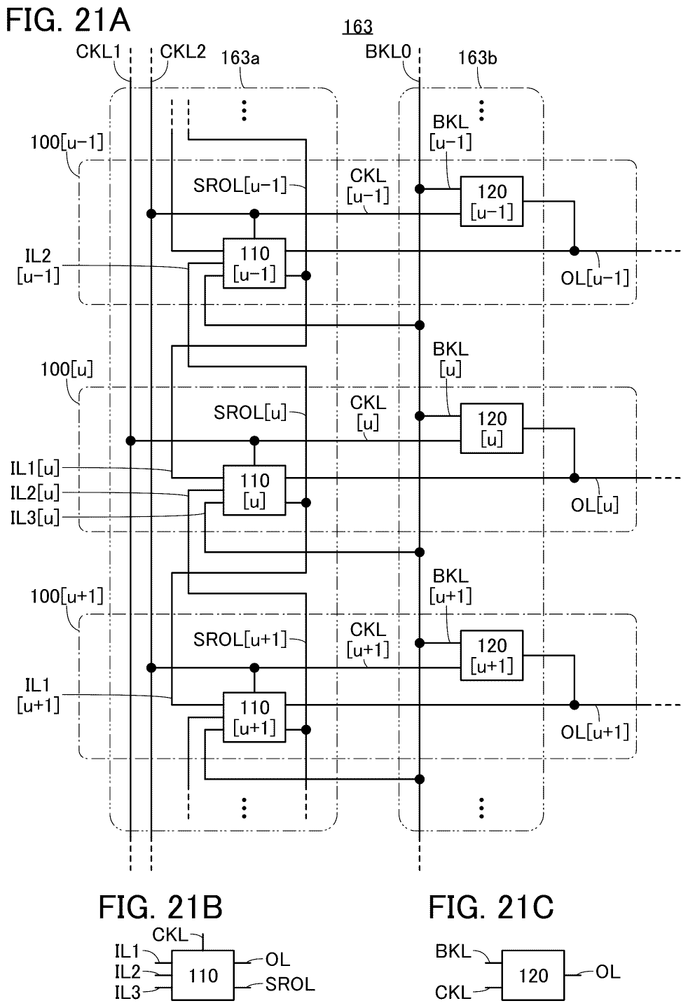

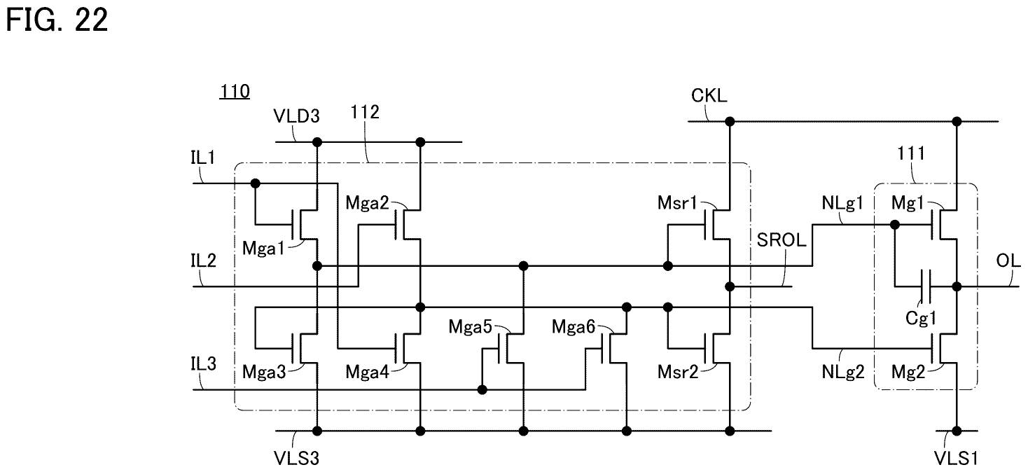

FIG. 21A is a circuit diagram illustrating an example in which a plurality of the driver circuits 100 are connected to each other in the gate driver portion 163. FIG. 21B is a circuit block corresponding to the first circuit 110 illustrated in FIG. 21A. FIG. 21C is a circuit block corresponding to the second circuit 120 illustrated in FIG. 21A. FIG. 22 is a circuit diagram illustrating an example of the first circuit 110 used in the driver circuit 100 illustrated in FIG. 21A.

The gate driver portion 163 includes at least m of the driver circuits 100 (driver circuits 100[1] to 100[m]) to drive the pixels 161, which are arranged in the matrix of m rows and n columns, row by row. FIG. 21A selectively illustrates the driver circuit 100[u−1] in the u−1-th row, the driver circuit 100[u] in the u-th row, and the driver circuit 100[u+1] in the u+1-th row. A first circuit 110[u−1] and a second circuit 120[u−1] included in the driver circuit 100[u−1], the first circuit 110[u] and the second circuit 120[u] included in the driver circuit 100[u], and a first circuit 110[u+1] and a second circuit 120[u+1] included in the driver circuit 100[u+1] are denoted by circuit blocks. Note that in description of matters common to the m driver circuits 100, matters common to m of the first circuits 110, or matters common to m of the second circuits 120, for example, identification signs such as “[u]” are sometimes omitted.

An output of the first circuit 110[u−1] and an output of the second circuit 120[u−1] are connected to a wiring OL[u−1]. The output of the first circuit 110[u] and the output of the second circuit 120[u] are connected to the wiring OL[u]. An output of the first circuit 110[u+1] and an output of the second circuit 120[u+1] are connected to a wiring OL[u+1].

A wiring CKL[u−1] connected to the first circuit 110[u−1] and the second circuit 120[u−1] is connected to a wiring CKL2. A wiring CKL[u] connected to the first circuit 110[u] and the second circuit 120[u] is connected to a wiring CKL1. A wiring CKL[u+1] connected to the first circuit 110[u+1] and the second circuit 120[u+1] is connected to the wiring CKL2.

A wiring BKL[u−1] connected to the second circuit 120[u−1] is connected to a wiring BKL0. A wiring BKL[u] connected to the second circuit 120[u] is connected to the wiring BKL0. A wiring BKL[u+1] connected to the second circuit 120[u+1] is connected to the wiring BKL0.

A wiring IL1[u] connected to the first circuit 110[u] is connected to a wiring SROL[u−1] connected to the first circuit 110[u−1]. A wiring IL2[u] connected to the first circuit 110[u] is connected to a wiring SROL[u+1] connected to the first circuit 110[u+1]. A wiring IL3[u] connected to the first circuit 110[u] is connected to the wiring BKL0. A wiring SROL[u] connected to the first circuit 110[u] is connected to a wiring IL2[u−1] connected to the first circuit 110[u−1] and a wiring IL1[u+1] connected to the first circuit 110[u+1].

The first circuit 110 illustrated in FIG. 22 (i.e., the first circuit 110 used in the driver circuit 100 illustrated in FIG. 21A) includes a transistor Msr1 and a transistor Msr2 in addition to the components of the first circuit 110 illustrated in FIG. 2B. One of a source and a drain of the transistor Msr1 is connected to one of a source and a drain of the transistor Msr2 and the wiring SROL. The other of the source and the drain of the transistor Msr1 is connected to the wiring CKL. The other of the source and the drain of the transistor Msr2 is connected to the wiring VLS3. A gate of the transistor Msr1 is connected to the wiring NLg1. A gate of the transistor Msr2 is connected to the wiring NLg2.

Note that in FIG. 22, either the other of the source and the drain of the transistor Mg1 or the other of the source and the drain of the transistor Msr1 may be connected to another wiring supplied with a constant potential or a signal different from a signal supplied to the wiring CKL. For example, the other of the source and the drain of the transistor Mg1 may be connected to another wiring supplied with a signal different from a signal supplied to the wiring CKL, in which case the period in which the signal output from the first circuit 110 to the wiring OL has the potential H can be different from the period in which the signal supplied to the wiring CKL has the potential H.

In the structure of the gate driver portion 163 illustrated in FIG. 21A and the like, the m first circuits 110 included in the sequential driving portion 163a sequentially supply, to m of the wirings OL (a wiring OL[1] to a wiring OL[m]), the signal supplied to the wiring CKL1 or the signal supplied to the wiring CKL2. The m second circuits 120 included in the concurrent driving portion 163b concurrently supply, to the m wirings OL, the signal supplied to the wiring BKL0.

Here, in the first circuit 110[u], the wiring SROL[u] is provided in addition to the wiring OL[u], and the wiring SROL[u] is connected to the wiring IL1[u+1] and the wiring IL2[u−1]. Accordingly, the signals that should be concurrently supplied to the m wirings OL by the m second circuits 120 can be prevented from being input to m of the wirings IL1 and m of the wirings IL2 to cause malfunctions of the m first circuits 110.

### [Operation Example of Gate Driver Portion]

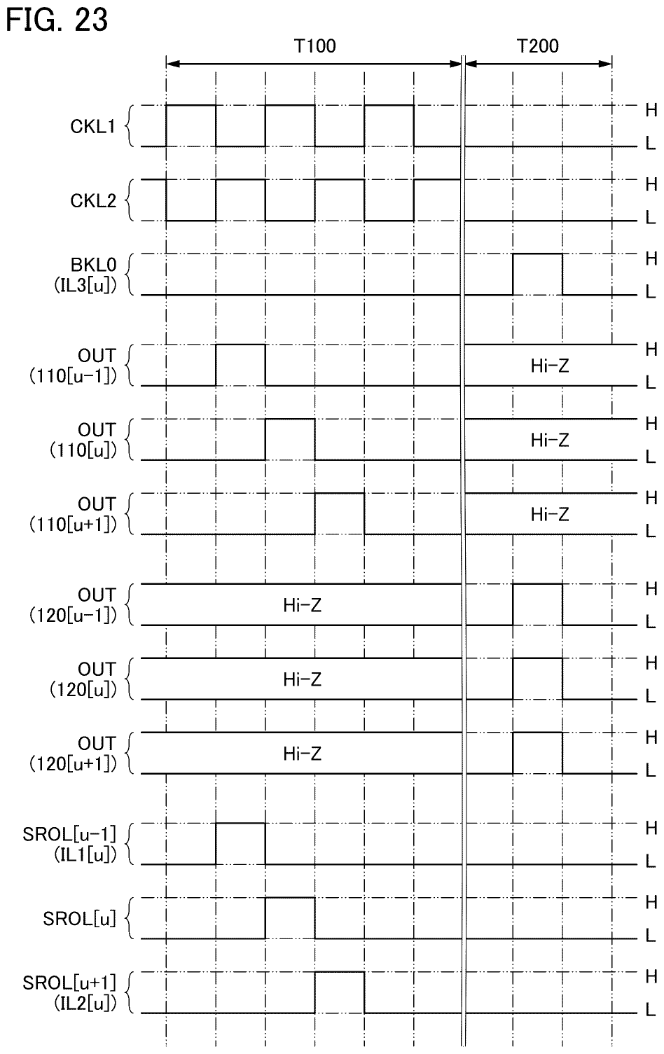

FIG. 23 is a timing chart illustrating an operation example of the gate driver portion 163.

The timing chart in FIG. 23 shows the potentials supplied to the wiring CKL1, the wiring CKL2, and the wiring BKL0 in each period of the operation. The timing chart also shows a potential H, a potential L, and a high impedance (denoted as “Hi-Z” in the drawing) for the outputs of the first circuit 110[u−1], the first circuit 110[u], the first circuit 110[u+1], the second circuit 120[u−1], the second circuit 120[u], and the second circuit 120[u+1](denoted as “OUT(110[u−1])”, “OUT(110[u])”, “OUT(110[u+1])”, “OUT(120[u−1])”, “OUT(120[u])”, and “OUT(120[u+1])” in the drawing). The timing chart also shows changes in the potentials of the wiring SROL[u−1], the wiring SROL[u], and the wiring SROL[u+1]. Note that the potential supplied to the wiring IL1[u] corresponds to the potential of the wiring SROL[u−1], the potential supplied to the wiring IL2[u] corresponds to the potential of the wiring SROL[u+1], and the potential supplied to the wiring IL3[u] corresponds to the potential of the wiring BKL0. Although not shown, the wiring OL[u−1], the wiring OL[u], and the wiring OL[u+1] are respectively supplied with outputs from the first circuit 110[u−1], the first circuit 110[u], and the first circuit 110[u+1] in Period T100, and the wiring OL[u−1], the wiring OL[u], and the wiring OL[u+1] are respectively supplied with outputs from the second circuit 120[u−1], the second circuit 120[u], and the second circuit 120[u+1] in Period T200.

The operation of each of the driver circuits 100 in Period T100 corresponds to the operation of the driver circuit 100 in Period T10 illustrated in FIG. 3 and the like. The operation of each of the driver circuits 100 in Period T200 corresponds to the operation of the driver circuit 100 in Period T20 illustrated in FIG. 3 and the like. Therefore, the above description can be appropriately referred to, and detailed description is sometimes omitted here.

As illustrated in FIG. 23, in Period T100, signals having the potential H are sequentially output from the m first circuits 110 included in the sequential driving portion 163a. That is, the signals having the potential H are sequentially supplied to the m wirings OL. In Period T200, signals having the potential H are concurrently output from the m second circuits 120 included in the concurrent driving portion 163b. That is, the signals having the potential H are concurrently supplied to the m wirings OL.

In the operation of the semiconductor device including the liquid crystal element in one embodiment of the present invention, Period T100 can be a period in which the writing operation is performed and Period T200 can be a period in which the black scanning operation is performed. That is, with the signals output from the sequential driving portion 163a, the writing operation can be sequentially performed row by row on the pixels 161A in the m rows. With the signals output from the concurrent driving portion 163b, the black scanning operation can be performed concurrently in all the rows.

Here, the use of the driver circuit 100 in the gate driver portion 163 makes it possible that the potential H is supplied to the wiring OL without a voltage drop due to the threshold voltage of the transistor Mb1 of the second circuit 120 included in the concurrent driving portion 163b at the time of the black scanning operation. Accordingly, the wiring BKL does not need to be supplied with “the potential H+the threshold voltage of the transistor Mb1”, so that an increase in power consumption can be inhibited. Moreover, the gate voltage of the transistor Mb1 is maintained, shortening the time it takes for the potential of the wiring OL to reach the potential H. Shortening the period in which the black scanning operation is performed (i.e., Period T200) can accordingly increase the operation speed.

### <Other Structure Examples of Semiconductor Device>

The semiconductor device of one embodiment of the present invention is not limited to the above-described structure.

### [Structure Example of Pixel Including Light-Emitting Element]

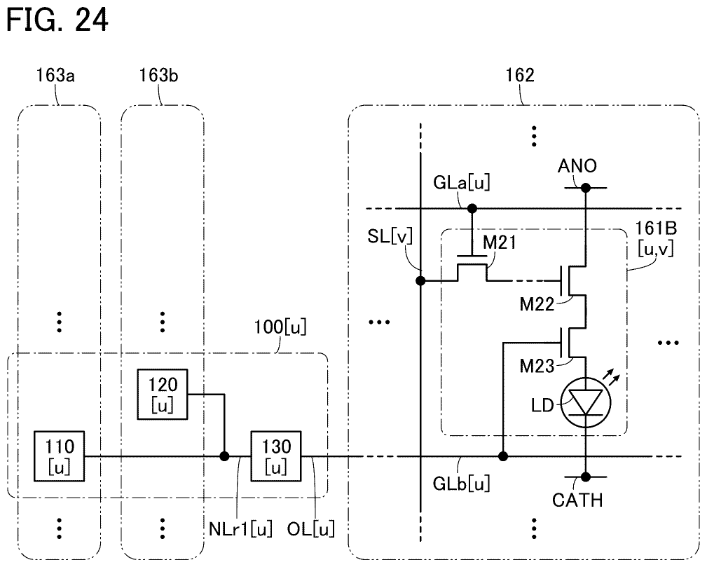

FIG. 24 is a circuit diagram illustrating an example in which a light-emitting element LD is used as the functional element Elm in the pixel 161 included in the semiconductor device 160.

FIG. 24 shows a pixel 161B[u,v] as the pixel 161[u,v]. In FIG. 24, as the driver circuit 100[u], a structure with an inverter circuit 130[u](which corresponds to the driver circuit 100 illustrated in FIG. 17) is illustrated using circuit blocks.

The pixel 161B[u,v] includes a transistor M21, a transistor M22, a transistor M23 (corresponding to the transistor Mpix), and the light-emitting element LD. One of a source and a drain of the transistor M23 is connected to one terminal of the light-emitting element LD. The other of the source and the drain the transistor M23 is connected to one of a source and a drain of the transistor M22. A gate of the transistor M23 is connected to a wiring GLb[u](corresponding to the wiring GL[u]). The other terminal of the light-emitting element LD is connected to a wiring CATH. The other of the source and the drain of the transistor M22 is connected to a wiring ANO. A gate of the transistor M22 is connected to a wiring supplied with a potential corresponding to the potential of one of a source and a drain of the transistor M21. The other of the source and the drain of the transistor M21 is connected to the wiring SL[v]. A gate of the transistor M21 is connected to a wiring GLa[u].

The light-emitting element LD emits light with emission intensity corresponding to the amount of current flowing through the light-emitting element LD. An organic EL element can be used as the light-emitting element LD, for example.

The transistor M22 is capable of varying a drain current in accordance with the potential supplied to the gate. Thus, in the pixel 161B[u,v], the transistor M22 has a function of controlling the amount of current flowing through the light-emitting element LD. In other words, the transistor M22 has a function of controlling the emission intensity of the light-emitting element LD. In this specification and the like, a transistor that functions like the transistor M22 is sometimes referred to as a driving transistor.

The transistor M21 functions as a switch for controlling whether to write a data potential to the pixel 161B[u,v]. The transistor M23 functions as a switch for controlling whether to make a current flow through the light-emitting element LD.

The pixel 161B[u,v] can have a structure that has a function of correcting a variation in the threshold voltage of the driving transistor (i.e., a structure that includes an internal correction circuit).

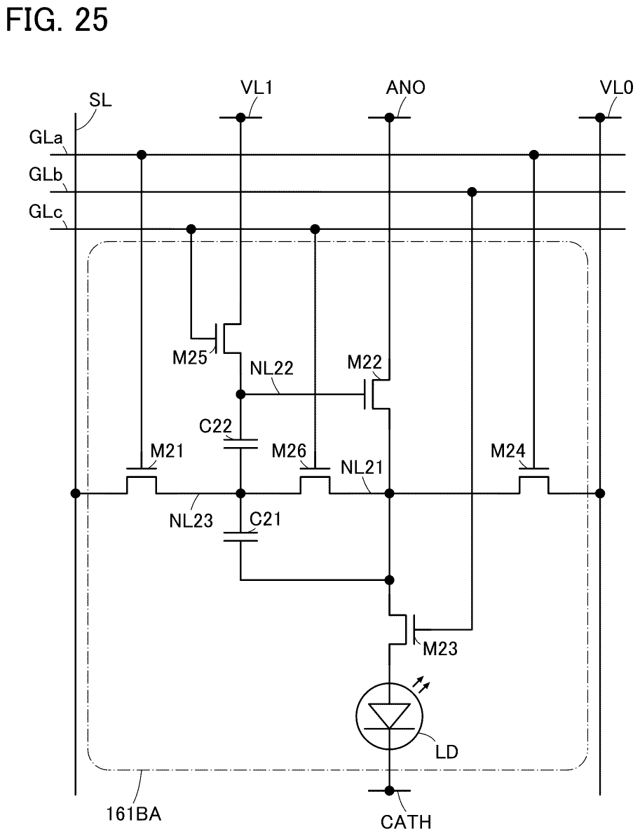

FIG. 25 is a circuit diagram illustrating a specific structure example of the pixel 161B[u,v] including an internal correction circuit.

A pixel 161BA shown in FIG. 25 includes a transistor M24, a transistor M25, a transistor M26, a capacitor C21, and a capacitor C22 in addition to the transistor M21, the transistor M22, the transistor M23, and the light-emitting element LD.

The one of the source and the drain of the transistor M23 is connected to the one terminal of the light-emitting element LD. The other of the source and the drain of the transistor M23 is connected to the one of the source and the drain of the transistor M22, one of a source and a drain of the transistor M24, one of a source and a drain of the transistor M26, one terminal of the capacitor C21, and a wiring NL21. The gate of the transistor M23 is connected to the wiring GLb. The other terminal of the light-emitting element LD is connected to the wiring CATH. The other of the source and the drain of the transistor M22 is connected to the wiring ANO. The gate of the transistor M22 is connected to one of a source and a drain of the transistor M25, one terminal of the capacitor C22, and a wiring NL22. The other terminal of the capacitor C22 is connected to the one of the source and the drain of the transistor M21, the other of the source and the drain of the transistor M26, the other terminal of the capacitor C21, and a wiring NL23. The other of the source and the drain of the transistor M21 is connected to the wiring SL. The gate of the transistor M21 is connected to a gate of the transistor M24 and the wiring GLa. The other of the source and the drain of the transistor M24 is connected to a wiring VL0. The other of the source and the drain of the transistor M25 is connected to a wiring VL1. A gate of the transistor M25 is connected to a gate of the transistor M26 and a wiring GLc.

The transistors M24, M25, and M26 each function as a switch. The capacitors C21 and C22 have a function of retaining the voltage between their respective pairs of terminals.

A correction operation and a writing operation of the pixel 161BA are described.

In the correction operation, first, a potential L is supplied to the wiring GLa, and a potential H is supplied to each of the wiring GLb and the wiring GLc. Then, a potential L is supplied to the wiring GLb. After that, a potential L is supplied to the wiring GLc. By such a series of operations, the voltage corresponding to the threshold voltage of the transistor M22 is retained in the capacitor C22.

In the writing operation, first, a potential H is supplied to the wiring GLa, and the potential L is supplied to each of the wiring GLb and the wiring GLc. Accordingly, a data potential is supplied from the wiring SL to the wiring NL23, and a predetermined potential is supplied from the wiring VL0 to the wiring NL21. At this time, the potential of the wiring NL22 becomes “the data potential+a voltage corresponding to the threshold voltage of the transistor M22 retained in the capacitor C22”. That is, a voltage corresponding to the data potential is applied as the gate voltage of the transistor M22. After that, the potential L is supplied to the wiring GLa, and the gate voltage is retained in the capacitor C21 and the capacitor C22.

Next, the potential H is supplied to the wiring GLb. Accordingly, a current in an amount corresponding to the gate voltage applied to the transistor M22 flows through the light-emitting element LD. Then, the light-emitting element LD emits light with an emission intensity corresponding to the amount of the current. At this time, a voltage that does not depend on the threshold voltage of the transistor M22 is applied as the gate voltage of the transistor M22. Thus, a current in an amount that does not depend on the threshold voltage of the transistor M22 flows through the light-emitting element LD.

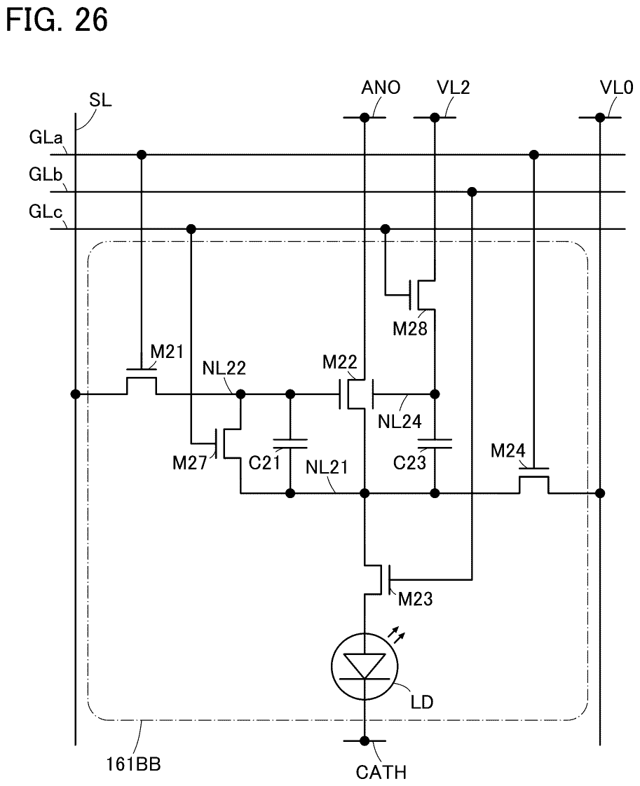

FIG. 26 is a circuit diagram illustrating a specific structure example of the pixel 161B[u,v] with an internal correction circuit, which is different from the pixel 161BA.

A pixel 161BB shown in FIG. 26 includes the transistor M24, a transistor M27, a transistor M28, the capacitor C21, and a capacitor C23 in addition to the transistor M21, the transistor M22, the transistor M23, and the light-emitting element LD. The transistor M22 has a back gate.

The one of the source and the drain of the transistor M23 is connected to the one terminal of the light-emitting element LD. The other of the source and the drain of the transistor M23 is connected to the one of the source and the drain of the transistor M22, the one of the source and the drain of the transistor M24, one of a source and a drain of the transistor M27, the one terminal of the capacitor C21, one terminal of the capacitor C23, and the wiring NL21. The gate of the transistor M23 is connected to the wiring GLb. The other terminal of the light-emitting element LD is connected to the wiring CATH. The other of the source and the drain of the transistor M22 is connected to the wiring ANO. The gate of the transistor M22 is connected to the one of the source and the drain of the transistor M21, the other of the source and the drain of the transistor M27, the other terminal of the capacitor C21, and the wiring NL22. The back gate of the transistor M22 is connected to one of a source and a drain of the transistor M28, the other terminal of the capacitor C23, and a wiring NL24. The other of the source and the drain of the transistor M21 is connected to the wiring SL. The gate of the transistor M21 is connected to the gate of the transistor M24 and the wiring GLa. The other of the source and the drain of the transistor M24 is connected to the wiring VL0. A gate of the transistor M27 is connected to a gate of the transistor M28 and the wiring GLc. The other of the source and the drain of the transistor M28 is connected to a wiring VL2.

The transistor M22 is capable of varying its threshold voltage in accordance with the potential supplied to the back gate.

The transistors M24, M27, and M28 each function as a switch. The capacitors C21 and C23 have a function of retaining the voltage between their respective pairs of terminals.

A correction operation and a writing operation of the pixel 161BB are described.

In the correction operation, first, the potential L is supplied to the wiring GLa, and the potential H is supplied to each of the wiring GLb and the wiring GLc. Then, the potential L is supplied to the wiring GLb. After that, the potential L is supplied to the wiring GLc. By such a series of operations, a back gate voltage for correcting the threshold voltage of the transistor M22 to 0 V is retained in the capacitor C23.

In the writing operation, first, the potential H is supplied to the wiring GLa, and the potential L is supplied to each of the wiring GLb and the wiring GLc. Accordingly, a data potential is supplied from the wiring SL to the wiring NL22, and a predetermined potential is supplied from the wiring VL0 to the wiring NL21. That is, a voltage corresponding to the data potential is applied as the gate voltage of the transistor M22. After that, the potential L is supplied to the wiring GLa, and the gate voltage is retained in the capacitor C21.

Next, the potential H is supplied to the wiring GLb. Accordingly, a current in an amount corresponding to the gate voltage applied to the transistor M22 flows through the light-emitting element LD. Then, the light-emitting element LD emits light with an emission intensity corresponding to the amount of the current. At this time, a voltage for correcting the threshold voltage of the transistor M22 to 0 V is applied as the back gate voltage of the transistor M22. Thus, a current in an amount that does not depend on the threshold voltage of the transistor M22 flows through the light-emitting element LD.

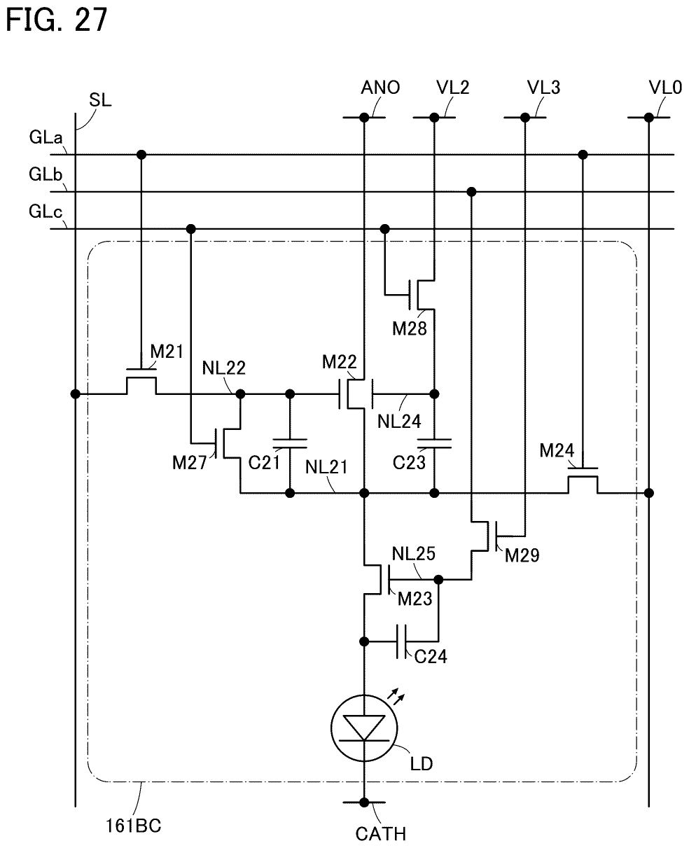

FIG. 27 is a circuit diagram illustrating a variation example of the pixel 161BB.

A pixel 161BC illustrated in FIG. 27 includes a transistor M29 and a capacitor C24 in addition to the components of the pixel 161BB.

The one of the source and the drain of the transistor M23 is connected to the one terminal of the light-emitting element LD and one terminal of the capacitor C24. The gate of the transistor M23 is connected to one of a source and a drain of the transistor M29, the other terminal of the capacitor C24, and a wiring NL25. The other of the source and the drain of the transistor M29 is connected to the wiring GLb. A gate of the transistor M29 is connected to a wiring VL3.

The transistor M29 functions as a switch. The capacitor C24 has a function of retaining the voltage between its pair of terminals.

In an operation of the pixel 161BC, when the potential of the one terminal of the light-emitting element LD (i.e., the one of the source and the drain of the transistor M23) increases at the time when a current in an amount corresponding to the gate voltage applied to the transistor M22 flows through the light-emitting element LD, the increase in the potential is followed by an increase in the potential of the wiring NL25 (i.e., the gate of the transistor M23) owing to capacitive coupling through the capacitor C24. Thus, the transistor M23 can be surely turned on. Accordingly, a current can be stably supplied to the light-emitting element LD. Note that the capacitor C23 is referred to as a bootstrap capacitor in some cases.

In one embodiment of the present invention, any of a variety of transistors can be used as the transistors included in the pixel 161B[u,v]. For example, an OS transistor may be used.

An OS transistor has a characteristic of an extremely low off-state current. Thus, when OS transistors are used as the transistors functioning as switches in the pixel 161BA, for example, the voltage between the pair of terminals of the capacitor C22 obtained by the correction operation (i.e., the voltage corresponding to the threshold voltage of the transistor M22) can be retained for a long period. When OS transistors are used as the transistors functioning as switches in the pixel 161BB or 161BC, for example, the voltage between the pair of terminals of the capacitor C23 obtained by the correction operation (i.e., the back gate voltage for correcting the threshold voltage of the transistor M22 to 0 V) can be retained for a long period. Accordingly, the frequency of the correction operation can be reduced, for example. As a result, power consumption can be reduced.

In the operation of the semiconductor device including the pixel with the internal correction circuit in one embodiment of the present invention, Period T100 can be a period in which the writing operation is performed and Period T200 can be a period in which the correction operation is performed. That is, with the signals output from the sequential driving portion 163a, the writing operation can be sequentially performed row by row on the pixels 161B in the m rows. With the signals output from the concurrent driving portion 163b, the correction operation can be performed concurrently in all the rows. Thus, a reduction in operation speed due to the correction operation can be inhibited.

Here, the use of the driver circuit 100 in the gate driver portion 163 makes it possible that the potential H is supplied to the wiring NLr1 without a voltage drop due to the threshold voltage of the transistor Mb1 of the second circuit 120 included in the concurrent driving portion 163b at the time of the correction operation. Accordingly, the wiring BKL does not need to be supplied with “the potential H+the threshold voltage of the transistor Mb1”, so that an increase in power consumption can be inhibited. Moreover, the gate voltage of the transistor Mb1 is maintained, shortening the time it takes for the potential of the wiring NLr1 to reach the potential H and for the potential of the wiring OL to reach the potential L. Shortening the period in which the correction operation is performed (i.e., Period T200) can accordingly increase the operation speed.

### [Structure Example of Pixel Including Light-Receiving Element]

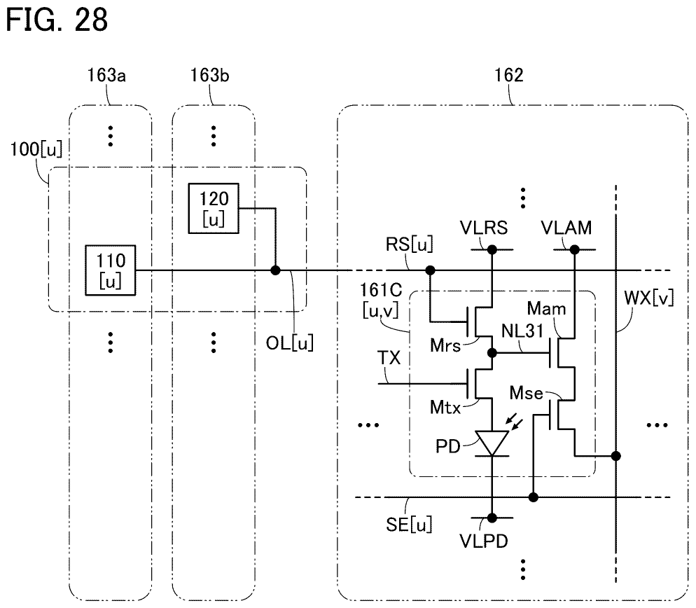

FIG. 28 is a circuit diagram illustrating an example in which a light-receiving element PD is used as the functional element Elm in the pixel 161 included in the semiconductor device 160.

FIG. 28 shows a pixel 161C[u,v] as the pixel 161[u,v].

The pixel 161C[u,v] includes a transistor Mtx, a transistor Mrs (corresponding to the transistor Mpix), a transistor Mam, a transistor Mse, and the light-receiving element PD. One of a source and a drain of the transistor Mrs is connected to one of a source and a drain of the transistor Mtx, a gate of the transistor Mam, and a wiring NL31. The other of the source and the drain of the transistor Mrs is connected to a wiring VLRS. A gate of the transistor Mrs is connected to a wiring RS[u](corresponding to the wiring GL[u]). The other of the source and the drain of the transistor Mtx is connected to one terminal of the light-receiving element PD. The other terminal of the light-receiving element PD is connected to a wiring VLPD. A gate of the transistor Mtx is connected to a wiring TX. One of a source and a drain of the transistor Mam is connected to one of a source and a drain of the transistor Mse. The other of the source and the drain of the transistor Mam is connected to a wiring VLAM. The other of the source and the drain of the transistor Mse is connected to a wiring WX[v]. A gate of the transistor Mse is connected to a wiring SE[u].

Although not shown, a capacitor may be provided in the pixel 161C[u,v], and one terminal of the capacitor may be connected to the wiring NL31. In that case, the other terminal of the capacitor may be connected to the wiring VLPD, the wiring VLRS, the wiring VLAM, or a wiring supplied with a given potential.

In the light-receiving element PD in a state where a reverse bias is applied between the pair of terminals, electric charge corresponding to the amount of light received by the light-receiving element PD is generated. For example, in the case where a constant potential is supplied to the other terminal of the light-receiving element PD and the one terminal thereof is brought into a floating state, electric charge is accumulated in the one terminal and the potential thereof increases.

The transistor Mtx functions as a switch for controlling light exposure of the light-receiving element. The transistor Mrs functions as a switch for controlling initialization of the potential of the wiring NL31. The transistor Mam functions as an amplifier that supplies a drain current corresponding to the potential of the gate (i.e., the potential of the wiring NL31). The transistor Mse functions as a switch for controlling whether to read the current corresponding to the potential of the wiring NL31 from the pixel 161C[u,v].

An image capturing operation and a reading operation of the pixel 161C are described.

In the image capturing operation, first, a potential H is supplied to each of the wiring TX and the wiring RS[u], and a potential L is supplied to the wiring SE[u]. Accordingly, the potential of the wiring NL31 and the reverse bias applied between the pair of terminals of the light-receiving element PD are initialized. Next, a potential L is supplied to each of the wiring TX and the wiring RS[u]. After a given light exposure time elapses, the potential H is supplied to the wiring TX, and then the potential L is supplied to the wiring TX. By such a series of operations, electric charge generated in accordance with the amount of light received by the light-receiving element PD is transferred to the wiring NL31, and a potential corresponding to the electric charge is retained in the wiring NL31.

In the reading operation, first, a potential H is supplied to the wiring SE[u], and the potential L is supplied to each of the wiring TX and the wiring RS[u]. Accordingly, a current corresponding to the potential retained in the wiring NL31 flows through the wiring WX[v], and the current is converted into a first voltage outside the pixel portion 162 (e.g., in the source driver portion 164). After that, the potential H is supplied to the wiring RS[u], and the potential of the wiring NL31 is initialized. Accordingly, a current that corresponds to the potential obtained by the initialization flows through the wiring WX[v], and the current is converted into a second voltage outside the pixel portion 162. At this time, correlated double sampling enables the difference between the first voltage and the second voltage to be read as a voltage that does not depend on the threshold voltage of the transistor Mam.

In one embodiment of the present invention, any of a variety of transistors can be used as the transistors included in the pixel 161C[u,v]. For example, an OS transistor may be used.

An OS transistor has a characteristic of an extremely low off-state current. Thus, when OS transistors are used as the transistors functioning as switches in the pixel 161C, for example, electric charge accumulated in the wiring NL31 (i.e., the potential of the wiring NL31) by the image capturing operation can be retained for a long period. This achieves a global shutter system in which all the pixels concurrently perform the image capturing operation.

In the operation of the semiconductor device including the light-receiving element in one embodiment of the present invention, Period T100 can be a period in which the reading operation is performed and Period T200 can be a period in which the image capturing operation is performed. That is, with the signals output from the sequential driving portion 163a, the reading operation can be sequentially performed row by row on the pixels 161C in the m rows. With the signals output from the concurrent driving portion 163b, the image capturing operation can be performed concurrently in all the rows.

Here, the use of the driver circuit 100 in the gate driver portion 163 makes it possible that the potential H is supplied to the wiring OL without a voltage drop due to the threshold voltage of the transistor Mb1 of the second circuit 120 included in the concurrent driving portion 163b at the time of the image capturing operation. Accordingly, the wiring BKL does not need to be supplied with “the potential H+the threshold voltage of the transistor Mb1”, so that an increase in power consumption can be inhibited.

### [Variation Example of Semiconductor Device]

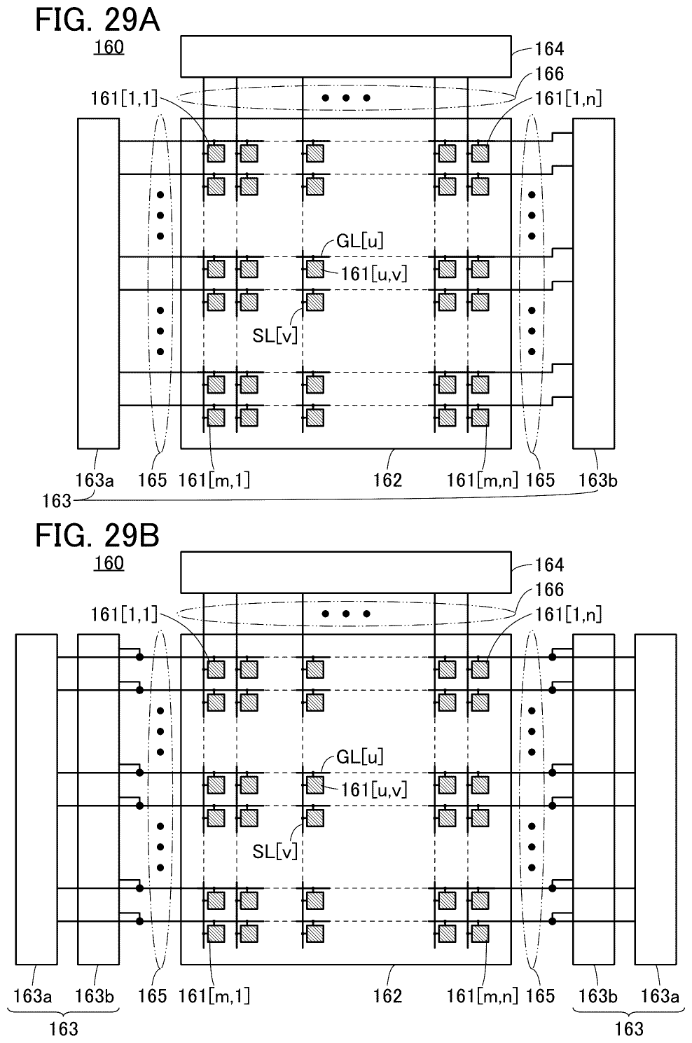

FIG. 29A is a block diagram illustrating a variation example of the semiconductor device 160. The semiconductor device 160 illustrated in FIG. 29A is different from the semiconductor device 160 illustrated in FIG. 19A in that the sequential driving portion 163a and the concurrent driving portion 163b in the gate driver portion 163 are placed to face each other with the pixel portion 162 therebetween. That is, in the drawing, the sequential driving portion 163a is placed on the outer left side of the pixel portion 162, and the concurrent driving portion 163b is placed on the outer right side of the pixel portion 162. In the case of employing such a structure, a display apparatus including the semiconductor device 160 can have a narrower bezel than in the case where both the sequential driving portion 163a and the concurrent driving portion 163b are placed on the outer left side of the pixel portion 162 in the drawing as illustrated in FIG. 19A.

FIG. 29B is a block diagram illustrating a variation example of the semiconductor device 160. The semiconductor device 160 illustrated in FIG. 29B is different from the semiconductor device 160 illustrated in FIG. 19A in including two of the gate driver portions 163 arranged to face each other with the pixel portion 162 therebetween. In the structure illustrated in FIG. 29B, the two gate driver portions 163 control the potentials of the m gate lines 165. Such a structure reduces substantial loads on the wirings (parasitic capacitance and parasitic resistance) to a quarter of loads on the wirings of the semiconductor device 160 illustrated in FIG. 19A. This enables a display apparatus including the semiconductor device 160 to have higher speed, resolution, and definition, a narrower bezel, and a larger screen, for example.

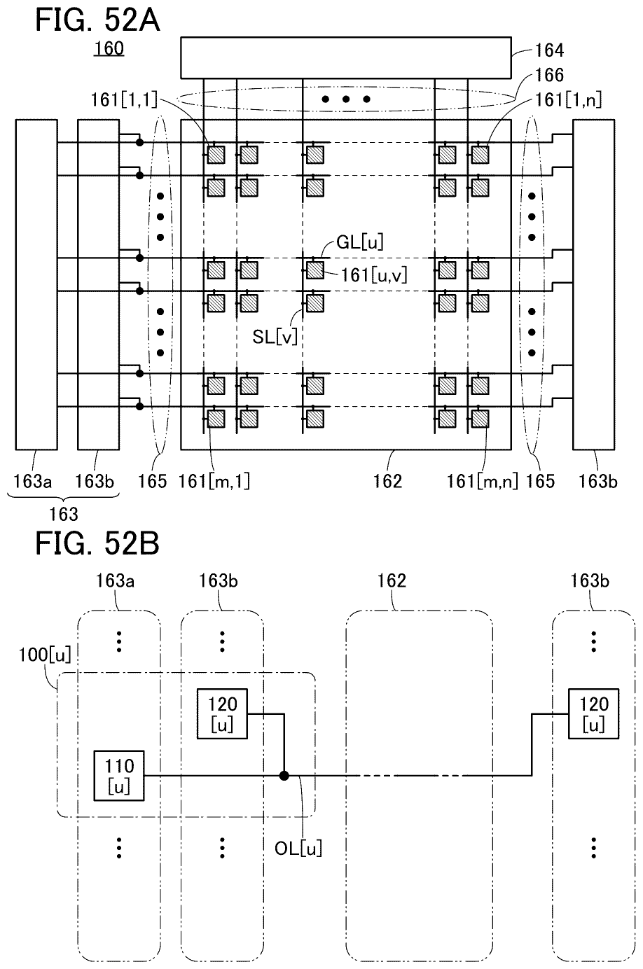

FIGS. 52A and 52B are block diagrams illustrating a variation example of the semiconductor device 160. The semiconductor device 160 illustrated in FIGS. 52A and 52B is different from the semiconductor device 160 illustrated in FIGS. 19A and 19B in that two of the concurrent driving portions 163b are placed to face each other with the pixel portion 162 therebetween in the gate driver portion 163. That is, in the drawing, the sequential driving portion 163a is placed on the outer left side of the pixel portion 162, and the concurrent driving portions 163b are placed on the outer left and right sides of the pixel portion 162. The concurrent driving portion 163b changes the potentials of the m gate lines 165 by using the potential of the wiring BKL, causing large loads on the wirings at the time of driving the concurrent driving portion 163b. In the variation example illustrated in FIGS. 52A and 52B, since the two concurrent driving portions 163b are provided to face each other with the pixel portion 162 therebetween, substantial loads on the wirings at the time of driving the concurrent driving portion 163b can be reduced. In other words, providing the two concurrent driving portions 163b improves the driving capability at the time of driving the concurrent driving portions 163b. Meanwhile, loads on the wirings at the time of driving the sequential driving portion 163a is smaller than those at the time of driving the concurrent driving portion 163b; thus, it is not always necessary to provide a plurality of the sequential driving portions 163a. For example, in the case where the sequential driving portion 163a is provided only on the outer left side or outer right side of the pixel portion (the outer left side in FIG. 52A), an increase in the bezel width can be inhibited as compared with the case where the sequential driving portions 163a are placed to face each other on the outer left and outer right sides of the pixel portion. That is, with the structure of the variation example illustrated in FIGS. 52A and 52B, the gate driver portion 163 can have both improved driving capability and a reduced footprint.

In one embodiment of the present invention, any of a variety of transistors can be used as the transistors included in the semiconductor device 160. For example, a Si transistor, an OS transistor, or both of them may be used.

The OS transistor can be freely placed over a silicon substrate or the like where a Si transistor is provided, for example; thus, integration can be easily achieved. Furthermore, the OS transistor can be manufactured with a manufacturing apparatus similar to that for a Si transistor and thus, the OS transistor can be manufactured at low cost.

Accordingly, in the semiconductor device 160, Si transistors each including part of a silicon substrate may be used as the transistors included in the source driver portion 164, and OS transistors provided over the silicon substrate may be used as the transistors included in the gate driver portion 163 and the pixel portion 162, for example. Note that OS transistors may be used as at least some of the transistors included in the source driver portion 164, and Si transistors may be used as at least some of the transistors included in the gate driver portion 163 and the pixel portion 162.

The Si transistors each including part of the silicon substrate may be used to provide a variety of circuits (which may include an arithmetic circuit, a memory circuit, and the like) that control the operation of the semiconductor device 160. Thus, one embodiment of the present invention can be a structure in which OS transistors are provided over a silicon substrate provided with Si transistors and a display element or a light-receiving element is provided over a layer provided with the OS transistors, for example.

The structure, operation, and the like of one embodiment of the present invention are not limited to the structure examples, operation examples, and the like described in this embodiment. An appropriate combination of the descriptions in this embodiment can be implemented. An appropriate combination of a description in this embodiment and a description in any of the other embodiments or the like can be implemented.

### Embodiment 2

In this embodiment, a transistor of one embodiment of the present invention will be described. At least part of the transistor described in this embodiment can be applied to the driver circuit, the semiconductor device, and the like described in Embodiment 1.

### <Structure Example 1 of Transistor>

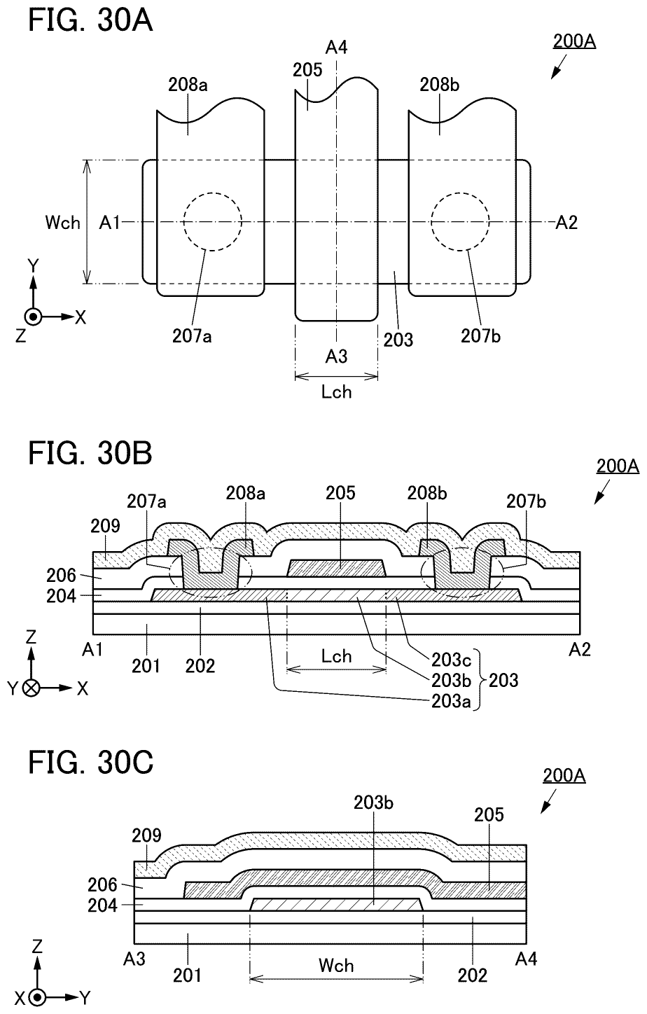

FIG. 30A is a top view of a transistor 200A. FIG. 30B is a cross-sectional view taken along dashed-dotted line A1-A2 in FIG. 30A. FIG. 30C is a cross-sectional view taken along dashed-dotted line A3-A4 in FIG. 30A. Note that for simplification, some components are not shown in the top view of FIG. 30A. Some components may be omitted also in the other top views.

The transistor 200A includes an insulating layer 202 over a substrate 201 and a semiconductor layer 203 over the insulating layer 202. An insulating layer 204 is provided over the insulating layer 202 and the semiconductor layer 203. A conductive layer 205 is provided over the insulating layer 204. The semiconductor layer 203 includes a region overlapping with the conductive layer 205 with the insulating layer 204 therebetween.

The semiconductor layer 203 includes a region 203a functioning as one of a source region and a drain region of the transistor 200A, a channel formation region 203b, and a region 203c functioning as the other of the source region and the drain region. A region of the semiconductor layer 203 that overlaps with the conductive layer 205 functions as the channel formation region 203b. Thus, the conductive layer 205 functions as a gate electrode of the transistor 200A. The insulating layer 204 functions as a gate insulating film of the transistor 200A.

In the semiconductor layer 203, the length of the channel formation region 203b in the X direction (which corresponds to the distance between the region 203a and the region 203c in the channel formation region 203b) is a channel length Lch of the transistor 200A (see FIGS. 30A and 30B). In the semiconductor layer 203, the length of the channel formation region 203b in the Y direction (which corresponds to the length of a portion of the channel formation region 203b where the region 203a and the region 203c face each other) is a channel width Wch of the transistor 200A (see FIGS. 30A and 30C).

Furthermore, an insulating layer 206 is provided over the insulating layer 204 and the conductive layer 205. The insulating layer 204 and the insulating layer 206 are provided with an opening portion 207a in a region overlapping with the region 203a of the semiconductor layer 203. The insulating layer 204 and the insulating layer 206 are provided with an opening portion 207b in a region overlapping with the region 203c of the semiconductor layer 203.

A conductive layer 208a is provided over the insulating layer 206 and in the opening portion 207a, and a conductive layer 208b is provided over the insulating layer 206 and in the opening portion 207b. The conductive layer 208a is in contact with the region 203a of the semiconductor layer 203 at the bottom portion of the opening portion 207a. The conductive layer 208b is in contact with the region 203c of the semiconductor layer 203 at the bottom portion of the opening portion 207b. The conductive layer 208a functions as one of a source electrode and a drain electrode of the transistor 200A and the conductive layer 208b functions as the other of the source electrode and the drain electrode of the transistor 200A.

An insulating layer 209 is provided over the insulating layer 206 and the conductive layer 208 (the conductive layers 208a and 208b).

### <Structure Example 2 of Transistor>

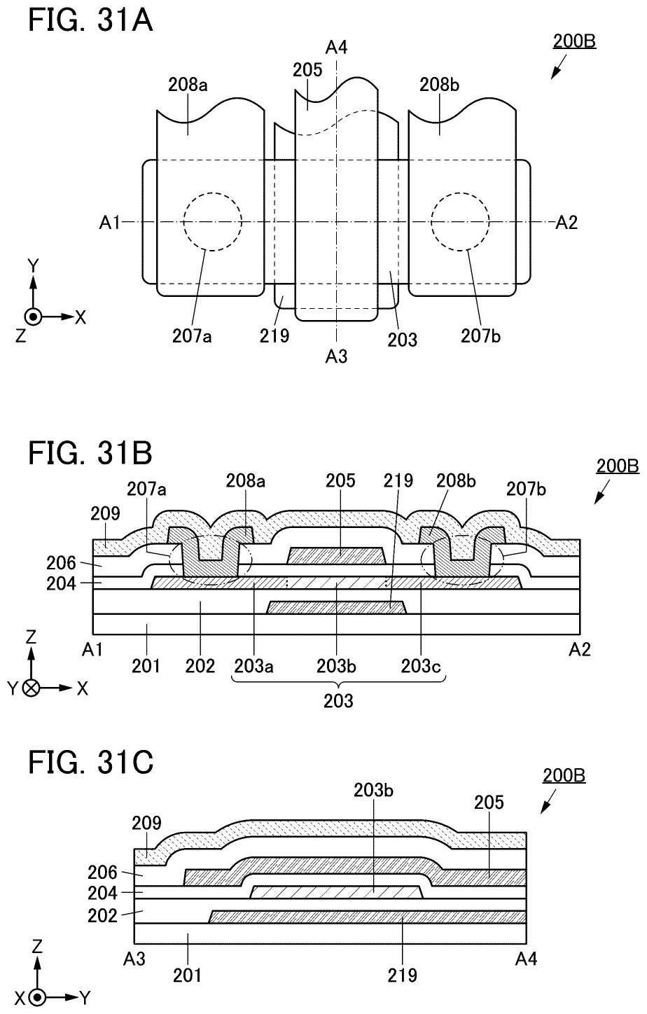

FIG. 31A is a top view of a transistor 200B. The transistor 200B is a variation example of the transistor 200A. Differences of the transistor 200B from the transistor 200A are mainly described to reduce repeated description.

FIG. 31B is a cross-sectional view taken along dashed-dotted line A1-A2 in FIG. 31A. FIG. 31C is a cross-sectional view taken along dashed-dotted line A3-A4 in FIG. 31A.

The transistor 200B is different from the transistor 200A in including a conductive layer 219 between the substrate 201 and the insulating layer 202. The conductive layer 219 overlaps with the channel formation region 203b with the insulating layer 202 therebetween. Thus, the insulating layer 202 functions as a back gate insulating film of the transistor 200B, and the conductive layer 219 functions as a back gate electrode of the transistor 200B. Note that the thickness of the insulating layer 202 in a region not overlapping with the conductive layer 219 may be different from that of the insulating layer 202 in a region overlapping with the conductive layer 219; alternatively, the insulating layer 202 may have a uniform thickness. The conductive layer 219 may extend beyond an end portion of the channel formation region 203b. Although not shown, an insulating layer may be provided between the substrate 201 and the conductive layer 219.

Here, in a transistor including a back gate, a gate and the back gate of the transistor are placed such that a channel formation region of a semiconductor layer is sandwiched therebetween. The back gate can function in a manner similar to that of the gate. In the case where the gate is used for control of the on state and the off state of the transistor, the potential of the back gate can be the same as the potential of the gate. Alternatively, the potential of the back gate can be a given potential.

In the case where the transistor is turned on, for example, the amount of on-state current can be larger when both the gate and the back gate are supplied with a potential for turning on the transistor than when only one of them is supplied with the potential. For example, when the gate and the back gate are connected to each other, the gate and the back gate can always have the same potential. By controlling the potential of the back gate independently of that of the gate, the threshold voltage of the transistor can be adjusted.

Alternatively, a constant potential such as a ground potential may be supplied to the back gate. Since the gate and the back gate are formed using a conductive layer or the like, an electric field generated outside the transistor does not easily act on a channel formation region of a semiconductor layer that is sandwiched between the gate and the back gate (such an effect is also referred to as “electric field blocking effect”). Therefore, the transistor provided with the back gate operates stably. Moreover, a variation in characteristics between a plurality of transistors is reduced when the transistors are provided with back gates. The transistor provided with the back gate can be highly reliable. Accordingly, a semiconductor device including the transistor can be highly reliable. The electric field blocking effect can be achieved in a state where one or both of the gate and the back gate are in an electrically floating state (also referred to as a “floating state”); the effect can be enhanced by supplying a potential to the gate and the back gate.

### <Structure Example 3 of Transistor>

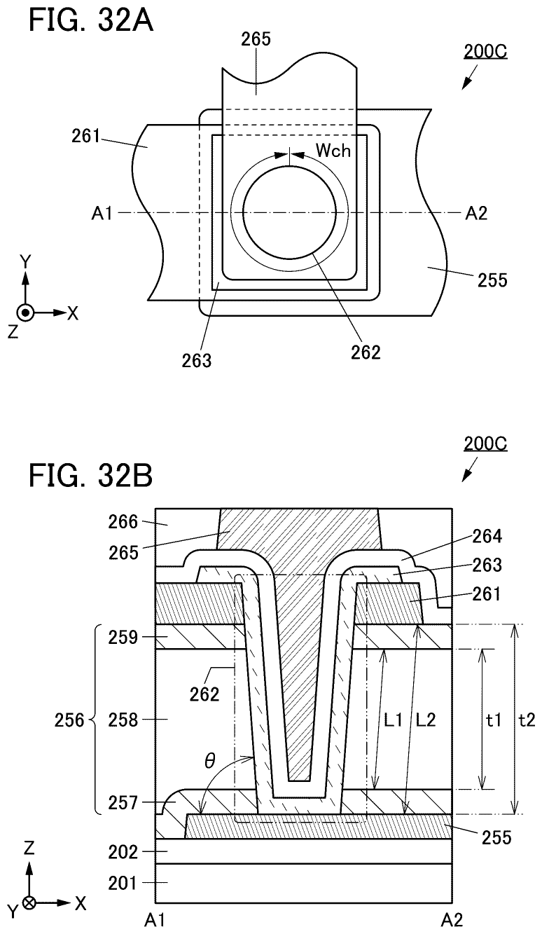

FIG. 32A is a top view of a transistor 200C. FIG. 32B is a cross-sectional view taken along dashed-dotted line A1-A2 in FIG. 32A.

The transistor 200C includes the insulating layer 202 over the substrate 201 and a conductive layer 255 over the insulating layer 202. An insulating layer 257 is provided over the conductive layer 255, an insulating layer 258 is provided over the insulating layer 257, and an insulating layer 259 is provided over the insulating layer 258. Note that in this specification and the like, the insulating layers 257, 258, and 259 are collectively referred to as an insulating layer 256 or a spacer layer in some cases. A conductive layer 261 is provided over the insulating layer 259.

In a region overlapping with part of the conductive layer 255, an opening portion 262 is provided in the conductive layer 261, the insulating layer 259, the insulating layer 258, and the insulating layer 257. A semiconductor layer 263 is provided in contact with the inner wall of the opening portion 262.

The semiconductor layer 263 includes a region overlapping with the bottom portion of the opening portion 262 and a region overlapping with the inner wall of the opening portion 262. That is, the semiconductor layer 263 includes, in the opening portion 262, a region in contact with the insulating layer 256. The semiconductor layer 263 includes, in the opening portion 262, a region in contact with the conductive layer 255 and a region in contact with the conductive layer 261.

An insulating layer 264 is provided over the insulating layer 259, the conductive layer 261, and the semiconductor layer 263. A conductive layer 265 is provided over the insulating layer 264. The conductive layer 265 includes a region overlapping with the semiconductor layer 263. The conductive layer 265 includes a region overlapping with the semiconductor layer 263 with the insulating layer 264 therebetween.

The insulating layer 264 and the conductive layer 265 each include a region overlapping with the opening portion 262. In the opening portion 262, the semiconductor layer 263 includes a region overlapping with the conductive layer 265 with the insulating layer 264 therebetween and a region overlapping with the inner wall of the opening portion 262 (the side surface of the insulating layer 256).

An insulating layer 266 is provided over the insulating layer 264. The top surface of the insulating layer 266 is preferably flat. Alternatively, the level (the position in the Z direction) of the top surface of the insulating layer 266 may be the same as that of the top surface of the conductive layer 265. For example, the flatness of the top surface of the insulating layer 266 can be improved by chemical mechanical polishing (CMP) treatment or the like. In addition, CMP treatment enables the top surfaces of the insulating layer 266 and the conductive layer 265 to be level with each other. CMP treatment can reduce unevenness of a sample surface, so that coverage with an insulating layer and a conductive layer to be formed later can be increased.

In the case where the semiconductor layer 263 is formed using an oxide semiconductor, the conductive layers 255 and 261, each of which is in contact with the semiconductor layer 263, is preferably formed using a conductive material that makes the oxide semiconductor have n-type conductivity. For example, a conductive material containing nitrogen may be used. For example, a conductive material containing nitrogen and titanium or tantalum may be used. Another conductive material may be provided so as to overlap with the conductive material containing nitrogen.

When an oxide semiconductor is used for the semiconductor layer 263, a material in which oxygen is contained and hydrogen is reduced is preferably used for the insulating layer 258. For example, a material containing silicon and oxygen may be used. Specifically, silicon oxide, silicon oxynitride, or the like may be used. Hydrogen is an impurity element in an oxide semiconductor; thus, the semiconductor layer 263 that is an oxide semiconductor is less likely to have n-type conductivity when in contact with the insulating layer 258 in which the amount of hydrogen is reduced. Furthermore, when the semiconductor layer 263 that is an oxide semiconductor is in contact with the insulating layer 258 that includes oxygen, oxygen vacancies in the semiconductor layer 263 are reduced, enabling the transistor to have stable characteristics and improved reliability.

In the case where the semiconductor layer 263 is formed using an oxide semiconductor, the insulating layer 258 may include excess oxygen. In this specification and the like, excess oxygen refers to oxygen that is released by heating. A material that releases oxygen by heating is a material in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in thermal desorption spectroscopy (TDS) analysis. Note that the temperature of the film surface in the TDS analysis is preferably within the range of 100° C. to 700° C. or 100° C. to 400° C.

In the case where a material containing excess oxygen is used for the insulating layer 258, a material that does not easily transmit oxygen is preferably used for the insulating layers 257 and 259. Examples of the material that does not easily transmit oxygen include a nitride of silicon and an oxide containing one or both of aluminum and hafnium. With the use of the material that does not easily transmit oxygen for the insulating layers 257 and 259, excess oxygen included in the insulating layer 258 is less likely to be released to a lower layer or an upper layer. Thus, sufficient oxygen can be supplied to the oxide semiconductor. For example, an insulating layer including silicon and oxygen (the insulating layer 258) may be provided between two insulating layers including silicon and nitrogen (the insulating layers 257 and 259).

In the case where an oxide semiconductor is used for the semiconductor layer 263, a material containing hydrogen may be used for the insulating layers 257 and 259. In that case, hydrogen is supplied to a region of the semiconductor layer 263 that is in contact with the insulating layer 257 and a region of the semiconductor layer 263 that is in contact with the insulating layer 259, so that these regions of the semiconductor layer 263 have n-type conductivity. Accordingly, the region of the semiconductor layer 263 that is in contact with the conductive layer 261 and the region of the semiconductor layer 263 that is in contact with the insulating layer 259 function as one of a source region and a drain region. The region of the semiconductor layer 263 that is in contact with the conductive layer 255 and the region of the semiconductor layer 263 that is in contact with the insulating layer 257 function as the other of the source region and the drain region.

The conductive layer 261 functions as one of a source electrode and a drain electrode of the transistor 200C. The conductive layer 255 functions as the other of the source electrode and the drain electrode of the transistor 200C. The source electrode and the drain electrode are provided in the Z direction in the transistor 200C. That is, the source electrode and the drain electrode of the transistor 200C are provided at different levels. In other words, the source electrode and the drain electrode of the transistor 200C are provided in different positions in the Z direction. Such a transistor is also referred to as a “vertical-channel transistor”, a “vertical transistor”, or a “vertical field effect transistor (VFET)”.

In the transistor 200C as a VFET employing the above structure, the length of the side surface of the insulating layer 258 seen from the X direction or the Y direction is the channel length Lch of the transistor 200C (here, a channel length L1) (see FIG. 32B). Thus, the channel length Lch of the transistor 200C depends on a thickness t1 of the insulating layer 258.

A material that contains no hydrogen or an extremely small amount of hydrogen may be used for the insulating layers 257 and 259. For example, silicon nitride that contains an extremely small amount of hydrogen or silicon nitride oxide that contains an extremely small amount of hydrogen may be used. In that case, the region of the semiconductor layer 263 that is in contact with the insulating layer 257 and the region of the semiconductor layer 263 that is in contact with the insulating layer 259 do not have n-type conductivity. Thus, the region of the semiconductor layer 263 that is in contact with the conductive layer 261 serves as the one of the source region and the drain region. The region of the semiconductor layer 263 that is in contact with the conductive layer 255 serves as the other of the source region and the drain region. A region of the semiconductor layer 263 that is in contact with the insulating layer 258 serves as a channel formation region.

In that case, the sum of the lengths of the side surfaces of the insulating layers 257, 258, and 259 seen from the X direction or the Y direction is the channel length Lch of the transistor 200C (here, a channel length L2). Thus, the channel length Lch of the transistor 200C depends on a thickness t2 obtained by adding the thicknesses of the insulating layers 257, 258, and 259. In this manner, the channel formation region of the transistor 200C includes a region along the side surface of the insulating layer 256.

Since the semiconductor layer 263 is provided in the opening portion 262, the length of the circumference of the opening portion 262 seen from the Z direction is the channel width Wch of the transistor 200C (see FIG. 32A). The length of the circumference can be calculated at the position at the half of the thickness t1 of the insulating layer 258 or the position at the half of the thickness t2, for example. Note that the length of the circumference of the opening portion 262 at a given position may be regarded as the channel width Wch as necessary. For example, the length of the circumference of the lowest portion or the uppermost portion of the opening portion 262 may be regarded as the channel width Wch. Although the outline (the planar shape) of the opening portion 262 seen from the Z direction is circular in FIG. 32A, the outline is not limited to this. For example, the outline of the opening portion 262 seen from the Z direction may be elliptical or rectangular.

The channel length Lch of the transistor 200C is preferably shorter than at least the channel width Wch of the transistor 200C. For example, the channel length Lch can be greater than or equal to 0.1 times and less than or equal to 0.99 times, preferably greater than or equal to 0.5 times and less than or equal to 0.8 times the channel width Wch.

In order to improve the coverage with the semiconductor layer 263, the insulating layer 264, and the conductive layer 265 formed inside the opening portion 262, the taper angle θ of the inner wall of the opening portion 262, i.e., the taper angle θ of each of the side surfaces of the insulating layers 257, 258, and 259, may be greater than or equal to 45° and less than or equal to 90°, preferably greater than or equal to 50° and less than or equal to 75°. Note that the taper angle θ of the side surface of a layer (an insulating layer, a conductive layer, or a semiconductor layer) refers to the angle formed between the bottom surface and the side surface of the layer (see FIG. 32B).

The footprint of a vertical transistor can be smaller than that of a transistor whose channel formation region, source region, and drain region are provided separately on the XY plane (also referred to as lateral transistor). Thus, a semiconductor device can have reduced footprint by including a vertical transistor. Furthermore, a semiconductor device achieves high integration by including a vertical transistor.

A lateral transistor, whose channel length is limited by the light exposure limit of photolithography, has been difficult to further miniaturize. By contrast, in a vertical transistor, the channel length can be set with the thickness of the insulating layer 256 or the insulating layer 258. Thus, the transistor can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 200C can have a higher on-state current and higher frequency characteristics. With the use of a vertical transistor, a semiconductor device with high operation speed can be provided.

### <Structure Example 4 of Transistor>

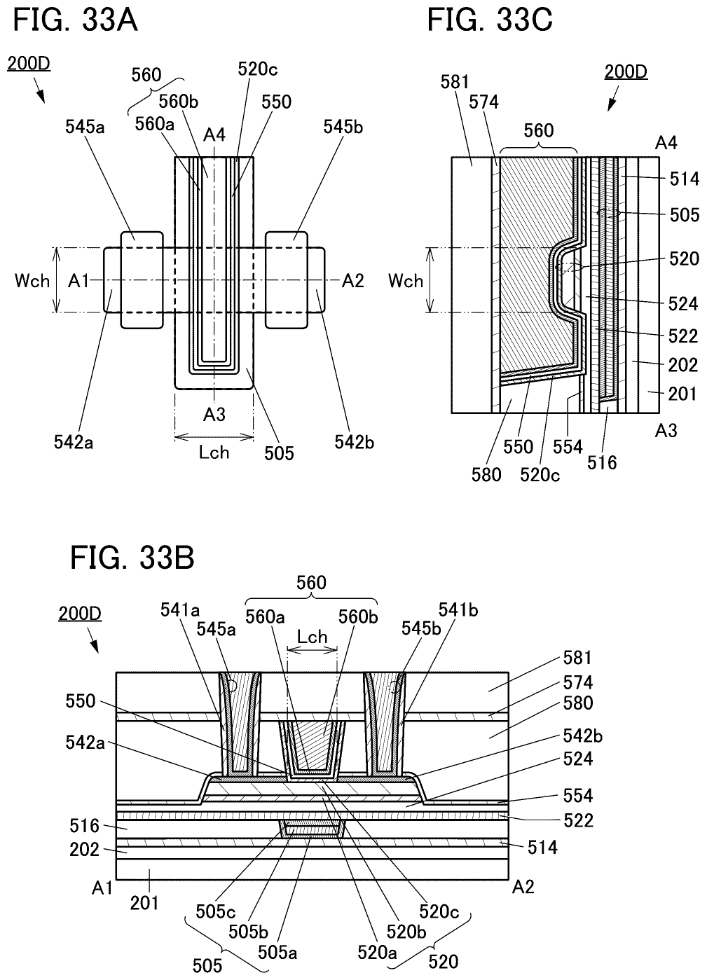

FIG. 33A is a top view of a transistor 200D. FIG. 33B is a cross-sectional view taken along dashed-dotted line A1-A2 in FIG. 33A. FIG. 33C is a cross-sectional view taken along dashed-dotted line A3-A4 in FIG. 33A. FIG. 33B is a cross-sectional view of the transistor 200D in the channel length direction, and FIG. 33C is a cross-sectional view of the transistor 200D in the channel width direction.

As illustrated in FIGS. 33A to 33C, the transistor 200D includes a semiconductor layer 520a placed over the substrate 201; a semiconductor layer 520b placed over the semiconductor layer 520a; a conductive layer 542a and a conductive layer 542b that are placed apart from each other over the semiconductor layer 520b; an insulating layer 580 that is placed over the conductive layers 542a and 542b and has an opening portion between the conductive layers 542a and 542b; a conductive layer 560 placed in the opening portion; an insulating layer 550 placed between the conductive layer 560 and each of the semiconductor layer 520b, the conductive layers 542a and 542b, and the insulating layer 580; and a semiconductor layer 520c placed between the insulating layer 550 and each of the semiconductor layer 520b, the conductive layers 542a and 542b, and the insulating layer 580. Here, as illustrated in FIGS. 33B and 33C, the top surface of the conductive layer 560 is level with the top surfaces of the insulating layer 550, the semiconductor layer 520c, and the insulating layer 580. Note that in the following description, the semiconductor layers 520a, 520b, and 520c are collectively referred to as the semiconductor layer 520 in some cases. The conductive layers 542a and 542b are collectively referred to as the conductive layer 542 in some cases.

As illustrated in FIGS. 33A to 33C, an insulating layer 554 is provided between the insulating layer 580 and each of an insulating layer 524, the semiconductor layers 520a and 520b, and the conductive layers 542a and 542b. The insulating layer 554 is in contact with the top surface and the side surface of the conductive layer 542a, the top surface and the side surface of the conductive layer 542b, side surfaces of the semiconductor layers 520a and 520b, and the top surface of the insulating layer 524.

The conductive layer 542a functions as one of a source electrode and a drain electrode of the transistor 200D. The conductive layer 542b functions as the other of the source electrode and the drain electrode of the transistor 200D. In the semiconductor layer 520, a region overlapping with the conductive layer 560 functions as a channel formation region of the transistor 200D. Thus, the conductive layer 560 functions as a gate electrode of the transistor 200D. Furthermore, the insulating layer 550 functions as a gate insulating film of the transistor 200D.

Here, the channel formation region of the transistor 200D is formed between a region functioning as one of a source region and a drain region and a region functioning as the other of the source region and the drain region in the semiconductor layer 520. Thus, the distance between the conductive layer 542a and the conductive layer 542b can be the channel length Lch of the transistor 200D (see FIGS. 33A and 33B). The length of a portion where the conductive layers 542a and 542b face each other can be the channel width Wch of the transistor 200D (see FIGS. 33A and 33C).

Note that although three layers of the semiconductor layers 520a, 520b, and 520c are stacked in the channel formation region and its vicinity in the transistor 200D, the present invention is not limited thereto. For example, a two-layer structure of the semiconductor layers 520b and 520c or a stacked-layer structure of four or more layers may be employed. Moreover, each of the semiconductor layers 520a, 520b, and 520c may have a stacked-layer structure of two or more layers.

For example, in the case where the semiconductor layer 520 is formed using an oxide semiconductor, which is a kind of metal oxide, and the semiconductor layer 520c has a stacked-layer structure of a first metal oxide and a second metal oxide over the first metal oxide, the first metal oxide may have a composition similar to that of the semiconductor layer 520b, and the second metal oxide may have a composition similar to that of the semiconductor layer 520a.

The conductive layer 560 is formed to be embedded in the opening portion formed in the insulating layer 580 and the region between the conductive layer 542a and the conductive layer 542b. Here, the conductive layer 560, the conductive layer 542a, and the conductive layer 542b are positioned in a self-aligned manner with respect to the opening portion formed in the insulating layer 580. That is, in the transistor 200D, the gate electrode can be positioned between the source electrode and the drain electrode in a self-aligned manner. Thus, the conductive layer 560 can be formed without an alignment margin, resulting in a reduction in the footprint of the transistor 200D. This can reduce the footprint of the semiconductor device. Moreover, the degree of integration of the semiconductor device can be increased.

As illustrated in FIGS. 33A to 33C, the conductive layer 560 includes a conductive layer 560a provided over the insulating layer 550 and a conductive layer 560b provided over the conductive layer 560a in the opening portion formed in the insulating layer 580. The insulating layer 550 and the conductive layer 560 are provided to be embedded in the opening portion formed in the insulating layer 580. Although the conductive layer 560 has a stacked-layer structure of two layers in the transistor 200D, the present invention is not limited thereto. For example, the conductive layer 560 may have a single-layer structure or a stacked-layer structure of three or more layers.

The transistor 200D includes the insulating layer 202 placed over the substrate 201; an insulating layer 514 placed over the insulating layer 202; an insulating layer 516 placed over the insulating layer 514; a conductive layer 505 placed to be embedded in the insulating layer 516; an insulating layer 522 placed over the insulating layer 516 and the conductive layer 505; and the insulating layer 524 placed over the insulating layer 522. The semiconductor layer 520a is placed over the insulating layer 524.

An insulating layer 574 and an insulating layer 581 functioning as interlayer films are provided over the transistor 200D. The insulating layer 574 is provided in contact with the top surfaces of the conductive layer 560, the insulating layer 550, the semiconductor layer 520c, and the insulating layer 580.

In the case where the semiconductor layer 520 is formed using an oxide semiconductor, each of the insulating layers 522, 554, and 574 may have a function of inhibiting diffusion of hydrogen (e.g., at least one of a hydrogen atom, a hydrogen molecule, and the like). For example, each of the insulating layers 522, 554, and 574 may have lower hydrogen permeability than the insulating layers 524, 550, and 580. Each of the insulating layers 522 and 554 may have a function of inhibiting diffusion of oxygen (e.g., at least one of an oxygen atom, an oxygen molecule, and the like). For example, each of the insulating layers 522 and 554 may have lower oxygen permeability than the insulating layers 524, 550, and 580. For the insulating layers 522, 554, and 574, silicon nitride or silicon nitride oxide can be used, for example.

Here, the insulating layer 524, the semiconductor layer 520, and the insulating layer 550 are separated from a layer below the insulating layer 522 and a layer above the insulating layer 574 by the insulating layer 522 and the insulating layer 574. This can inhibit excess oxygen and impurities such as hydrogen included in the layer above the insulating layer 574 and the layer below the insulating layer 522 from entering the insulating layer 524, the semiconductor layer 520, and the insulating layer 550.

In the example shown in FIG. 33B, a conductive layer 545 (a conductive layer 545a and a conductive layer 545b) that is connected to the transistor 200D and functions as a plug is provided. In the example, an insulating layer 541 (an insulating layer 541a and an insulating layer 541b) is provided in contact with the side surface of the conductive layer 545 functioning as the plug. That is, the insulating layers 541a and 541b are provided in contact with the inner walls of two opening portions formed in the insulating layers 554, 580, 574, and 581. In FIG. 33B, a first conductive layer of the conductive layer 545 is provided in contact with the side surface of the insulating layer 541 and a second conductive layer of the conductive layer 545 is provided inward from the first conductive layer.

Here, the top surface of the conductive layer 545 and the top surface of the insulating layer 581 can be substantially level with each other. Although the transistor 200D has a structure in which the first conductive layer of the conductive layer 545 and the second conductive layer of the conductive layer 545 are stacked, the present invention is not limited thereto. For example, the conductive layer 545 may have a single-layer structure or a stacked-layer structure of three or more layers.

The semiconductor layer 520b in a region that does not overlap with the conductive layer 542 sometimes has a smaller thickness than the semiconductor layer 520b in a region that overlaps with the conductive layer 542. The thin region is formed when part of the top surface of the semiconductor layer 520b is removed at the time of forming the conductive layers 542a and 542b. When a conductive film to be the conductive layer 542 is formed, a low-resistance region is sometimes formed on the top surface of the semiconductor layer 520b in the vicinity of the interface with the conductive film. In that case, removing the low-resistance region in the semiconductor layer 520b positioned between the conductive layer 542a and the conductive layer 542b can prevent formation of a channel in the region.

Next, the structure of the transistor 200D is described in detail.

The conductive layer 505 is positioned to include a region overlapping with the conductive layer 560 with the semiconductor layer 520 therebetween. Since the conductive layer 505 is provided to be embedded in the insulating layer 516, unevenness of the top surfaces of the conductive layer 505 and the insulating layer 516 can be reduced and coverage with a layer formed in a later step can be improved.

The conductive layer 505 includes a conductive layer 505a, a conductive layer 505b, and a conductive layer 505c. The conductive layer 505a is provided in contact with the bottom portion and the inner wall of an opening portion provided in the insulating layer 516. The conductive layer 505b is provided to be embedded in a depressed portion formed by the conductive layer 505a. Here, the level of the top surface of the conductive layer 505b is lower than the level of the top surface of the conductive layer 505a and the level of the top surface of the insulating layer 516. The conductive layer 505c is provided in contact with the top surface of the conductive layer 505b and the side surface of the conductive layer 505a. Here, the top surface of the conductive layer 505c is substantially level with the top surfaces of the conductive layer 505a and the insulating layer 516. That is, the conductive layer 505b is surrounded by the conductive layers 505a and 505c.

In the case where the semiconductor layer 520 is formed using an oxide semiconductor, the conductive layers 505a and 505c may be formed using a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, the conductive layers 505a and 505c may be formed using a conductive material having a function of inhibiting diffusion of oxygen (e.g., at least one of an oxygen atom, an oxygen molecule, and the like).

When the conductive layers 505a and 505c are formed using a conductive material having a function of inhibiting diffusion of hydrogen, impurities such as hydrogen included in the conductive layer 505b can be inhibited from diffusing into the semiconductor layer 520 through the insulating layer 524 and the like. When the conductive layers 505a and 505c are formed using a conductive material having a function of inhibiting diffusion of oxygen, the conductivity of the conductive layer 505b can be inhibited from being lowered because of oxidation. As the conductive material having a function of inhibiting diffusion of oxygen, for example, titanium, titanium nitride, tantalum, tantalum nitride, ruthenium, or ruthenium oxide can be used. Thus, the conductive layer 505a can be a single layer or stacked layers of the above conductive materials. For example, the conductive layer 505a can be formed using titanium nitride.

Furthermore, the conductive layer 505b may be formed using a conductive material containing tungsten, copper, or aluminum as its main component. For example, the conductive layer 505b can be formed using tungsten.

In the case where the conductive layer 560 is used as the gate electrode, the conductive layer 505 functions as a back gate electrode. The insulating layer 522 and the insulating layer 524 function as back gate insulating films.

Note that the conductive layer 505 may be used as the gate electrode. In that case, the conductive layer 560 functions as the back gate electrode. The insulating layer 522 and the insulating layer 524 function as the gate insulating films, and the insulating layer 550 functions as the back gate insulating film.

The conductive layer 505 may be more extensive than the channel formation region of the semiconductor layer 520. Specifically, as illustrated in FIG. 33C, the conductive layer 505 may extend beyond an end portion of the semiconductor layer 520 that intersects with the channel width direction. That is, the conductive layers 505 and 560 may overlap with each other with the insulating layers therebetween, in a region beyond a side surface of the semiconductor layer 520 in the channel width direction.

With the above structure, the channel formation region of the semiconductor layer 520 can be surrounded by the electric field of the conductive layer 560 functioning as the gate electrode and the electric field of the conductive layer 505 functioning as the back gate electrode.

The conductive layer 505 extending beyond the end portion of the semiconductor layer 520 may be used as a wiring. However, without limitation to this structure, a structure in which a conductive layer functioning as a wiring is provided below the conductive layer 505 may be employed.

The insulating layer 514 may be formed using an insulating material that functions as a barrier insulating film inhibiting entry of an impurity such as water or hydrogen to the transistor 200D from the substrate side. Accordingly, the insulating layer 514 may be formed using an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom, that is, an insulating material that does not easily transmit the above impurities. Alternatively, the insulating layer 514 may be formed using an insulating material having a function of inhibiting diffusion of oxygen (e.g., at least one of an oxygen atom, an oxygen molecule, and the like), that is, an insulating material that does not easily transmit oxygen.

For example, the insulating layer 514 may be formed using aluminum oxide, silicon nitride, or the like. In that case, it is possible to inhibit diffusion of an impurity such as water or hydrogen to the transistor 200D side from the substrate side through the insulating layer 514. Alternatively, it is possible to inhibit diffusion of oxygen included in the insulating layer 524 and the like to the substrate side through the insulating layer 514.

For the insulating layers 516, 580, and 581 functioning as interlayer films, an insulating material having a lower permittivity than the insulating layer 514 may be used. When a material with a low permittivity is used for the interlayer films, parasitic capacitance generated between wirings can be reduced. For example, the insulating layers 516, 580, and 581 can be formed using silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like.

Here, the insulating layer 524 in contact with the semiconductor layer 520 may include excess oxygen. For example, the insulating layer 524 can be formed using silicon oxide, silicon oxynitride, or the like. When an insulating layer including oxygen is provided in contact with the semiconductor layer 520, the amount of oxygen vacancies in the semiconductor layer 520 is reduced, whereby the reliability of the transistor 200D is improved.

As illustrated in FIG. 33C, the insulating layer 524 is sometimes thinner in a region overlapping with neither the insulating layer 554 nor the semiconductor layer 520b than in the other regions. In the insulating layer 524, the region overlapping with neither the insulating layer 554 nor the semiconductor layer 520b preferably has a thickness with which the above oxygen can be adequately diffused.

In a manner similar to that of the insulating layer 514 or the like, the insulating layer 522 may be formed using a material that functions as a barrier insulating film inhibiting entry of an impurity such as water or hydrogen to the transistor 200D from the substrate side. For example, the insulating layer 522 may be formed using a material having lower hydrogen permeability than the insulating layer 524. When the insulating layer 524, the semiconductor layer 520, the insulating layer 550, and the like are surrounded by the insulating layers 522, 554, and 574, an impurity such as water or hydrogen can be inhibited from entering the transistor 200D from the outside.

Furthermore, the insulating layer 522 may be formed using a material having a function of inhibiting diffusion of oxygen (e.g., at least one of an oxygen atom, an oxygen molecule, and the like), that is, an insulating material that does not easily transmit oxygen. For example, the insulating layer 522 may be formed using a material having lower oxygen permeability than the insulating layer 524. By having a function of inhibiting diffusion of oxygen, the insulating layer 522 can reduce oxygen diffusing from the semiconductor layer 520 to the substrate side. Moreover, the insulating layer 522 can inhibit the conductive layer 505 from reacting with oxygen included in the insulating layer 524 or the semiconductor layer 520.

As the insulating layer 522, an insulating layer including an oxide of one or both of aluminum and hafnium, which is an insulating material, may be used. Aluminum oxide, hafnium oxide, an oxide containing aluminum and hafnium (hafnium aluminate), or the like can be used for the insulating layer including an oxide of one or both of aluminum and hafnium. The insulating layer 522 formed using such a material functions as a layer that inhibits release of oxygen from the semiconductor layer 520 and entry of an impurity such as hydrogen from the periphery of the transistor 200D into the semiconductor layer 520.

Alternatively, aluminum oxide, bismuth oxide, germanium oxide, niobium oxide, silicon oxide, titanium oxide, tungsten oxide, yttrium oxide, or zirconium oxide may be added to the above insulating layers, for example. Alternatively, the above insulating layers may be subjected to nitriding treatment. A stack of silicon oxide, silicon oxynitride, or silicon nitride and any of the above insulating layers may be used. For example, a three-layer structure in which silicon nitride, silicon oxide, and aluminum oxide are stacked in this order can be used as the insulating layer 522.

The insulating layer 522 may have a single-layer structure or a stacked-layer structure of an insulating layer including a material with a high relative permittivity (high-k material) such as aluminum oxide, hafnium oxide, tantalum oxide, zirconium oxide, lead zirconate titanate (PZT), strontium titanate (SrTiO₃), or (Ba,Sr)TiO₃ (BST). As miniaturization and high integration of transistors progress, a problem such as generation of a gate leakage current may arise because of a thinner gate insulating film. When a material with a high relative permittivity is used for an insulating layer functioning as a gate insulating film, a gate potential at the time of operating the transistor can be reduced while the physical thickness of the gate insulating film is maintained.

Note that the insulating layers 522 and 574 may each have a stacked-layer structure of two or more layers. In that case, without limitation to a stacked-layer structure formed of the same material, a stacked-layer structure formed of different materials may be employed.

The semiconductor layer 520 includes the semiconductor layer 520a, the semiconductor layer 520b over the semiconductor layer 520a, and the semiconductor layer 520c over the semiconductor layer 520b. Since the semiconductor layer 520a is provided under the semiconductor layer 520b, impurities can be inhibited from diffusing into the semiconductor layer 520b from the structures formed below the semiconductor layer 520a. Since the semiconductor layer 520c is provided over the semiconductor layer 520b, impurities can be inhibited from diffusing into the semiconductor layer 520b from the structures formed above the semiconductor layer 520c.

Note that in the case where an oxide semiconductor is used for the semiconductor layer 520, the semiconductor layer 520 may have a stacked-layer structure of a plurality of oxide layers that differ in the atomic ratio of metal atoms. For example, in the case where the semiconductor layer 520 includes at least indium (In) and an element M, the proportion of the number of atoms of the element M included in the semiconductor layer 520a in the number of atoms of all the elements that constitute the semiconductor layer 520a may be higher than the proportion of the number of atoms of the element M included in the semiconductor layer 520b in the number of atoms of all the elements that constitute the semiconductor layer 520b. The atomic ratio of the element M to In in the semiconductor layer 520a may be higher than the atomic ratio of the element M to In in the semiconductor layer 520b. Here, the semiconductor layer 520c may be formed using a metal oxide that can be used for the semiconductor layer 520a or 520b.

The energy level at the conduction band minimum of each of the semiconductor layers 520a and 520c may be higher than the energy level at the conduction band minimum of the semiconductor layer 520b. In other words, the electron affinity of each of the semiconductor layers 520a and 520c may be lower than the electron affinity of the semiconductor layer 520b. In that case, a metal oxide that can be used for the semiconductor layer 520a may be used for the semiconductor layer 520c. Specifically, the proportion of the number of atoms of the element M included in the semiconductor layer 520c in the number of atoms of all the elements that constitute the semiconductor layer 520c may be higher than the proportion of the number of atoms of the element M included in the semiconductor layer 520b in the number of atoms of all the elements that constitute the semiconductor layer 520b. The atomic ratio of the element M to In in the semiconductor layer 520c may be higher than the atomic ratio of the element M to In in the semiconductor layer 520b.

The energy level at the conduction band minimum gradually changes in junction portions of the semiconductor layers 520a, 520b, and 520c. In other words, the energy level at the conduction band minimum in the junction portions of the semiconductor layers 520a, 520b, and 520c is continuously varied or continuously connected. To vary the energy level gradually, the density of defect states in each of a mixed layer formed at the interface between the semiconductor layer 520a and the semiconductor layer 520b and a mixed layer formed at the interface between the semiconductor layer 520b and the semiconductor layer 520c may be made low.

Specifically, when the semiconductor layers 520a and 520b or the semiconductor layers 520b and 520c include the same element in addition to oxygen, a mixed layer with a low density of defect states can be formed. For example, when the semiconductor layer 520b is indium-gallium-zinc oxide (In—Ga—Zn oxide), In—Ga—Zn oxide, gallium-zinc oxide (Ga—Zn oxide), gallium oxide, or the like may be used for the semiconductor layers 520a and 520c. Furthermore, the semiconductor layer 520c may have a stacked-layer structure. For example, a stacked-layer structure of In—Ga—Zn oxide and Ga—Zn oxide over the In—Ga—Zn oxide or a stacked-layer structure of In—Ga—Zn oxide and gallium oxide over the In—Ga—Zn oxide can be employed. In other words, a stacked-layer structure of In—Ga—Zn oxide and an oxide that does not contain In can be used for the semiconductor layer 520c.

Specifically, the semiconductor layer 520a may be formed using a metal oxide having an atomic ratio of In:Ga:Zn=1:3:4 or in the neighborhood thereof, or an atomic ratio of In:Ga:Zn=1:1:0.5 or in the neighborhood thereof. The semiconductor layer 520b may be formed using a metal oxide having an atomic ratio of In:Ga:Zn=4:2:3 or in the neighborhood thereof, an atomic ratio of In:Ga:Zn=3:1:2 or in the neighborhood thereof, or an atomic ratio of In:Ga:Zn=1:1:1 or in the neighborhood thereof. The semiconductor layer 520c may be formed using a metal oxide having an atomic ratio of In:Ga:Zn=1:3:4 or in the neighborhood thereof, an atomic ratio of In:Ga:Zn=4:2:3 or in the neighborhood thereof, an atomic ratio of Ga:Zn=2:1 or in the neighborhood thereof, or an atomic ratio of Ga:Zn=2:5 or in the neighborhood thereof. Furthermore, specific examples of the semiconductor layer 520c having a stacked-layer structure include a stacked-layer structure of a layer having an atomic ratio of In:Ga:Zn=4:2:3 or in the neighborhood thereof and a layer having an atomic ratio of Ga:Zn=2:1 or in the neighborhood thereof, a stacked-layer structure of a layer having an atomic ratio of In:Ga:Zn=4:2:3 or in the neighborhood thereof and a layer having an atomic ratio of Ga:Zn=2:5 or in the neighborhood thereof, and a stacked-layer structure of a layer having an atomic ratio of In:Ga:Zn=4:2:3 or in the neighborhood thereof and gallium oxide.

In that case, the semiconductor layer 520b serves as a main carrier path. When the semiconductor layers 520a and 520c have the above structures, the density of defect states at the interface between the semiconductor layers 520a and 520b and the interface between the semiconductor layers 520b and 520c can be made low. This reduces the influence of interface scattering on carrier conduction, and the transistor 200D can have a high on-state current and high frequency characteristics. Note that in the case where the semiconductor layer 520c has a stacked-layer structure, not only is the density of defect states at the interface between the semiconductor layers 520b and 520c reduced, but also diffusion of the constituent elements of the semiconductor layer 520c to the insulating layer 550 side can be inhibited. Specifically, since the semiconductor layer 520c has a stacked-layer structure in which the upper layer is an oxide that does not contain In, the amount of In that would diffuse to the insulating layer 550 side can be reduced. Since the insulating layer 550 functions as the gate insulating film, the transistor would show poor characteristics when In diffuses into the insulating layer 550. Thus, the semiconductor layer 520c having a stacked-layer structure allows the semiconductor device to have high reliability.

The conductive layer 542 (the conductive layers 542a and 542b) functioning as the source electrode and the drain electrode is provided over the semiconductor layer 520b. In the case where the semiconductor layer 520b is formed using an oxide semiconductor, the conductive layer 542 may be formed using a conductive material that is less likely to be oxidized or a conductive material that maintains its conductivity even after absorbing oxygen.

A region of the semiconductor layer 520 that is in contact with the conductive layer 542 functions as the source region or the drain region of the transistor 200D. Here, the region between the conductive layers 542a and 542b is formed to overlap with the opening portion formed in the insulating layer 580. Accordingly, the conductive layer 560 can be formed in a self-aligned manner between the conductive layers 542a and 542b.

The insulating layer 550 functions as the gate insulating film. The insulating layer 550 is provided in contact with the top surface of the semiconductor layer 520c. The insulating layer 550 can be formed using silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. For example, the insulating layer 550 can be formed using silicon oxide or silicon oxynitride.

Like the insulating layer 524, the insulating layer 550 may be formed using an insulating material with a reduced concentration of an impurity such as water or hydrogen. The thickness of the insulating layer 550 may be greater than or equal to 1 nm and less than or equal to 20 nm.

A metal oxide may be provided between the insulating layer 550 and the conductive layer 560. The metal oxide inhibits diffusion of oxygen from the insulating layer 550 to the conductive layer 560. Thus, oxidation of the conductive layer 560 due to oxygen included in the insulating layer 550 can be inhibited.

Although the conductive layer 560 has a two-layer structure in FIGS. 33A to 33C, the conductive layer 560 may have a single-layer structure or a stacked-layer structure of three or more layers.

The conductive layer 560a may be formed using a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, the conductive layer 560a may be formed using a conductive material having a function of inhibiting diffusion of oxygen (e.g., at least one of an oxygen atom, an oxygen molecule, and the like).

When the conductive layer 560a has a function of inhibiting diffusion of oxygen, the conductivity of the conductive layer 560b can be inhibited from being lowered because of oxidation due to oxygen included in the insulating layer 550. As the conductive material having a function of inhibiting diffusion of oxygen, for example, tantalum, tantalum nitride, ruthenium, or ruthenium oxide can be used.

The conductive layer 560b may be formed using a conductive material containing tungsten, copper, or aluminum as its main component. The conductive layer 560 also functions as a wiring and thus may have high conductivity. The conductive layer 560b may have a stacked-layer structure, for example, a stacked-layer structure of titanium or titanium nitride and the above conductive material.

As illustrated in FIGS. 33B and 33C, the side surface of the semiconductor layer 520 is covered with the conductive layer 560 in a region of the semiconductor layer 520b that does not overlap with the conductive layer 542, i.e., the channel formation region of the semiconductor layer 520. Accordingly, the electric field of the conductive layer 560 functioning as the gate electrode of the transistor 200D easily acts on the side surface of the semiconductor layer 520. Hence, the transistor 200D can have a higher on-state current and higher frequency characteristics.

In a manner similar to that of the insulating layer 514 or the like, the insulating layer 554 may be formed using an insulating material that inhibits entry of an impurity such as water or hydrogen into the transistor 200D. For example, the insulating layer 554 may be formed using an insulating material having lower hydrogen permeability than the insulating layer 524. Furthermore, as illustrated in FIGS. 33B and 33C, the insulating layer 554 is provided in contact with the side surface of the semiconductor layer 520c, the top surface and the side surface of the conductive layer 542a, the top surface and the side surface of the conductive layer 542b, the side surfaces of the semiconductor layers 520a and 520b, and the top surface of the insulating layer 524. Such a structure can inhibit entry of hydrogen included in the insulating layer 580 into the semiconductor layer 520.

Furthermore, the insulating layer 554 may be formed using an insulating material having a function of inhibiting diffusion of oxygen (e.g., at least one of an oxygen atom, an oxygen molecule, and the like), that is, an insulating material that does not easily transmit oxygen. For example, the insulating layer 554 may be formed using an insulating material having lower oxygen permeability than the insulating layer 580 or the insulating layer 524.

In the case where the semiconductor layer 520 is formed using an oxide semiconductor, the insulating layer 554 may be formed by a sputtering method. When the insulating layer 554 is formed by a sputtering method in an oxygen-containing atmosphere, oxygen can be added to the vicinity of a region of the insulating layer 524 that is in contact with the insulating layer 554. Thus, oxygen can be supplied from the region into the semiconductor layer 520 through the insulating layer 524. Here, with the insulating layer 554 having a function of inhibiting upward oxygen diffusion, oxygen can be prevented from diffusing from the semiconductor layer 520 into the insulating layer 580. Moreover, with the insulating layer 522 having a function of inhibiting downward oxygen diffusion, oxygen can be prevented from diffusing from the semiconductor layer 520 toward the substrate. In the above manner, oxygen is supplied to the channel formation region of the semiconductor layer 520. Accordingly, oxygen vacancies in the semiconductor layer 520 can be reduced, so that the transistor can be prevented from having normally-on characteristics.

As the insulating layer 554, for example, an insulating layer including an oxide of one or both of aluminum and hafnium may be formed. Aluminum oxide, hafnium oxide, an oxide containing aluminum and hafnium (hafnium aluminate), or the like can be used for the insulating layer including an oxide of one or both of aluminum and hafnium.

The insulating layer 580 is provided over the insulating layer 524, the semiconductor layer 520, and the conductive layer 542 with the insulating layer 554 therebetween. For example, the insulating layer 580 can be formed using silicon oxide, silicon oxynitride, silicon nitride oxide, silicon oxide to which fluorine is added, silicon oxide to which carbon is added, silicon oxide to which carbon and nitrogen are added, porous silicon oxide, or the like. Silicon oxide and silicon oxynitride are particularly preferable because of their thermal stability. In particular, materials such as silicon oxide, silicon oxynitride, and porous silicon oxide are preferably used, in which case a region including oxygen that is released by heating can be easily formed.

In a manner similar to that of the insulating layer 514 or the like, the insulating layer 574 may be formed using an insulating material that functions as a barrier insulating film inhibiting entry of an impurity such as water or hydrogen from above into the insulating layer 580. For the insulating layer 574, an insulating material that can be used for the insulating layer 514, the insulating layer 554, and the like may be used, for example.

In the example shown in FIGS. 33A to 33C, the insulating layer 581 functioning as the interlayer film is provided over the insulating layer 574. In a manner similar to that of the insulating layer 524 or the like, the insulating layer 581 may be formed using an insulating material with a reduced concentration of an impurity such as water or hydrogen.

The conductive layers 545a and 545b are provided in the two opening portions formed in the insulating layers 581, 574, 580, and 554. The conductive layers 545a and 545b are provided to face each other with the conductive layer 560 therebetween. Note that the top surfaces of the conductive layers 545a and 545b may be level with the top surface of the insulating layer 581.

The insulating layer 541a is provided in contact with the inner wall of one of the two opening portions formed in the insulating layers 581, 574, 580, and 554, and the first conductive layer of the conductive layer 545a is formed in contact with the side surface of the insulating layer 541a. The conductive layer 542a is positioned on at least part of the bottom portion of the opening portion, and the conductive layer 545a is in contact with the conductive layer 542a. Similarly, the insulating layer 541b is provided in contact with the inner wall of the other of the two opening portions formed in the insulating layers 581, 574, 580, and 554, and the first conductive layer of the conductive layer 545b is formed in contact with the side surface of the insulating layer 541b. The conductive layer 542b is positioned on at least part of the bottom portion of the opening portion, and the conductive layer 545b is in contact with the conductive layer 542b.

The conductive layers 545a and 545b may be formed using a conductive material containing tungsten, copper, or aluminum as its main component. The conductive layers 545a and 545b may each have a stacked-layer structure of two or more layers.

In the case where the conductive layer 545 has a stacked-layer structure, a conductive layer having a function of inhibiting diffusion of an impurity such as water or hydrogen may be used as the conductive layer in contact with the semiconductor layers 520a and 520b, the conductive layer 542, and the insulating layers 554, 580, 574, and 581. For example, tantalum, tantalum nitride, titanium, titanium nitride, ruthenium, ruthenium oxide, or the like can be used. The use of the conductive material can inhibit oxygen included in the insulating layer 580 from being absorbed by the conductive layers 545a and 545b. Moreover, an impurity such as water or hydrogen can be inhibited from entering the semiconductor layer 520 through the conductive layers 545a and 545b from a layer above the insulating layer 581.

As each of the insulating layers 541a and 541b, for example, an insulating layer that can be used as the insulating layer 554 or the like may be used. Since the insulating layers 541a and 541b are provided in contact with the insulating layer 554, an impurity such as water or hydrogen from the insulating layer 580 or the like can be inhibited from entering the semiconductor layer 520 through the conductive layers 545a and 545b. Furthermore, oxygen included in the insulating layer 580 can be inhibited from being absorbed by the conductive layers 545a and 545b.

### <Structure Example 5 of Transistor>

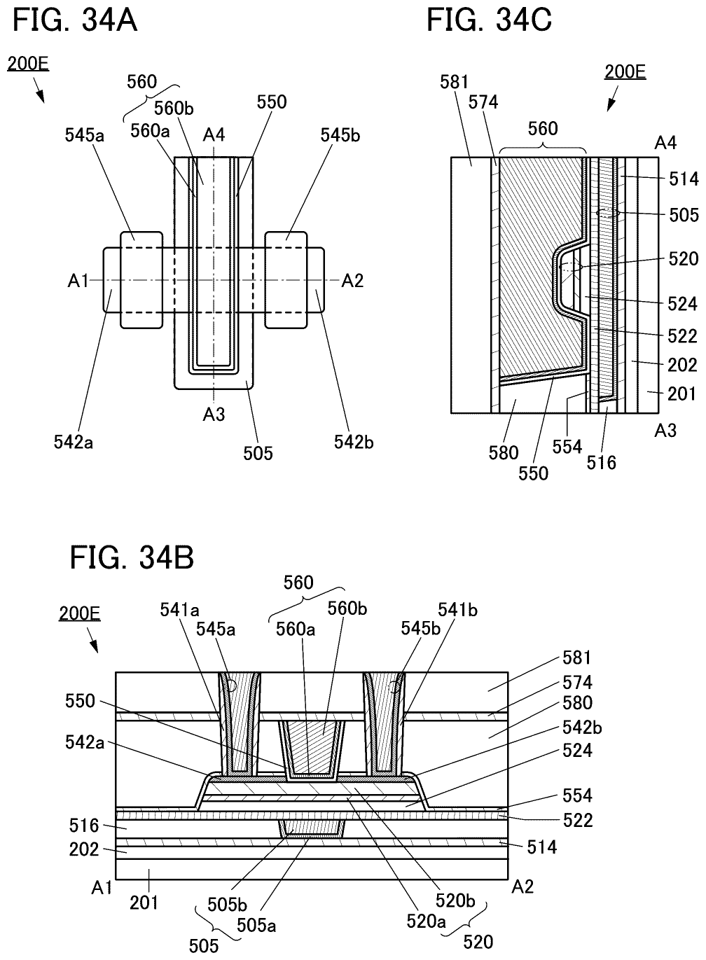

FIGS. 34A to 34C illustrate a variation example of the transistor 200D shown in FIGS. 33A to 33C. FIG. 34A is a top view of a transistor 200E, which is a variation example of the transistor 200D. FIG. 34B is a cross-sectional view taken along dashed-dotted line A1-A2 in FIG. 34A. FIG. 34C is a cross-sectional view taken along dashed-dotted line A3-A4 in FIG. 34A. The transistor 200E is a variation example of the transistor 200D; thus, differences of the transistor 200E from the transistor 200D are mainly described.

The transistor 200E has the structure of the transistor 200D from which the semiconductor layer 520c and the conductive layer 505c are omitted. A reduction in the number of components of the transistor can reduce the manufacturing cost. Furthermore, a reduction in the number of components of the transistor shortens the manufacturing process, improving the manufacturing yield.

In the transistor 200E, the insulating layer 554 and the insulating layer 522 are in contact with each other in a region outside the semiconductor layer 520, and the side surface of the insulating layer 524 is covered with the insulating layer 554. In the case where the semiconductor layer 520 is formed using an oxide semiconductor, covering the side surface of the insulating layer 524 with the insulating layer 554 can prevent not only diffusion of oxygen from the semiconductor layer 520 to the outside through the insulating layer 524 but also excessive supply of oxygen from the insulating layer 524 side to the semiconductor layer 520.

An insulating layer may be provided between the insulating layer 550 and each of the insulating layers 580 and 554, the conductive layer 542, and the semiconductor layer 520b. The insulating layer can be formed using aluminum oxide, hafnium oxide, or the like. Providing the insulating layer can inhibit release of oxygen from the semiconductor layer 520 to the insulating layer 550 side, excessive supply of oxygen from the insulating layer 550 side to the semiconductor layer 520, oxidation of the conductive layer 542, and the like.

### <Constituent Materials of Transistor>

Next, constituent materials that can be used for the transistor 200 (the transistor 200A, the transistor 200B, the transistor 200C, the transistor 200D, and the transistor 200E) are described.

### [Substrate]

In the case where the transistor is provided over a substrate, there is no particular limitation on a material used for the substrate. The material used for the substrate can be determined in accordance with the purpose considering whether it has a light-transmitting property, heat resistance high enough to withstand heat treatment, and the like. As the substrate, an insulator substrate, a semiconductor substrate, or a conductor substrate may be used, for example. As the insulator substrate, a glass substrate of barium borosilicate glass, aluminoborosilicate glass, or the like, a ceramic substrate, a quartz substrate, a sapphire substrate, or a stabilized zirconia substrate (e.g., an yttria-stabilized zirconia substrate) can be used, for example. Alternatively, a semiconductor substrate, a flexible substrate, a resin substrate, or the like may be used as the substrate.

Examples of the semiconductor substrate include a semiconductor substrate including a material such as silicon or germanium and a compound semiconductor substrate including a material such as silicon carbide, silicon germanium, gallium arsenide, indium phosphide, zinc oxide, or gallium oxide. Other examples include the above semiconductor substrates provided with an insulator region, such as a silicon on insulator (SOI) substrate. The semiconductor substrate may be a single crystal semiconductor or a polycrystalline semiconductor.

Examples of the conductor substrate include a graphite substrate, a metal substrate, an alloy substrate, and a conductive resin substrate. Other examples include a substrate including a nitride of a metal and a substrate including an oxide of a metal. Other examples include an insulator substrate provided with a conductive layer or a semiconductor layer, a semiconductor substrate provided with a conductive layer or an insulating layer, and a conductor substrate provided with a semiconductor layer or an insulating layer.

For the material of the flexible substrate, the resin substrate, or the like, a polyester such as polyethylene terephthalate (PET) or polyethylene naphthalate (PEN), polyacrylonitrile, an acrylic resin, polyimide, polymethyl methacrylate, polycarbonate (PC), polyethersulfone (PES), a polyamide (e.g., nylon or aramid), polysiloxane, a cycloolefin resin, polystyrene, polyamide-imide, polyurethane, polyvinyl chloride, polyvinylidene chloride, polypropylene, polytetrafluoroethylene (PTFE), an ABS resin, or cellulose nanofiber can be used, for example.

When any of the above-described materials is used for the substrate, a lightweight semiconductor device can be provided. Furthermore, with the use of any of the materials described above for the substrate, a shock-resistant semiconductor device can be provided. Furthermore, with the use of any of the materials described above for the substrate, a semiconductor device that is less likely to be broken can be provided. Alternatively, these substrates provided with elements may be used. Examples of the element provided over the substrate include a capacitor, a resistor, a switching element, a light-emitting element, and a memory element.

### [Insulating Layer]

An inorganic insulating film can be used for each of the insulating layers (e.g., the insulating layers 202, 204, 206, 209, 257, 258, 259, 264, 266, 516, 522, 524, 541, 554, 580, 574, and 581). Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

Note that in this specification and the like, an oxynitride refers to a material in which the oxygen content is higher than the nitrogen content, and a nitride oxide refers to a material in which the nitrogen content is higher than the oxygen content. For example, silicon oxynitride refers to a material in which the oxygen content is higher than the nitrogen content, and silicon nitride oxide refers to a material in which the nitrogen content is higher than the oxygen content. Note that the content of each element can be measured by Rutherford backscattering spectrometry (RBS), for example.

As miniaturization and high integration of transistors progress, for example, a problem such as generation of a gate leakage current may arise because of a thinner gate insulating film. When a material with a high relative permittivity (high-k material) is used for an insulating layer functioning as a gate insulating film, such as the insulating layer 204 or the insulating layer 202, the voltage at the time of operation of the transistor can be reduced while the physical thickness is maintained. In addition, the equivalent oxide thickness (EOT) of the gate insulating film can be reduced. When a material with a high relative permittivity is used for an insulating layer functioning as a dielectric of a capacitor, the capacitance per unit area can be increased. By contrast, when a material with a low relative permittivity is used for an insulating layer functioning as an interlayer film, parasitic capacitance generated between wirings can be reduced. Thus, a material can be selected depending on the function of an insulating layer. Note that a material with a low relative permittivity is a material with high dielectric strength.

Examples of a material with a high relative permittivity include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low relative permittivity include inorganic insulating materials such as silicon oxide, silicon oxynitride, and silicon nitride oxide, and resins such as a polyester, a polyolefin, a polyamide (e.g., nylon and aramid), polyimide, polycarbonate, and an acrylic resin. Other examples of an inorganic insulating material with a low relative permittivity include silicon oxide to which fluorine is added, silicon oxide to which carbon is added, and silicon oxide to which carbon and nitrogen are added. Another example is porous silicon oxide. Note that these silicon oxides may contain nitrogen.

### [Conductive Layer]

For each of the conductive layers (e.g., the conductive layers 205, 208, 219, 255, 261, 265, 505, 545, and 560) included in the transistor 200, it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high conductivity, typified by polycrystalline silicon containing an impurity element such as phosphorus, or silicide such as nickel silicide may be used.

It is preferable to use a conductive material that is less likely to be oxidized, a conductive material having a function of inhibiting diffusion of oxygen, or a material that maintains its conductivity even after absorbing oxygen. Examples of such a material include a conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum. Other examples include a conductive material containing oxygen, such as ruthenium oxide, an oxide containing strontium and ruthenium, or an oxide containing lanthanum and nickel. Another example is a material containing a metal element such as titanium, tantalum, or ruthenium. Examples of the conductive material containing oxygen include a material containing tungsten oxide and indium oxide, a material containing titanium oxide and indium oxide, indium tin oxide (also referred to as ITO), indium tin oxide containing titanium oxide, indium tin oxide containing silicon oxide (also referred to as ITSO), indium zinc oxide (also referred to as IZO (a registered trademark)), and indium zinc oxide containing tungsten oxide. In this specification and the like, a conductive layer formed using the conductive material containing oxygen may be referred to as an oxide conductive layer.

Furthermore, as a material having high conductivity, a conductive material containing tungsten, copper, or aluminum as its main component is preferably used.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

For example, in the case where the semiconductor layer 203 of the transistor 200A or 200B is formed using an oxide semiconductor, which is a kind of metal oxide, the conductive layers functioning as the gate electrodes such as the conductive layers 205 and 219 may each have a stacked-layer structure combining a material containing any of the above metal elements and a conductive material containing oxygen. In that case, the conductive material containing oxygen may be provided on the semiconductor layer 203 side. By providing the conductive material containing oxygen on the semiconductor layer 203 side, oxygen released from the conductive material is easily supplied to the channel formation region of the semiconductor layer 203.

In the case where the semiconductor layers 203, 263, and 520 are formed using an oxide semiconductor, which is a kind of metal oxide, the conductive layers 208a, 208b, 255, 261, 542a, and 542b, which are in contact with the semiconductor layers 203, 263, and 520, may be formed using a conductive material that is not easily oxidized, a conductive material that maintains low electrical resistance even after being oxidized, a conductive metal oxide (also referred to as an oxide conductor), or a conductive material having a function of inhibiting diffusion of oxygen. Examples of the conductive materials include a conductive material containing nitrogen and a conductive material containing oxygen. This can inhibit a reduction in the conductivity of each of the conductive layers 208a, 208b, 255, 261, 542a, and 542b.

The conductive layers 208a, 208b, 255, 261, 542a, and 542b formed using a conductive material containing oxygen can maintain their conductivity even after absorbing oxygen. This is preferable because the conductive layers 208a, 208b, 255, 261, 542a, and 542b can maintain their conductivity even in the case where they are in contact with an insulating layer including excess oxygen, for example. The conductive layers 208a, 208b, 255, 261, 542a, and 542b can each be formed using ITO, ITSO, or IZO (registered trademark), for example.

### [Semiconductor Layer]

For each of the semiconductor layers (e.g., the semiconductor layers 203, 263, and 520), a single-crystal semiconductor, a polycrystalline semiconductor, a microcrystalline semiconductor, an amorphous semiconductor, or the like can be used alone or in combination.

A single-element semiconductor or a compound semiconductor may be used for the semiconductor layers. Examples of the single-element semiconductor include silicon and germanium. Examples of the compound semiconductor include gallium arsenide, silicon carbide, and silicon germanium. Other examples of the compound semiconductor include an organic semiconductor and a nitride semiconductor. Note that an oxide semiconductor is also a kind of compound semiconductor. These semiconductor materials may contain an impurity as a dopant.

In the case where silicon is used for the semiconductor layers, examples of silicon that can be used for the semiconductor layers include single crystal silicon, polycrystalline silicon, microcrystalline silicon, and amorphous silicon. An example of polycrystalline silicon is low-temperature polysilicon (LTPS).

When silicon is used for the semiconductor layer 203 and phosphorus or arsenic is included as an n-type dopant in the regions 203a and 203c of the semiconductor layer 203 in the transistor 200A or 200B, for example, the transistor can function as an n-channel transistor. When boron is included as a p-type dopant in the regions 203a and 203c in the semiconductor layer 203, the transistor can function as a p-channel transistor. Note that in the case where both an n-type dopant and a p-type dopant are included in the regions 203a and 203c of the semiconductor layer 203, the conductive type of the dopant having a higher concentration is likely to be exhibited.

Alternatively, the semiconductor layers may be formed using a two-dimensional material functioning as a semiconductor. The two-dimensional material, which is also referred to as a layered material, generally refers to a group of materials having a layered crystal structure. In the layered crystal structure, layers formed by covalent bonding or ionic bonding are stacked with bonding such as the van der Waals binding, which is weaker than covalent bonding or ionic bonding. The layered material has high conductivity in a unit layer, that is, high two-dimensional conductivity. When a material that functions as a semiconductor and has high two-dimensional conductivity is used for the semiconductor layers, the transistors can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for the semiconductor layers include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

For the semiconductor layers, an oxide semiconductor, which is a kind of metal oxide, may be used, for example. In that case, the band gap of the metal oxide is preferably greater than or equal to 2.0 eV, further preferably greater than or equal to 2.5 eV. The use of such a metal oxide having a wide band gap for the semiconductor layers can significantly reduce the amounts of the off-state currents of the transistors. The off-state current of an OS transistor is low, so that power consumption of the semiconductor device can be reduced.

It is preferable that a channel formation region of a transistor including an oxide semiconductor in a semiconductor layer contain less oxygen vacancies or have a lower impurity concentration (e.g., concentration of hydrogen, nitrogen, and a metal element) than a source region and a drain region. In some cases, V_{O}H (a defect in which hydrogen enters an oxygen vacancy) is formed with hydrogen in the vicinity of an oxygen vacancy and an electron serving as a carrier is generated; therefore, it is also preferable that the amount of V_{O}H be small. Thus, the channel formation region of the transistor is a high-resistance region having a low carrier concentration. Accordingly, the channel formation region of the transistor can be regarded as an i-type (intrinsic) or substantially i-type region.

The source region and the drain region of the transistor preferably include more oxygen vacancies, include more V_{O}H, or have a higher impurity concentration than the channel formation region. Thus, the source region and the drain region of the transistor are n-type regions having higher carrier concentrations and lower resistances than the channel formation region.

Note that an oxide semiconductor will be described later in detail in Embodiment 3.

An appropriate combination of the descriptions in this embodiment can be implemented. An appropriate combination of a description in this embodiment and a description in any of the other embodiments or the like can be implemented.

### Embodiment 3

In this embodiment, an oxide semiconductor layer that can be used as a semiconductor layer of a transistor of one embodiment of the present invention will be described.

### <Oxide Semiconductor Layer>

It is preferable that the oxide semiconductor layer include a metal oxide having crystallinity. Examples of the structure of a metal oxide having crystallinity include a c-axis aligned crystalline (CAAC) structure, a polycrystalline structure, and a nano-crystalline (nc) structure. By using a metal oxide having crystallinity for the oxide semiconductor layer, the density of defect states in the oxide semiconductor layer can be reduced. Thus, the reliability of a transistor including the oxide semiconductor layer can be increased, and the reliability of a semiconductor device including the transistor can be increased.

It is particularly preferable that the oxide semiconductor layer include a metal oxide having a CAAC structure. The CAAC structure is a crystal structure in which a plurality of microcrystals (typically, a plurality of microcrystals each having a hexagonal crystal structure) have c-axis alignment and are connected on the a-b plane without alignment. In cross-sectional observation of an oxide semiconductor layer having the CAAC structure with use of a high-resolution transmission electron microscope (TEM) image, metal atoms are observed to be arranged in a layered manner in a crystal part. Thus, the oxide semiconductor layer having the CAAC structure can also be referred to as a structure including the layered crystal parts.

The crystallinity of the oxide semiconductor layer can be analyzed by X-ray diffraction (XRD), TEM, or electron diffraction (ED), for example. Alternatively, two or more of these methods may be combined for the analysis.

Note that there is no particular limitation on the crystallinity of a semiconductor material included in the oxide semiconductor layer. The oxide semiconductor layer sometimes includes, for example, at least one of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including crystal regions). The oxide semiconductor layer having crystallinity can inhibit deterioration of the transistor characteristics in some cases.

Examples of a metal oxide include indium oxide, gallium oxide, and zinc oxide. The metal oxide preferably contains at least indium (In). The metal oxide preferably contains at least indium (In) or zinc (Zn). The metal oxide preferably contains two or three selected from indium, the element M, and zinc. The element M is a metal element or a metalloid element that has a high binding energy with oxygen and is, for example, a metal element or a metalloid element whose binding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, and still further preferably gallium. When the element M is gallium, the metal oxide preferably includes one or more selected from indium, gallium, and zinc. In this specification and the like, a metal element and a metalloid element may be collectively referred to as a “metal element”, and a “metal element” in this specification and the like may refer to a metalloid element.

Examples of the metal oxide include indium oxide. As the metal oxide, for example, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (also referred to as In—Ga—Sn oxide or IGTO), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to In—Sn—Zn oxide), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, or IAGZO) can be used. Alternatively, indium tin oxide containing silicon oxide (also referred to as ITSO), gallium tin oxide (Ga—Sn oxide), aluminum tin oxide (Al—Sn oxide), or the like can be used.

By increasing the proportion of the number of indium atoms (also referred to as indium (In) content percentage) in the total number of atoms of all the metal elements included in the metal oxide, a high on-state current and high frequency characteristics of the transistor can be achieved.

Instead of indium, the metal oxide may contain one or more of metal elements whose period number in the periodic table is large. Alternatively, in addition to indium, the metal oxide may contain one or more of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more selected from nonmetallic elements. A transistor including the metal oxide including a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed and the transistor can have high reliability.

By increasing the proportion of the number of element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, changes in the electrical characteristics of the transistor can be reduced to improve the reliability of the transistor.

In the description of this embodiment, In—Ga—Zn oxide is sometimes taken as an example of the metal oxide.

### [Fabrication Method]

The oxide semiconductor layer can be formed by forming a metal oxide using one kind of film formation method, or can be formed by forming a metal oxide using at least two kinds of film formation methods. For example, the oxide semiconductor layer can be formed by forming a metal oxide using a first film formation method or a second film formation method, or by forming a metal oxide using the first film formation method and the second film formation method. Note that the oxide semiconductor layer formed by using at least two kinds of film formation methods may be referred to as a hybrid OS.

The oxide semiconductor layer can be formed in the following manner: a metal oxide is formed as a first layer by a first film formation method, and then a metal oxide is formed as a second layer over the first layer by a second film formation method. In that case, as the first film formation method, a film formation method that causes less damage to the formation surface than the second film formation method is preferably used. When a film formation method that causes less damage to the formation surface is used as the first film formation method, formation of a mixed layer at an interface between the oxide semiconductor layer and a layer serving as the formation surface of the oxide semiconductor layer can be inhibited. Moreover, entry of impurities such as silicon into the second layer can be inhibited, so that the crystallinity of the oxide semiconductor layer can be increased.

Examples of the first film formation method include an atomic layer deposition (ALD) method, a chemical vapor deposition (CVD) method, a molecular beam epitaxy (MBE) method, and a wet process. Examples of the CVD method include a plasma enhanced CVD (PECVD) method, a thermal CVD method, a photo CVD method, and a metal organic CVD (MOCVD) method. Examples of the wet process include a spray coating method. An ALD method and a CVD method are suitable as the first film formation method because they cause less damage to the formation surface than a sputtering method described later.

Examples of the ALD method include a thermal ALD method, in which a precursor and a reactant react with each other only by thermal energy, and a plasma-enhanced ALD (PEALD) method, in which a reactant excited by plasma is used.

An ALD method enables atomic layers to be deposited one by one, and has advantages such as formation of an extremely thin film, formation of a film on a component with a high aspect ratio, formation of a film on a surface with a large step, formation of a film with few defects such as pinholes, formation of a film with excellent coverage, and low-temperature film formation. In a PEALD method, the use of plasma is sometimes preferable for lower-temperature film formation. Note that some precursors used in an ALD method contain an element such as carbon or chlorine. Thus, a film formed by the ALD method sometimes includes an element such as carbon or chlorine in a larger quantity than a film formed by another film formation method. Note that these elements can be quantified by X-ray photoelectron spectroscopy (XPS) or secondary ion mass spectrometry (SIMS). An ALD method employing one or both of a film formation condition with a high substrate temperature and impurity removal treatment can sometimes form a film with smaller amounts of carbon and chlorine than an ALD method without the film formation condition with a high substrate temperature or the impurity removal treatment.

Unlike in a film formation method in which particles ejected from a target or the like are deposited, a film is formed by reaction at a surface of an object to be processed in an ALD method. Thus, an ALD method can provide good step coverage, almost regardless of the shape of an object to be processed. In particular, an ALD method allows excellent step coverage and excellent thickness uniformity and can be suitably used to cover a surface of an opening portion with a high aspect ratio, for example.

A high-quality film can be obtained at a relatively low temperature through a plasma CVD method. A thermal CVD method does not use plasma and thus causes less plasma damage to an object to be processed. A thermal CVD method does not cause plasma damage during film formation, so that a film with few defects can be obtained.

Examples of the second film formation method include a sputtering method and a pulsed laser deposition (PLD) method. The metal oxide formed by the second film formation method is likely to have the CAAC structure.

Here, as the first layer, for example, a metal oxide with a microcrystalline structure or an amorphous structure that has lower crystallinity than the CAAC structure is sometimes formed. Even in such a case, formation of the second layer having high crystallinity (e.g., CAAC) over the first layer having low crystallinity or formation of the first and second layers followed by heat treatment can increase the crystallinity of the first layer using the second layer as a nucleus. Accordingly, the crystallinity can be increased in the whole oxide semiconductor layer including the vicinity of the interface with the formation surface.

Furthermore, a third layer can be formed over the second layer. Since the second layer has high crystallinity, the crystal growth of the third layer can be achieved with the use of the crystal of the second layer as a nucleus or a seed. Thus, the third layer can be crystallized even when a film formation method that easily gives crystallinity is not used as the film formation method of the third layer. Here, for example, when a film formation method that gives higher coverage than that of the second layer is employed for formation of the third layer, the whole oxide semiconductor layer can have both high crystallinity and high coverage.

For example, the oxide semiconductor layer can be formed in the following manner: a metal oxide is formed as the first layer by the first film formation method, a metal oxide is formed as the second layer by the second film formation method, and a metal oxide is formed as the third layer by the first film formation method. Specifically, an ALD method can be used as the first film formation method, and a sputtering method can be used as the second film formation method. An ALD method is a film formation method that achieves higher coverage than a sputtering method, and when an ALD method is used as the film formation method of the first layer and the third layer, the coverage with the oxide semiconductor layer can be improved. Thus, the oxide semiconductor layer can favorably cover a step, an opening portion, or the like with a high aspect ratio.

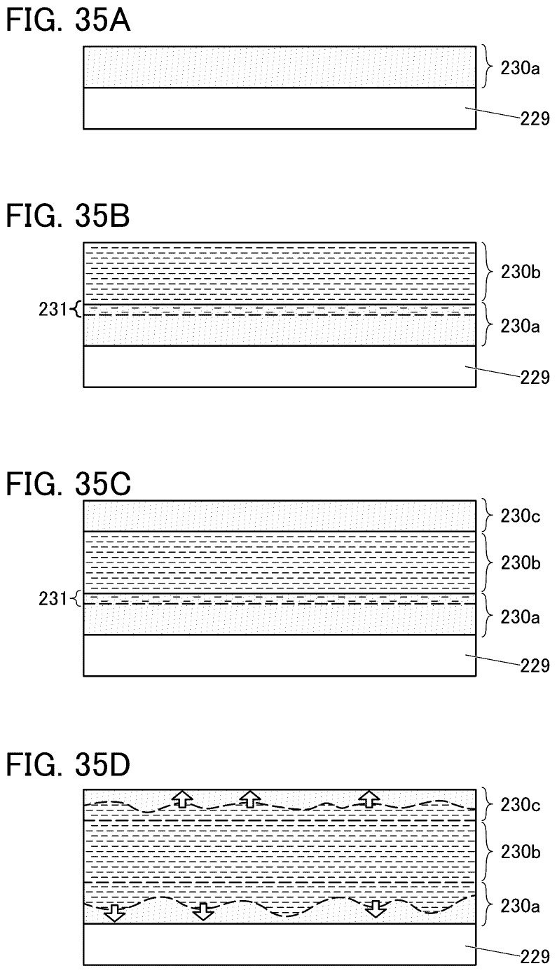

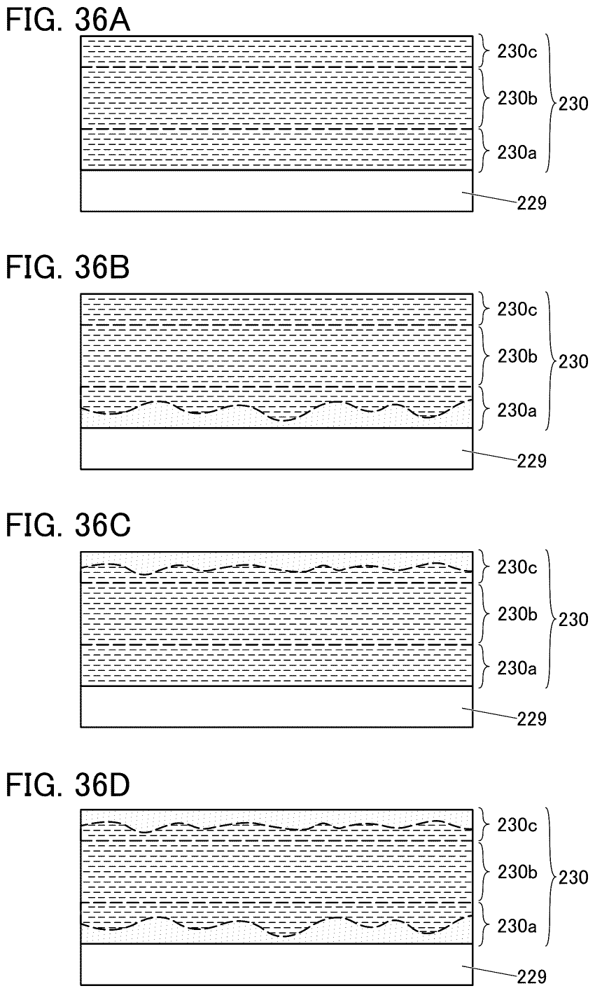

An example of a method for forming a semiconductor layer 230 is described with reference to FIGS. 35A to 35D and FIGS. 36A to 36D.

In the case where a metal oxide film is formed by a sputtering method, damage to the formation surface due to, for example, sputtered particles or energy applied to the substrate side by sputtered particles or the like might cause alloying of a component included in the metal oxide film with a component included in the layer serving as the formation surface. In the case where the alloying occurs, it is difficult to increase the crystallinity of the alloyed region even when heat treatment described later is performed. When an oxide semiconductor layer including the alloyed region is used for a transistor, the initial characteristics or reliability of the transistor might be adversely affected. Therefore, it is preferable to inhibit the alloying of the component included in the metal oxide film with the component included in the layer serving as the formation surface.

Thus, first, a semiconductor layer 230a is formed over a layer 229 by an ALD method (FIG. 35A). Next, a semiconductor layer 230b is formed over the semiconductor layer 230a by a sputtering method (FIG. 35B).

In the formation method of the oxide semiconductor layer described in this embodiment, the semiconductor layer 230a is formed between the semiconductor layer 230b and the layer 229 by a film formation method that causes less damage to the formation surface; thus, the alloying of the component included in the semiconductor layer 230 with the component included in the layer 229 can be inhibited, and the crystallinity of the semiconductor layer 230 can be further increased.

With the above structure, the thickness of the alloyed region can be reduced or reduced to have a thickness that is small enough to make the alloyed region difficult to observe. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIGS. 35A and 35B illustrate an example in which the alloyed region is not formed between the layer 229 and the semiconductor layer 230a.

Note that the thickness of the alloyed region can sometimes be calculated by performing SIMS analysis or energy dispersive X-ray spectroscopy (EDX) composition line analysis on the region and its vicinity.

For example, EDX line analysis is performed on the region and its vicinity with the direction perpendicular to the formation surface of the semiconductor layer 230a regarded as the depth direction. Next, in profiles of quantitative values of elements in the depth direction obtained by the analysis, the depth at which the quantitative value of a metal that is the main component of the semiconductor layer 230a and is not the main component of the layer (here, the layer 229) serving as the formation surface (the metal is In when the semiconductor layer 230a includes In) becomes half is defined as the depth (position) of the interface between the region and the semiconductor layer 230a. The depth at which the quantitative value of an element (e.g., Si) that is the main component of the layer serving as the formation surface and that is not the main component of the semiconductor layer 230a becomes half is defined as the depth (position) of the interface between the region and the layer serving as the formation surface. In the above manner, the thickness of the alloyed region can be calculated.

When the thickness of the alloyed region in the oxide semiconductor layer is observed by EDX analysis, the thickness is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm, for example.

For example, in the case where SIMS analysis of the semiconductor layer 230 formed over the layer 229 that is formed using a silicon oxide layer is performed, the depth at which the silicon concentration is 50% of the maximum value of the silicon concentration of the layer 229 is defined as an interface, and the distance between the interface and the depth at which the silicon concentration decreases to 1.0×10²¹ atoms/cm³, preferably 5.0×10²⁰ atoms/cm³, further preferably 1.0×10²⁰ atoms/cm³ is defined as a thickness t_s2. The thickness t_s2 is preferably less than or equal to 3 nm, further preferably less than or equal to 2 nm.

When the thickness of the alloyed region is reduced, the thickness t_s2 can be a value within the above range.

Note that when the thickness of the alloyed region is reduced, the CAAC structure can be formed in the vicinity of the formation surface. Here, the vicinity of the formation surface refers to, for example, a region extending greater than 0 nm and less than or equal to 3 nm, preferably greater than 0 nm and less than or equal to 2 nm, further preferably greater than or equal to 1 nm and less than or equal to 2 nm from the formation surface of the semiconductor layer 230 in a direction perpendicular to the surface.

Note that the CAAC structure in the vicinity of the formation surface of the oxide semiconductor layer can be confirmed in TEM observation in some cases. For example, in high-resolution TEM cross-sectional observation of the semiconductor layer 230, bright spots arranged in a layered manner in a direction parallel to the formation surface are observed in the vicinity of the formation surface.

Note that when the semiconductor layer 230a is formed by an ALD method, an oxide semiconductor layer having a microcrystalline structure or an amorphous structure that has lower crystallinity than the CAAC structure may be formed. That is, in the formation step illustrated in FIG. 35A, the semiconductor layer 230a sometimes includes a region having lower crystallinity than the semiconductor layer 230b.

The semiconductor layer 230b preferably has a composition suitable for forming the CAAC structure.

When the semiconductor layer 230b is formed by a sputtering method, a mixed layer 231 is formed on the surface of the semiconductor layer 230a or in the vicinity of the surface. A fine crystal region is sometimes formed in the mixed layer 231 by, for example, sputtered particles or energy applied to the substrate side by sputtered particles or the like at the time of forming the semiconductor layer 230b. In the subsequent heat treatment step, the mixed layer 231 or the fine crystal region formed in the mixed layer 231 serves as a nucleus, and at least part of the semiconductor layer 230a is crystallized in some cases.

In the formation of the semiconductor layer 230b by a sputtering method, substrate heating is preferably performed. When the substrate temperature (stage temperature) at the time of forming the metal oxide is increased, a metal oxide with high crystallinity can be formed in some cases.

Next, a semiconductor layer 230c is formed over the semiconductor layer 230b by an ALD method (FIG. 35C). For the formation of the semiconductor layer 230c by an ALD method, the method for forming the semiconductor layer 230a can be referred to.

When the semiconductor layer 230c is formed over the semiconductor layer 230b having the CAAC structure by an ALD method, the semiconductor layer 230c may epitaxially grow with the semiconductor layer 230b as a nucleus. Thus, at the time of forming the semiconductor layer 230c, the semiconductor layer 230c may include a region having the CAAC structure. The region having the CAAC structure is preferably formed throughout the semiconductor layer 230c.

Next, a heat treatment step may be performed. By the heat treatment step, the crystallinity of the region having the CAAC structure in the semiconductor layer 230c is increased in some cases. In the case where the region is formed only below the semiconductor layer 230c after film formation by an ALD method, the region may extend upward by the heat treatment step (FIG. 35D). That is, by the heat treatment, the region having the CAAC structure is sometimes formed in the whole semiconductor layer 230c.

At least part of the semiconductor layer 230a preferably has the CAAC structure by the heat treatment step (FIG. 35D). The CAAC structure is more likely to be easily generated when the mixed layer 231 formed in the semiconductor layer 230a in the formation of the semiconductor layer 230b serves as a nucleus or a seed. The semiconductor layer 230a preferably has a large CAAC region, and the CAAC region preferably extends to the vicinity of the layer 229.

Since the CAAC region extends from the upper portion to the lower portion of the semiconductor layer 230a, the CAAC region can extend to the vicinity of the layer 229, regardless of the material and crystallinity of the layer 229. For example, even when the layer 229 has an amorphous structure, the semiconductor layer 230a having high crystallinity can be formed. Thus, the formation method of the oxide semiconductor layer described in this embodiment is particularly suitable for the case where the layer serving as the formation surface has an amorphous structure.

FIGS. 35A to 35D are cross-sectional views illustrating the method for forming a film of the metal oxide. FIGS. 35A to 35D can also be regarded as conceptual diagrams illustrating a film formation model of the metal oxide. As illustrated in FIGS. 35A to 35D, the crystallinity of each of the semiconductor layers 230a and 230c is increased with the semiconductor layer 230b as a nucleus or a seed. Specifically, the crystallinity of the semiconductor layer 230a may be increased at the time of forming the semiconductor layer 230b or by heat treatment after the formation of the semiconductor layer 230c. The crystallinity of the semiconductor layer 230c may be increased at the time of forming the semiconductor layer 230c or by heat treatment after the formation of the semiconductor layer 230c. Note that the heat treatment has an assisting function of increasing the crystallinity.

As described above, in the formation method of a film of the metal oxide described in this embodiment, the crystallinity of the oxide semiconductors (here, the semiconductor layers 230a and 230c) above and below the semiconductor layer 230b can be increased by using the semiconductor layer 230b (i.e., CAAC) having high crystallinity as a nucleus or a seed. This can increase the crystallinity of the whole oxide semiconductor. In other words, the semiconductor layer 230b serves as a nucleus or a seed to cause solid-phase growths of the oxide semiconductors above and below the semiconductor layer 230b, so that the oxide semiconductor with high crystallinity can be formed. An oxide semiconductor formed by such a film formation method, here, a CAAC film, may be referred to as an axial growth CAAC (AG CAAC). Although FIGS. 36A to 36D illustrate a structure example including the semiconductor layers 230a, 230b, and 230c, one embodiment of the present invention is not limited thereto. For example, a structure including the semiconductor layers 230a and 230b can also be referred to as an AG CAAC.

The region having the CAAC structure preferably spreads in the whole semiconductor layer 230. FIG. 36A illustrates a state where the semiconductor layers 230a, 230b, and 230c are each crystallized. In this case, a boundary between the semiconductor layer 230a and the semiconductor layer 230b is not observed in some cases. In addition, a boundary between the semiconductor layer 230b and the semiconductor layer 230c is not observed in some cases. The semiconductor layer 230 may be expressed as one layer where the interfaces are not clearly observed. The semiconductor layer 230 may be expressed as a single layer in some cases.

Part of the semiconductor layer 230a or part of the semiconductor layer 230c is not crystallized in some cases. FIG. 36B illustrates an example state where the vicinity of the interface between the semiconductor layer 230a and the layer 229 is not crystallized. FIG. 36C illustrates a state where the vicinity of the surface of the semiconductor layer 230c is not crystallized. FIG. 36D illustrates a state where the vicinity of the interface between the semiconductor layer 230a and the layer 229 and the vicinity of the surface of the semiconductor layer 230c are not crystallized.

Increasing the crystallinity of the oxide semiconductor layer improves the initial characteristics (in particular, the on-state current) of the transistor including the oxide semiconductor layer, so that the transistor can be suitable for high-speed driving. In addition, the reliability of the transistor can be improved and the amount of the on-state current can be increased.

The whole oxide semiconductor layer described in this embodiment has high crystallinity. Thus, in the semiconductor layer 230 where the semiconductor layers 230a, 230b, and 230c are stacked, the boundaries between the stacked films are difficult to observe in some cases. In particular, after heat treatment is performed, the boundaries between the stacked films are difficult to observe in some cases. Whether the boundaries between the stacked films are present can be checked with a TEM, for example.

Here, when a metal oxide with a high In content percentage is used for a transistor, the field-effect mobility of the transistor can be increased. On the other hand, an oxide semiconductor with a high In content percentage tends to be polycrystallized. The use of a metal oxide having a polycrystalline structure for a transistor adversely affects the initial characteristics or reliability of the transistor. Thus, when an oxide semiconductor with a high In content percentage is used for one or both of the semiconductor layers 230a and 230c, crystals reflecting orientations of crystals included in the semiconductor layer 230b are formed, so that one or both of the semiconductor layers 230a and 230c can be inhibited from being polycrystallized.

Here, it is preferable that crystals included in the semiconductor layer 230b and crystals included in the semiconductor layer 230a or 230c have a small lattice mismatch. Thus, the semiconductor layer 230a or 230c can form crystals reflecting the orientation of crystals included in the semiconductor layer 230b. In this case, for example, in high-resolution TEM cross-sectional observation of the semiconductor layer 230, bright spots arranged in a layered manner in a direction parallel to the formation surface are observed in the semiconductor layer 230a or 230c.

As long as crystals included in the semiconductor layer 230b and crystals included in the semiconductor layer 230a or 230c have a small lattice mismatch, there is no particular limitation on the crystal structure of the semiconductor layer 230a or 230c. The crystal structure of the semiconductor layer 230a or 230c may be any of a cubic crystal structure, a tetragonal crystal structure, an orthorhombic crystal structure, a hexagonal crystal structure, a monoclinic crystal structure, and a trigonal crystal structure.

### [Composition]

The semiconductor layer 230b preferably has a composition suitable for forming the CAAC structure. The semiconductor layer 230b can be formed by a sputtering method, for example. The semiconductor layer 230b preferably includes zinc, for example. The semiconductor layer 230b including zinc is a metal oxide with high crystallinity. The semiconductor layer 230b preferably includes the element M in addition to zinc. When the semiconductor layer 230b includes the element M, formation of oxygen vacancies in the metal oxide can be inhibited, for example. Thus, the reliability of the transistor including the oxide semiconductor layer can be improved. For the semiconductor layer 230b, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:2 [atomic ratio] or in the neighborhood thereof, a metal oxide with a composition of In:M:Zn=4:2:3 [atomic ratio] or in the neighborhood thereof, a metal oxide with a composition of In:M:Zn=1:3:2 [atomic ratio] or in the neighborhood thereof, or a metal oxide with a composition of In:M:Zn=1:3:4 [atomic ratio] or in the neighborhood thereof may be specifically used. Note that the neighborhood of the atomic ratio includes ±30% of an intended atomic ratio. It is preferable to use one or more of gallium, aluminum, and tin as the element M.

The semiconductor layer 230b does not necessarily include the element M. For example, In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be employed. Alternatively, the semiconductor layer 230b does not necessarily include the element M or Zn. For example, indium oxide may be used. A structure including a slight amount of the element M may be employed. Examples of the composition include a composition of In:Ga:Zn=4:0.1:1 [atomic ratio] or in the neighborhood thereof and a composition of In:Ga:Zn=2:0.1:1 [atomic ratio] or in the neighborhood thereof. Other examples include a composition of In:Sn:Zn=4:0.1:1 [atomic ratio] or in the neighborhood thereof and a composition of In:Sn:Zn=2:0.1:1 [atomic ratio] or in the neighborhood thereof.

The semiconductor layers 230a and 230c can be metal oxides with a high proportion of In. The semiconductor layers 230a and 230c can each be formed by an ALD method, for example. In particular, a metal oxide in which the proportion of In is higher than that of the element M is preferably used. With the use of a metal oxide having a high proportion of In, the on-state current can be increased and the frequency characteristics can be enhanced in a transistor using an oxide semiconductor layer.

Alternatively, the semiconductor layers 230a and 230c do not necessarily include the element M. For example, In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be employed. Alternatively, the semiconductor layers 230a and 230c do not necessarily include the element M or Zn. For example, indium oxide may be used. Each of the semiconductor layers 230a and 230c may include a slight amount of the element M. Specifically, a composition of In:Ga:Zn=4:0.1:1 [atomic ratio] or in the neighborhood thereof, a composition of In:Ga:Zn=2:0.1:1 [atomic ratio] or in the neighborhood thereof, a composition of In:Sn:Zn=4:0.1:1 [atomic ratio] or in the neighborhood thereof, or a composition of In:Sn:Zn=2:0.1:1[atomic ratio] or in the neighborhood thereof can be employed.

Note that when the atomic ratio of zinc contained in the oxide semiconductor is increased, the crystallinity of the oxide semiconductor can be increased. In particular, the semiconductor layer 230a preferably includes zinc. For example, in the case where the semiconductor layer 230a is formed by an ALD method and the semiconductor layer 230b is formed by a sputtering method, zinc included in the semiconductor layer 230a is diffused into the semiconductor layer 230b in some cases. Note that the diffusion can occur at the time of sputtering or later heat treatment. The diffusion of zinc from the semiconductor layer 230a to the semiconductor layer 230b can improve the crystallinity of the semiconductor layer 230b. Alternatively, the diffusion of zinc from the semiconductor layer 230a into the semiconductor layer 230b can induce lateral growth of a crystal part having c-axis alignment to promote extension of the CAAC structure in the semiconductor layer 230b.

The semiconductor layers 230a and 230c can each be a metal oxide having a higher proportion of In than the semiconductor layer 230b.

For example, a metal oxide having a higher proportion of Ga than the semiconductor layer 230b can also be used for the semiconductor layers 230a and 230c. For each of the semiconductor layers 230a and 230c, a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof is preferably used, for example. When the proportion of Ga is increased, the band gap of each of the semiconductor layers 230a and 230c can be larger than that of the semiconductor layer 230b in some cases, for example. Thus, the semiconductor layer 230b is sandwiched between the semiconductor layers 230a and 230c each having a wide band gap, and the semiconductor layer 230b mainly functions as a current path. When the semiconductor layer 230b is sandwiched between the semiconductor layers 230a and 230c, the trap states at the interfaces with the semiconductor layer 230b and the vicinity thereof can be reduced. Accordingly, a buried-channel transistor where a channel is away from the interface with an insulating layer can be achieved, whereby the field-effect mobility can be increased.

Even when each of the semiconductor layers 230a and 230c as a single layer has a composition that does not easily form the CAAC structure, the whole oxide semiconductor layer, including the semiconductor layers 230a and 230c, can have the CAAC structure owing to crystal growth caused with the semiconductor layer 230b as a nucleus. Alternatively, the CAAC structure can be formed in a region including the whole semiconductor layer 230b and at least part of each of the semiconductor layers 230a and 230c.

In particular, even when the semiconductor layers 230a and 230c have a composition with a high In proportion, crystallinity suitable for a semiconductor layer of a transistor can be obtained. The oxide semiconductor layer described in this embodiment enables both high on-state characteristics and high reliability of a transistor, respectively by having a high proportion of In and by having the CAAC structure with high crystallinity.

Note that the semiconductor layers 230a and 230c may have different compositions.

The semiconductor layers 230a and 230c may be formed using a metal oxide having the same composition as the semiconductor layer 230b.

With the use of the oxide semiconductor layer with the CAAC structure formed by the above-described two types of film formation methods for a channel formation region of a transistor as described above, the transistor can have excellent characteristics (e.g., a high on-state current, high field-effect mobility, a low S value, high frequency characteristics (also referred to as f characteristics), or high reliability).

Analysis of the composition of the metal oxide used for the semiconductor layer 230 can be performed by EDX, XPS, inductively coupled plasma-mass spectrometry (ICP-MS), or inductively coupled plasma-atomic emission spectrometry (ICP-AES), for example. Alternatively, two or more of these methods may be combined for the analysis. As for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

### [Crystallinity]

The degree of the crystallinity of the oxide semiconductor layer can be evaluated with the use of crystal orientation, for example.

The crystal orientation can be obtained from a fast Fourier transform (FFT) pattern obtained by performing FFT processing on a TEM image. Specifically, the directions of the crystal axes can be obtained using an FFT pattern. The FFT pattern obtained by the FFT processing reflects reciprocal lattice space information like an electron diffraction pattern.

When FFT processing is performed on each region in the TEM image of the oxide semiconductor layer, crystal orientation in each region can be obtained. For example, crystal orientation is obtained in each region in a certain area range, so that a map indicating crystal orientation can be formed. Specifically, two spots with high intensity are observed in the FFT pattern of the region including the layered crystal part. The direction of the crystal axis of the region can be obtained from the angle of the line segment connecting the two spots.

In the map showing crystal orientation, the proportion of regions having c-axis alignment is calculated to obtain a c-axis alignment proportion.

In the oxide semiconductor layer, the c-axis alignment proportion can be calculated by, for example, cross-sectional or plan-view TEM observation of the oxide semiconductor layer. The region where the FFT is performed (also referred to as an FFT window) can be a circle with a diameter of 1.0 nm, for example. Note that the region where the FFT is performed is not limited to a circle.

When the proportion of regions where the orientation is deviated from the c-axis by less than or equal to 200 is calculated as the c-axis alignment proportion in the oxide semiconductor layer, for example, the c-axis alignment proportion is preferably higher than or equal to 60%, further preferably higher than or equal to 70%, still further preferably higher than or equal to 80%, yet still further preferably higher than or equal to 90%, yet still further preferably higher than or equal to 95%.

Furthermore, the c-axis alignment proportions of the region formed as the semiconductor layer 230a, the region formed as the semiconductor layer 230b, and the region formed as the semiconductor layer 230c are Rc1, Rc2, and Rc3, respectively. Each of Rc2 and Rc3 is higher than or equal to 60%, preferably higher than or equal to 70%, further preferably higher than or equal to 80%, still further preferably higher than or equal to 90%, yet still further preferably higher than or equal to 95%. Rc3/Rc1 is preferably greater than 1. Furthermore, Rc2/Rc1 is preferably greater than 1.

Note that after the formation of the semiconductor layer 230, the boundaries between the semiconductor layers 230a, 230b, and 230c are not clearly observed in some cases.

The semiconductor layer 230 can be divided into three regions: a first region, a second region, and a third region in this order from the top of the layer 229. Each of the regions is a layered region.

The first, second, and third regions each have the CAAC structure. In addition, the c-axis alignment proportion in the third region is preferably higher than that in the first region. The c-axis alignment proportion in the second region is preferably higher than that in the first region. The c-axis alignment proportions in the second and third regions are each higher than or equal to 80%, preferably higher than or equal to 90%, further preferably higher than or equal to 95%.

The first region extends greater than or equal to 0 nm and less than or equal to 3 nm from the top surface of the layer 229, and the third region extends greater than or equal to 0 nm and less than or equal to 3 nm from the top surface of the semiconductor layer 230.

The thicknesses of the layers in the regions are the same, for example.

An appropriate combination of the descriptions in this embodiment can be implemented. An appropriate combination of a description in this embodiment and a description in any of the other embodiments or the like can be implemented.

### Embodiment 4

This embodiment describes an example of a layout of the case where the transistor described in Embodiment 2 is used in the driver circuit described in Embodiment 1.

### <Layout Example>

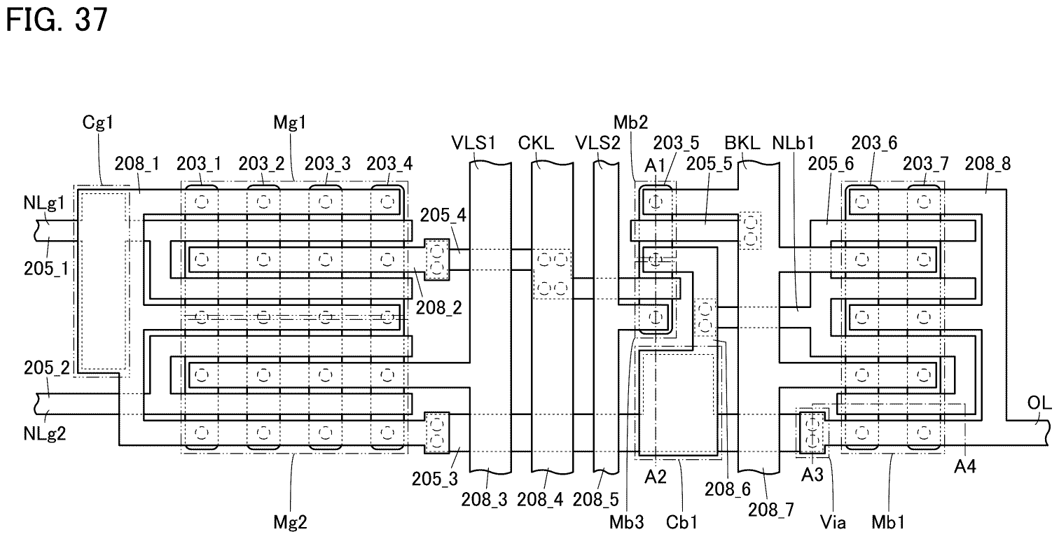

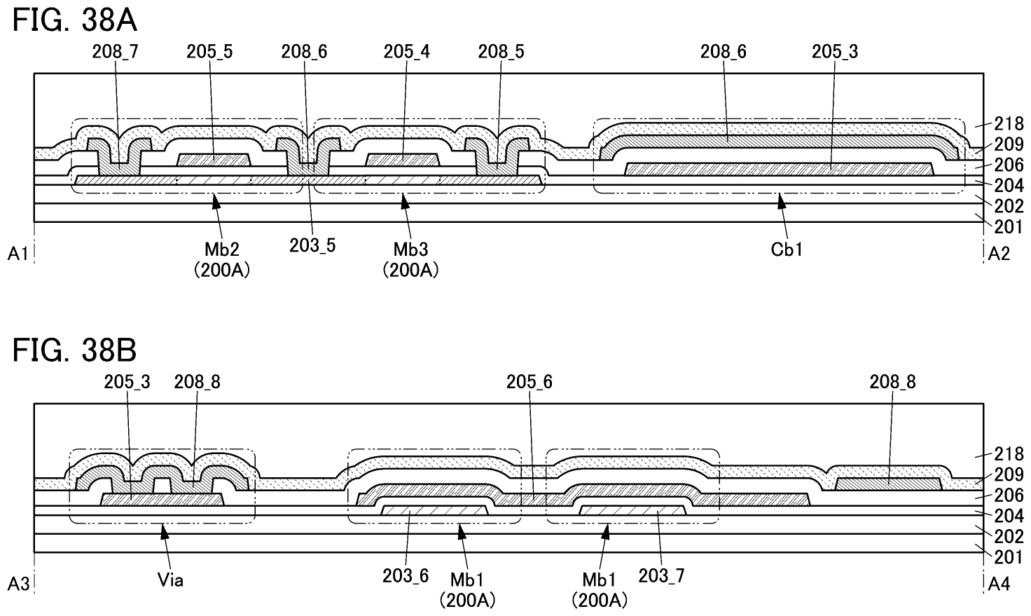

FIG. 37 is a top view illustrating an example of a layout of the case where the transistor 200A illustrated in FIGS. 30A to 30C is used as a transistor included in the driver circuit 100 illustrated in FIG. 1. FIG. 38A is a cross-sectional view taken along dashed-dotted line A1-A2 in FIG. 37. FIG. 38B is a cross-sectional view taken along dashed-dotted line A3-A4 in FIG. 37.

FIG. 37 and the like show a semiconductor layer 2031, a semiconductor layer 2032, a semiconductor layer 203_3, a semiconductor layer 203_4, a semiconductor layer 203_5, a semiconductor layer 203_6, and a semiconductor layer 203_7, each of which corresponds to the semiconductor layer 203 over the insulating layer 202. FIG. 37 and the like also show a conductive layer 205_1, a conductive layer 205_2, a conductive layer 205_3, a conductive layer 205_4, a conductive layer 205_5, and a conductive layer 205_6, each of which corresponds to the conductive layer 205 over the insulating layer 204. FIG. 37 and the like also show a conductive layer 208_1, a conductive layer 208_2, a conductive layer 208_3, a conductive layer 208_4, a conductive layer 208_5, a conductive layer 208_6, a conductive layer 208_7, and a conductive layer 208_8, each of which corresponds to the conductive layer 208 over the insulating layer 206.

The semiconductor layers 203_1, 203_2, 203_3, and 203_4 each include a region functioning as a channel formation region of the transistor Mg1 and a region functioning as a channel formation region of the transistor Mg2. The semiconductor layer 203_5 includes a region functioning as a channel formation region of the transistor Mb2 and a region functioning as a channel formation region of the transistor Mb3. The semiconductor layers 203_6 and 203_7 each include a region functioning as a channel formation region of the transistor Mb1.

The conductive layer 205_1 includes a region functioning as the gate of the transistor Mg1, a region functioning as the other terminal of the capacitor Cg1, and a region functioning as the wiring NLg1. The conductive layer 205_2 includes a region functioning as the gate of the transistor Mg2 and a region functioning as the wiring NLg2. The conductive layer 205_3 includes a region functioning as the one terminal of the capacitor Cb1 and a region functioning as the wiring OL. The conductive layer 205_4 includes a region functioning as the gate of the transistor Mb3 and a region functioning as the wiring CKL. The conductive layer 2055 includes a region functioning as the gate of the transistor Mb2 and a region functioning as the wiring BKL. The conductive layer 205_6 includes a region functioning as the gate of the transistor Mb1 and a region functioning as the wiring NLb1.

The conductive layer 2081 includes a region functioning as the one of the source and the drain of the transistor Mg1, a region functioning as the one of the source and the drain of the transistor Mg2, a region functioning as the one terminal of the capacitor Cg1, and a region functioning as the wiring OL. The conductive layer 208_2 includes a region functioning as the other of the source and the drain of the transistor Mg1 and a region functioning as the wiring CKL. The conductive layer 208_3 includes a region functioning as the other of the source and the drain of the transistor Mg2 and a region functioning as the wiring VLS1. The conductive layer 208_4 includes a region functioning as the wiring CKL. The conductive layer 208_5 includes a region functioning as the other of the source and the drain of the transistor Mb3 and a region functioning as the wiring VLS2. The conductive layer 208_6 includes a region functioning as the other of the source and the drain of the transistor Mb2, a region functioning as the one of the source and the drain of the transistor Mb3, a region functioning as the other terminal of the capacitor Cb1, and a region functioning as the wiring NLb1. The conductive layer 2087 includes a region functioning as the other of the source and the drain of the transistor Mb1, a region functioning as the one of the source and the drain of the transistor Mb2, and a region functioning as the wiring BKL. The conductive layer 208_8 includes a region functioning as the one of the source and the drain of the transistor Mb1 and a region functioning as the wiring OL.

The conductive layer 208_1 is connected to the conductive layer 205_3 in an opening portion provided in the insulating layer 206. The conductive layer 2082 is connected to the conductive layer 205_4 in an opening portion provided in the insulating layer 206. The conductive layer 208_4 is connected to the conductive layer 205_4 in an opening portion provided in the insulating layer 206. The conductive layer 208_6 is connected to the conductive layer 205_6 in an opening portion provided in the insulating layer 206. The conductive layer 208_7 is connected to the conductive layer 2055 in an opening portion provided in the insulating layer 206. The conductive layer 208_8 is connected to the conductive layer 2054 in an opening portion provided in the insulating layer 206. FIG. 37 and FIG. 38B each show a via where the conductive layer 208_8 and the conductive layer 205_3 are connected to each other in opening portions provided in the insulating layer 206.

A plurality of the transistors 200A used as the transistors included in the driver circuit 100 may share the continuous semiconductor layer 203. FIG. 37 illustrates a state where four of the transistors 200A share the semiconductor layer 203_1, four of the transistors 200A share the semiconductor layer 203_2, four of the transistors 200A share the semiconductor layer 2033, four of the transistors 200A share the semiconductor layer 203_4, two of the transistors 200A share the semiconductor layer 203_5, four of the transistors 200A share the semiconductor layer 203_6, and four of the transistors 200A share the semiconductor layer 2037.

Here, in FIG. 37, the transistors Mg1 and Mg2 share the semiconductor layers 2031, 203_2, 203_3, and 203_4, for example. The transistors Mb2 and Mb3 share the semiconductor layer 203_5, for example. FIG. 38A illustrates a state where the transistors Mb2 and Mb3 share the continuous semiconductor layer 203_5. When the plurality of transistors 200A share the continuous semiconductor layers 203 in this manner, the footprints of the transistors can be reduced. This reduces the footprint of the gate driver portion 163 and the bezel width. Accordingly, the semiconductor device can be downsized.

A plurality of the transistors 200A used as the transistors included in the driver circuit 100 may be connected in parallel. In FIG. 37, the transistor Mg1 has a structure in which eight of the transistors 200A are connected in parallel, for example. The transistor Mg2 has a structure in which eight of the transistors 200A are connected in parallel, for example. The transistor Mb1 has a structure in which eight of the transistors 200A are connected in parallel, for example. FIG. 38B illustrates two of the transistors 200A as part of the transistor Mb1. Such a structure in which a plurality of the transistors 200A are connected in parallel increases the substantial channel width, leading to a high on-state current of the transistor. Accordingly, the time required for changing the potential of the wiring OL (i.e., rise time and fall time) can be shortened. As a result, the semiconductor device can have increased operation speed.

Here, in FIG. 37, the channel length (i.e., the width of the conductive layer 205) and the channel width (i.e., the width of the semiconductor layer 203) of each of the transistors 200A in the transistors Mg1, Mg2, and Mb1 are the same as the channel length and the channel width of each of the transistors 200A in the transistors Mb2 and Mb3. Such a structure, in which a plurality of transistors having the same channel length and the same channel width are connected in parallel to increase the on-state current of the transistor, reduces variations in characteristics among the transistors.

Although not shown, in order to increase the on-state current of the transistor, the channel length of each transistor may be reduced or the channel width of each transistor may be increased. In that case, the number of parallel-connected transistors needed for achieving the same on-state current can be reduced, leading to a smaller footprint.

The capacitor Cg1 can have a structure in which part of the insulating layer 206 serves as a dielectric in a region where the conductive layer 205_1 and the conductive layer 208_1 overlap with each other. The capacitor Cb1 can have a structure in which part of the insulating layer 206 serves as a dielectric in a region where the conductive layer 205_3 and the conductive layer 208_6 overlap with each other. FIG. 38A illustrates, as an example, the capacitor Cb1 in which part of the insulating layer 206 serves as the dielectric and part of the conductive layer 205_3 and part of the conductive layer 208_6 serve as the pair of terminals.

Although not shown, a capacitor may be employed in which part of the insulating layer 204 and part of the insulating layer 206 serve as dielectrics and part of the semiconductor layer 203 and part of the conductive layer 208 serve as a pair of terminals, for example. Alternatively, for example, a capacitor may be employed in which a conductive layer (not shown) is provided between the substrate 201 and the insulating layer 202, part of the insulating layer 202 and part of the insulating layer 204 serve as dielectrics, and part of the conductive layer (not shown) and part of the conductive layer 205 serve as a pair of terminals. Further alternatively, for example, a capacitor may be employed in which a conductive layer (not shown) is provided between the substrate 201 and the insulating layer 202, part of the insulating layer 202 serves as a dielectric, and part of the conductive layer (not shown) and part of the semiconductor layer 203 serve as a pair of terminals.

Here, in FIG. 37, a region where neither the capacitor Cg1 nor the capacitor Cb1 is positioned and the conductive layer 205 and the conductive layer 208 overlap with each other serves as parasitic capacitance whose dielectric is part of the insulating layer 206. Thus, the area of the capacitor Cg1 (i.e., the area of the region where the conductive layer 205_1 and the conductive layer 208_1 overlap with each other) is preferably larger than the area of the region where the conductive layer 208_1 and the conductive layer 205_2 overlap with each other, is preferably larger than the area of the region where the conductive layer 205_3 and the conductive layer 208_3 overlap with each other, is preferably larger than the area of the region where the conductive layer 205_3 and the conductive layer 208_4 overlap with each other, is preferably larger than the area of the region where the conductive layer 2053 and the conductive layer 208_5 overlap with each other, and is preferably larger than the area of the region where the conductive layer 205_3 and the conductive layer 208_7 overlap with each other. The area of the capacitor Cb1 (i.e., the area of the region where the conductive layer 2053 and the conductive layer 208_6 overlap with each other) is preferably larger than the area of the region where the conductive layer 208_1 and the conductive layer 205_2 overlap with each other, is preferably larger than the area of the region where the conductive layer 205_3 and the conductive layer 208_3 overlap with each other, is preferably larger than the area of the region where the conductive layer 205_3 and the conductive layer 208_4 overlap with each other, is preferably larger than the area of the region where the conductive layer 205_3 and the conductive layer 2085 overlap with each other, and is preferably larger than the area of the region where the conductive layer 205_3 and the conductive layer 208_7 overlap with each other.

In FIG. 37, the capacitor Cb1 is positioned near the transistor Mb2, not near the transistor Mb1. Since the footprint of the transistor Mb2 is smaller than that of the transistor Mb1, the layout area can be smaller in the case where the capacitor Cb1 is provided near the transistor Mb2 than in the case where the capacitor Cb1 is provided near the transistor Mb1. Based on such a technical concept, in the layout in FIG. 37, the conductive layer 2086 includes both the region functioning as the other terminal of the capacitor Cb1 and the region functioning as the other of the source and the drain of the transistor Mb2. The conductive layer 208_6 is connected to the conductive layer 205_6, and the conductive layer 205_6 includes the region functioning as the gate of the transistor Mb1. The conductive layer 2053 includes the region functioning as the one terminal of the capacitor Cb1. The conductive layer 205_3 is connected to the conductive layer 208_8, and the conductive layer 208_8 includes the region functioning as the one of the source and the drain of the transistor Mb1.

Furthermore, the connection of the capacitor Cb1 and the transistor Mb2 to the transistor Mb1 using the conductive layers 205_3 and 205_6 allows the conductive layer 208_7 to be provided between the transistor Mb1 and each of the capacitor Cb1 and the transistor Mb2. The conductive layer 208_7 can intersect with the conductive layers 205_6 and 205_3. Since the conductive layer 208_7 includes the region functioning as the other of the source and the drain of the transistor Mb1, the region functioning as the one of the source and the drain of the transistor Mb2, and the region functioning as the wiring BKL, the transistor Mb1, the transistor Mb2, the capacitor Cb1, and the wiring BKL can be placed efficiently.

The conductive layer 208_2, which includes the region functioning as the other of the source and the drain of the transistor Mg1, is connected to the conductive layer 205_4, which includes the region functioning as the gate of the transistor Mb3, and the conductive layer 205_4 is connected to the conductive layer 208_4, which is provided between the transistor Mg1 and the transistor Mb1. Since the conductive layer 2084 includes the region functioning as the wiring CKL, the transistor Mg1, the transistor Mb3, and the wiring CKL can be placed efficiently.

Here, the potential of the wiring BKL is supplied to the m gate lines 165 (corresponding to the wirings OL) concurrently. At this time, the current flowing through the wiring BKL is increased instantaneously, and the voltage of the wiring BKL significantly drops. To reduce the influence of this voltage drop of the wiring BKL, the wiring BKL preferably has a large width. Note that each of the wirings CKL, VLS1, and VLS2 also preferably has a large width because a high current flows instantaneously also through the wirings CKL, VLS1, and VLS2. Such large widths of the wirings BKL, CKL, VLS1, and VLS2 increase the layout area. In view of this, the width of a wiring through which a higher current flows instantaneously is preferentially made large, so that both an increase in the layout area and the influence of the voltage drop can be inhibited. When the width of a wiring through which a higher current flows instantaneously is preferentially made large, the current density in the wiring can be reduced. This inhibits disconnection or a short circuit of the wiring due to electromigration, leading to higher reliability.

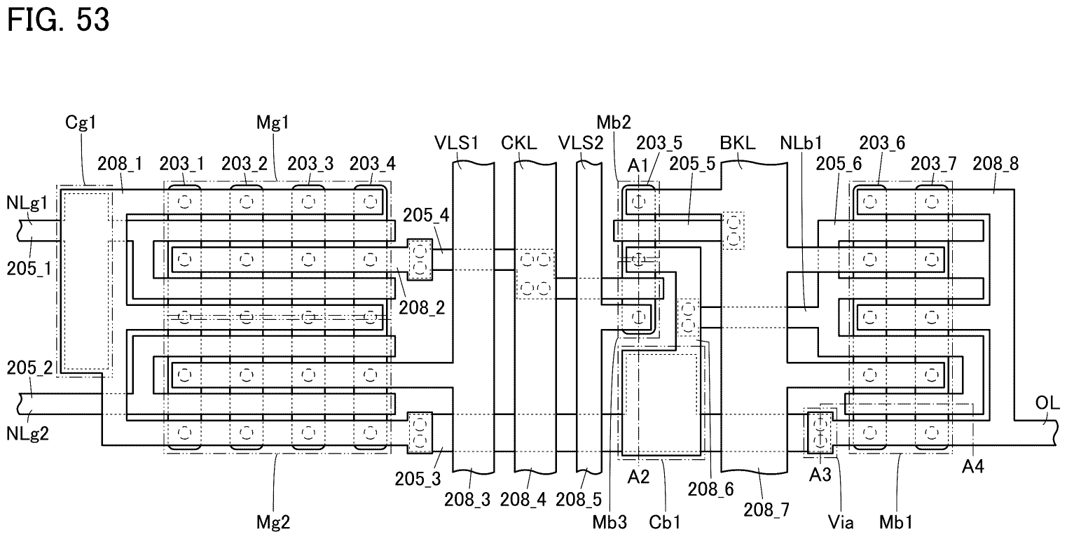

Specifically, the amount of current that flows instantaneously through the wiring BKL is larger than the amount of current that flows instantaneously through each of the wirings CKL, VLS1, and VLS2. Therefore, as illustrated in FIG. 53, the width of the wiring BKL is preferably larger than the width of each of the wirings CKL, VLS1, and VLS2. In that case, both an increase in the layout area and the influence of the voltage drop of the wiring BKL can be inhibited.

A large width of the wiring BKL makes the conductive layer 2087 including the region functioning as the wiring BKL largely overlap with the conductive layer 205_3 including the region functioning as the wiring OL, which might increase parasitic capacitance due to the overlap of these conductive layers. In view of this, to inhibit an increase in parasitic capacitance in such a case, the width of the conductive layer 205_3 may be selectively reduced or an opening portion may be formed in the conductive layer 2053, for example, in a region where the conductive layer 205_3 and the conductive layer 208_7 overlap with each other, although not shown. The same applies to the overlap between other conductive layers where parasitic capacitance can be formed.

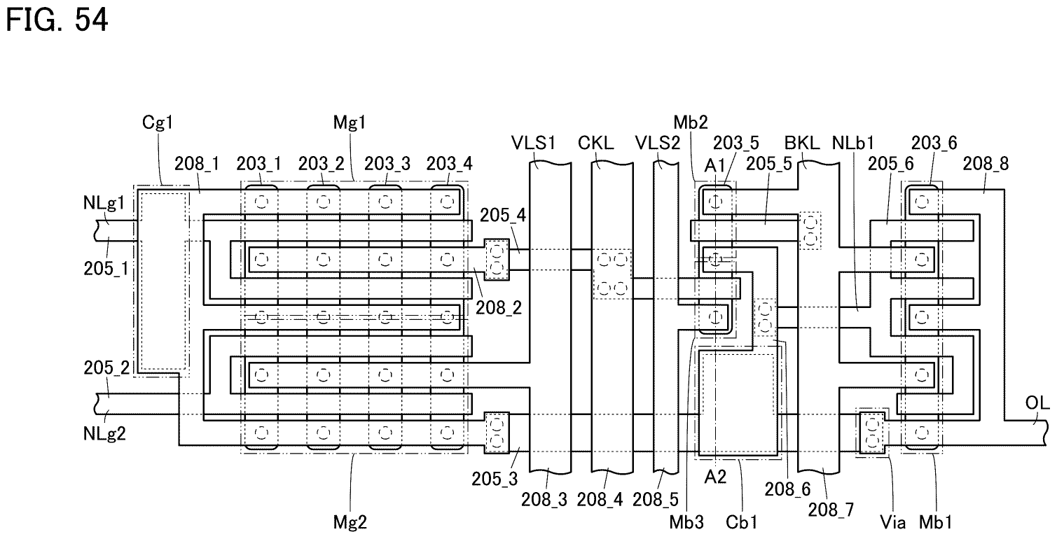

Note that in the case where the driver circuit 100 is used in a display apparatus including a liquid crystal element, for example, a black scanning operation in which a potential is supplied from the wiring BKL to the wiring OL through the transistor Mb1 is performed just before the display apparatus is shut down. Thus, the display apparatus is less affected even when the speed of the black scanning operation is lower than the speed of the writing operation in which a potential is supplied from the wiring CKL to the wiring OL through the transistor Mg1. Accordingly, for example, the on-state current of the transistor Mb1 may be lower than that of the transistor Mg1. For example, as illustrated in FIG. 54, the channel width of the transistor Mb1 may be smaller than that of the transistor Mg1. In that case, the layout area can be reduced.

The structure, operation, and the like of one embodiment of the present invention are not limited to the structure examples, operation examples, and the like described in this embodiment. An appropriate combination of the descriptions in this embodiment can be implemented. An appropriate combination of a description in this embodiment and a description in any of the other embodiments or the like can be implemented.

### Embodiment 5

In this embodiment, display apparatuses of embodiments of the present invention are described.

Note that at least part of the driver circuit, the semiconductor device, and the like described in Embodiment 1 can be applied to the display apparatus described in this embodiment, a module including the display apparatus, and the like.

Here, examples of the module including the display apparatus include a module in which a connector such as a flexible printed circuit board (FPC) or a tape carrier package (TCP) is attached to the display apparatus and a module in which the display apparatus is provided with an integrated circuit (IC) by a chip on glass (COG) method, a chip on film (COF) method, or the like.

### <Structure Example of Display Apparatus>

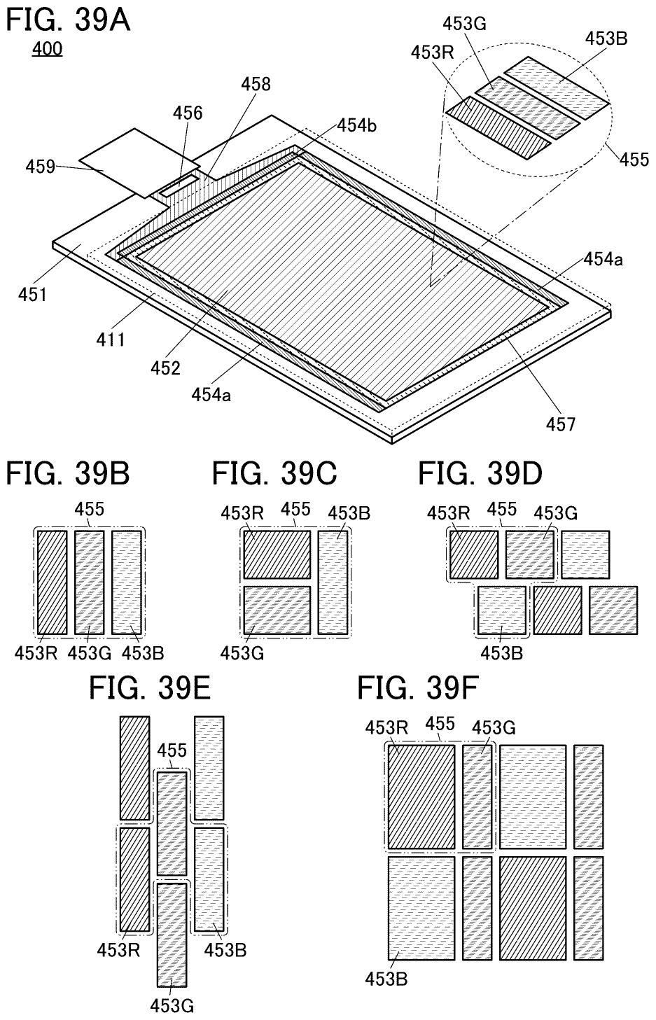

FIG. 39A is a perspective view illustrating a structure example of a display apparatus 400 of one embodiment of the present invention.

In the display apparatus 400, a substrate 411 and a substrate 451 are bonded to each other. In FIG. 39A, the substrate 411 is indicated by a dashed line.

The display apparatus 400 includes a display portion 452, a circuit portion 454a, a circuit portion 454b, a connection portion 457, a wiring portion 458, and the like. In the example illustrated in FIG. 39A, the display apparatus 400 is provided with an IC chip 456 and an FPC 459. Thus, the structure illustrated in FIG. 39A can be regarded as a display module including the display apparatus 400, the IC chip, and the FPC.

Note that at least part of the semiconductor device 160 described in Embodiment 1 can be applied to the display apparatus 400. For example, at least part of the driver circuit 100 described in Embodiment 1 can be applied to the circuit portions 454a and 454b. For another example, at least part of the pixel 161 described in Embodiment 1 can be applied to the display portion 452.

The circuit portion 454a includes a scan line driver circuit (also referred to as a gate driver or a scan driver), for example. The circuit portion 454b includes a scan line driver circuit (also referred to as a source driver or a data driver), for example.

The wiring portion 458 has a function of supplying a signal and power to the display portion 452, the circuit portion 454a, and the circuit portion 454b. The signal and power are input to the wiring portion 458 from outside the display apparatus 400 through the FPC 459 or input to the wiring portion 458 from the IC chip 456.

In the example illustrated in FIG. 39A, the IC chip 456 is provided on the substrate 451 by a COG method, a COF method, or the like. An IC chip including one or both of a scan line driver circuit and a signal line driver circuit can be used as the IC chip 456, for example. Note that the display apparatus 400 and the display module are not necessarily provided with an IC chip. The IC chip may be mounted on the FPC by a COF method or the like.

One or both of the IC chip 456 and the circuit portion 454a may construct the scan line driver circuit, in which case the IC chip 456 may be referred to as a gate driver IC. One or both of the IC chip 456 and the circuit portion 454b may construct the signal line driver circuit, in which case the IC chip 456 may be referred to as a source driver IC.

The display portion 452 of the display apparatus 400 is a region where an image is to be displayed, and includes a plurality of pixels 455 that are periodically arranged. FIG. 39A shows an enlarged view of one of the pixels 455.

The pixel 455 illustrated in FIG. 39A includes a pixel 453R that emits red (R) light, a pixel 453G that emits green (G) light, and a pixel 453B that emits blue (B) light. The pixels 453R, 453G, and 453B form one pixel 455, which achieves full-color display. The pixels 453R, 453G, and 453B each serve as a subpixel. In the display apparatus 400 illustrated in FIG. 39A, the pixels 453R, 453B, and 453G serving as subpixels are arranged in a stripe pattern, for example. The number of subpixels forming one pixel 455 is not limited to three, and may be four or more. For example, one pixel 455 may include four subpixels that emit light of R, G, B, and white (W). Alternatively, one pixel 455 may include four subpixels that emit light of R, G, B, and yellow (Y).

In the description in this specification and the like, identification signs such as “R”, “G”, and “B” are sometimes used to indicate the components related to red light, green light, and blue light, respectively. Such identification signs are sometimes omitted in the description of matters common to the components. For example, a plurality of pixels 453 are sometimes shown individually as the pixel 453R, the pixel 453G, and the pixel 453B when they need to be distinguished from each other. For example, the pixels 453R, 453G, and 453B are sometimes shown simply as the pixel 453 when there is no need to distinguish between them.

The pixels 453R, 453G, and 453B each include a display element and a circuit (a pixel circuit) controlling the driving of the display element.

The connection portion 457 is provided outside the display portion 452. The connection portion 457 can be provided along one or more sides of the display portion 452. The number of connection portions 457 may be one or more. In the example illustrated in FIG. 39A, the connection portion 457 is provided to surround the four sides of the display portion. In the connection portion 457, a common electrode of the display element is connected to the wiring portion 458, and a potential can be supplied to the common electrode.

For each of the substrates 451 and 411, glass, quartz, ceramic, sapphire, a resin, a metal, an alloy, a semiconductor, or the like can be used. The substrate through which light from the display element is extracted (here, the substrate 411) is preferably formed using a material that transmits the light. Furthermore, a polarizing plate may be used as at least one of the substrates 451 and 411. The substrates 451 and 411 can be formed using a flexible material. In that case, the display apparatus can have higher flexibility, achieving a flexible display (e.g., a bendable display, a foldable display, a rollable display, a slidable display, or a stretchable display).

The display apparatus of one embodiment of the present may have a function of a touch panel. The display apparatus can employ any of a variety of sensor elements that can sense proximity or touch of a sensing target such as a finger, for example.

For example, the sensor may be of any of a capacitive type, a resistive type, a surface acoustic wave type, an infrared type, an optical type, and a pressure-sensitive type.

Examples of the capacitive touch sensor are a surface capacitive touch sensor and a projected capacitive touch sensor. Examples of the projected capacitive touch sensor include a self-capacitive touch sensor and a mutual capacitive touch sensor. A mutual capacitive touch sensor is preferably used, in which case multiple points can be sensed simultaneously.

Examples of a touch panel include an out-cell touch panel, an on-cell touch panel, and an in-cell touch panel. An in-cell touch panel has a structure in which an electrode included in a sensor element is provided on one or both of a substrate supporting a display element (also referred to as a display device) and a counter substrate.

### [Pixel Arrangement]

FIGS. 39B to 39F are top views illustrating pixel arrangement. There is no particular limitation on the arrangement of the pixels in the display apparatus of one embodiment of the present invention, and any of a variety of arrangements can be employed. Examples of the arrangement of pixels include a stripe arrangement (see FIG. 39B), an S-stripe arrangement (see FIG. 39C), a delta arrangement (see FIG. 39D), a zigzag arrangement (see FIG. 39E), and a PenTile arrangement (see FIG. 39F). Other examples include a mosaic arrangement, a diamond arrangement, and a Bayer arrangement.

Furthermore, examples of the top-view shape of each of the subpixels (the pixels 453R, 453G, and 453B) in FIGS. 39B to 39F include polygons such as a triangle, a tetragon (including a rectangle and a square), and a pentagon, polygons with rounded corners, an ellipse, and a circle. Here, a top-view shape of the subpixel corresponds to a top-view shape of a display region of the display element included in the subpixel. The top-view shapes and sizes of the subpixels can be determined independently. Note that the positions of the pixels 453R, 453G, and 453B may be interchanged with each other as appropriate. The arrangement of the display elements and the arrangement of the pixel circuits maybe the same or different.

### [Display Element]

Any of a variety of elements can be used as the display element, and a liquid crystal element or a light-emitting element can be used, for example. Alternatively, a micro electro mechanical systems (MEMS) shutter element, an optical interference type MEMS element, or a display element using a microcapsule method, an electrophoretic method, an electrowetting method, an Electronic Liquid Powder (registered trademark) method, or the like can be used. Alternatively, a quantum-dot LED (QLED) employing a light source and color conversion technology using quantum dot materials may be used.

As examples of a display apparatus that includes a liquid crystal element, a transmissive liquid crystal display apparatus, a reflective liquid crystal display apparatus, and a transflective liquid crystal display apparatus can be given.

Examples of the mode applicable to the display apparatus using a liquid crystal element include a vertical alignment (VA) mode, a fringe field switching (FFS) mode, an in-plane-switching (IPS) mode, a twisted nematic (TN) mode, an axially symmetric aligned micro-cell (ASM) mode, an optically compensated birefringence (OCB) mode, a ferroelectric liquid crystal (FLC) mode, an antiferroelectric liquid crystal (AFLC) mode, an electrically controlled birefringence (ECB) mode, and a guest-host mode. Examples of the VA mode include a multi-domain vertical alignment (MVA) mode, a patterned vertical alignment (PVA) mode, and an advanced super view (ASV) mode.

Examples of the liquid crystal material that can be used for the liquid crystal element include a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. Such a liquid crystal material exhibits a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used.

As the light-emitting element, a self-luminous light-emitting element such as a light-emitting diode (LED), an organic electroluminescent (EL) element (also referred to as an organic LED (OLED)), or a semiconductor laser can be used. Examples of the LED include a mini LED and a micro LED.

Examples of a light-emitting substance contained in the light-emitting element include a substance exhibiting fluorescence (a fluorescent material), a substance exhibiting phosphorescence (a phosphorescent material), a substance exhibiting thermally activated delayed fluorescence (a thermally activated delayed fluorescent (TADF) material), and an inorganic compound (e.g., a quantum dot material).

The light-emitting element can emit light of red, green, blue, blue green, reddish violet, yellow, white, or the like. The light-emitting element may emit ultraviolet light or infrared light. When the light-emitting element has a micro optical resonator (microcavity) structure, higher color purity can be achieved.

One of a pair of electrodes of the light-emitting element functions as an anode, and the other electrode functions as a cathode.

### <Cross-Sectional Structure Example of Display Apparatus>

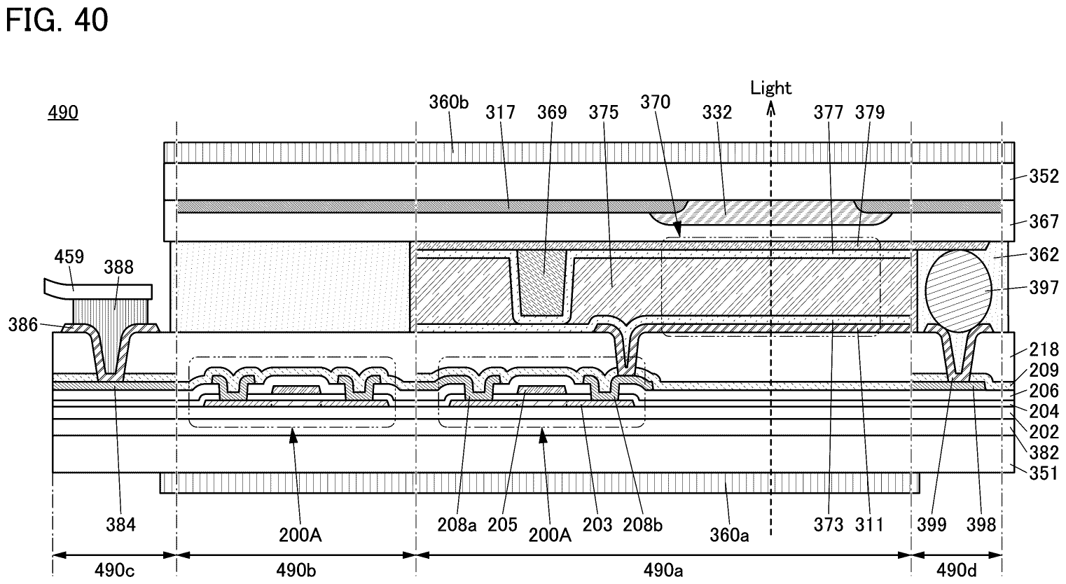

FIG. 40 is a cross-sectional view illustrating a cross-sectional structure example of the display apparatus of one embodiment of the present invention.

Structures illustrated as a region 490a, a region 490b, a region 490c, and a region 490d of a display apparatus 490 in FIG. 40 can be used for the display apparatus 400. For example, the structure illustrated as the region 490a can be used for a region where the pixel 453 is provided. The structure illustrated as the region 490b can be used for a region where the circuit portions 454a and 454b and the like are provided. The structure illustrated as the region 490c can be used for a region where the FPC 459 is provided. The structure illustrated as the region 490d can be used for a region where the connection portion 457 is provided.

Note that the region 490a corresponds to a region where the pixel 161 described in Embodiment 1 is provided. That is, a transistor provided in the region 490a corresponds to the transistor included in the pixel 161 described in Embodiment 1 (e.g., the transistor Mpix). The region 490b corresponds to a region where the driver circuit 100 described in Embodiment 1 is provided. That is, a transistor provided in the region 490b corresponds to the transistor included in the driver circuit 100 described in Embodiment 1 (e.g., the transistor Mg1, Mg2, Mb1, Mb2, or Mb3).

The display apparatus 490 includes a substrate 351 (which corresponds to the substrate 451 described above) and a substrate 352 (which corresponds to the substrate 411 described above). The display apparatus 490 also includes a liquid crystal 375 between the substrates 351 and 352 in the region 490a, and includes an adhesive layer 362 between the substrates 351 and 352 in the regions 490b and 490d. The substrate 352 faces the substrate 351 with the liquid crystal 375 and the adhesive layer 362 therebetween. Note that the display apparatus 490 does not include the substrate 352, the liquid crystal 375, or the adhesive layer 362 in the region 490c.

An insulating layer 382 is provided on the side of the substrate 351 facing the substrate 352. A transistor, a liquid crystal element, and the like are provided over the insulating layer 382.

In the example structure described here, the regions 490a and 490b each include the transistor 200A described in Embodiment 2. The region 490c includes a conductive layer 384, and the region 490d includes a conductive layer 398. The conductive layers 384 and 398 can be formed in the same process as the conductive layer 208 (e.g., the conductive layers 208a and 208b) in the transistor 200A.

Note that the structure of the region 490a can be applied to the pixel 161A[u,v] that includes the liquid crystal element LC as the functional element Elm in the semiconductor device 160 described in Embodiment 1.

The transistors provided in the regions 490a and 490b do not necessarily have the structure of the transistor 200A. Transistors with a variety of structures, such as the transistors 200B, 200C, 200D, and 200E described in Embodiment 2, can be provided in the regions 490a and 490b. In that case, transistors with two or more different structures may be provided.

The insulating layer 209 and an insulating layer 218 are provided to cover the transistors 200A. Note that the display apparatus 490 does not necessarily include the insulating layer 218.

### <Structure Example of Liquid Crystal Element>

In the region 490a, a liquid crystal element 370 and the like are provided over the insulating layer 218.

The liquid crystal element 370 includes a pixel electrode 311 and a common electrode 379, and the liquid crystal 375 is provided between the pixel electrode 311 and the common electrode 379. The pixel electrode 311 is provided to cover an opening portion that is provided in the insulating layers 209 and 218 to reach the conductive layer 208b. Here, the case where a liquid crystal element in a vertical alignment (VA) mode is used as the liquid crystal element 370 is described.

An insulating layer 373 is provided between the pixel electrode 311 and the liquid crystal 375, and an insulating layer 377 is provided between the liquid crystal 375 and the common electrode 379. The insulating layer 373 and the insulating layer 377 each function as an alignment film. An insulating layer 369 is provided between the liquid crystal elements 370. The insulating layer 369 has a function of controlling the distance (cell gap) between the pixel electrode 311 and the common electrode 379.

A light-blocking layer 317 and a coloring layer 332 are provided on the surface of the substrate 352 facing the substrate 351. The coloring layer 332 has a function of selectively transmitting light in a specific wavelength range, such as red light, green light, or blue light, and absorbing light in the other wavelength ranges. A protective layer 367 is provided to cover the light-blocking layer 317 and the coloring layer 332.

The coloring layer 332 includes a region overlapping with the liquid crystal element 370, and the transmittance of the coloring layer 332 with respect to light of a specific color is higher than the transmittance thereof with respect to light of the other colors. For example, in the case where the transmittance of the coloring layer 332 with respect to red light is higher than the transmittance thereof with respect to light of the other colors, light emitted from the liquid crystal element 370 including a region overlapping with the coloring layer 332 (sometimes referred to as a coloring layer 332R) is extracted as red light to outside the display apparatus 490. For example, in the case where the transmittance of the coloring layer 332 with respect to green light is higher than the transmittance thereof with respect to light of the other colors, light emitted from the liquid crystal element 370 including a region overlapping with the coloring layer 332 (sometimes referred to as a coloring layer 332G) is extracted as green light to outside the display apparatus 490. For example, in the case where the transmittance of the coloring layer 332 with respect to blue light is higher than the transmittance thereof with respect to light of the other colors, light emitted from the liquid crystal element 370 including a region overlapping with the coloring layer 332 (sometimes referred to as a coloring layer 332B) is extracted as blue light to outside the display apparatus 490. Thus, the display apparatus 490 can perform full-color display.

The light-blocking layer 317 can be provided in a region where the coloring layer 332 is not provided. In that case, light emitted from the liquid crystal element 370 can be inhibited from entering the coloring layer 332 that does not overlap with the liquid crystal element 370. For example, light emitted from the liquid crystal element 370 overlapping with the coloring layer 332R can be inhibited from entering the coloring layer 332G to be extracted as green light to outside the display apparatus 490. This can inhibit color mixture.

Moreover, the light-blocking layer 317 can inhibit a component of the display apparatus 490 from being seen. For example, the light-blocking layer 317 provided to include a region overlapping with the transistor 200A can inhibit the transistor 200A from being seen. Here, the light-blocking layer 317 is preferably provided in the regions 490b and 490d to inhibit the circuit portions 454a and 454b, the connection portion 457, and the like from being seen.

The protective layer 367 is provided at least in the region 490a and is preferably provided to entirely cover the region 490a. The protective layer 367 is preferably provided to cover not only the region 490a but also the regions 490b and 490d. The protective layer 367 is preferably provided to extend to an end portion of the display apparatus 490.

The insulating layer 218 and the protective layer 367 are bonded to each other with the adhesive layer 362. A region surrounded by the substrate 351, the substrate 352, and the adhesive layer 362 is filled with the liquid crystal 375. A polarizing plate 360a is positioned on the surface of the substrate 351 facing outside (facing away from the substrate 352), and a polarizing plate 360b is positioned on the surface of the substrate 352 facing outside (facing away from the substrate 351). Note that in the case where the display apparatus 490 is a reflective liquid crystal display apparatus, one of the polarizing plates 360a and 360b may be omitted. In the case where the display apparatus 490 is a transmissive liquid crystal display apparatus, a backlight can be provided outside the polarizing plate 360a or outside the polarizing plate 360b, although not shown.

In the case where the display apparatus 490 is a transmissive liquid crystal display apparatus, the pixel electrode 311 and the common electrode 379 transmit visible light. For example, in the case where a backlight is placed on the substrate 351 side, light from the backlight polarized by the polarizing plate 360a passes through the substrate 351, the pixel electrode 311, the liquid crystal 375, the common electrode 379, and the substrate 352 and then reaches the polarizing plate 360b. In that case, alignment of the liquid crystal 375 is controlled with a voltage applied between the pixel electrode 311 and the common electrode 379, and thus, optical modulation of light can be controlled. That is, the intensity of light emitted through the polarizing plate 360b can be controlled. Light other than one in a particular wavelength range is absorbed by the coloring layer 332, and thus, light of a specific color (e.g., red, green, or blue) is emitted, for example.

In FIG. 40, the dashed arrow and “Light” show a state where light is emitted from the backlight (not shown) placed on the substrate 351 side to outside the display apparatus 490 through the polarizing plate 360a, the substrate 351, the pixel electrode 311, the liquid crystal 375, the common electrode 379, the substrate 352, and the polarizing plate 360b.

As the polarizing plate 360b, a linear polarizing plate or a circularly polarizing plate can be used. An example of a circularly polarizing plate is a stack including a linear polarizing plate and a quarter-wave retardation plate. Reflection of external light can be suppressed with a circularly polarizing plate used as the polarizing plate 360b.

In the case where a circularly polarizing plate is used as the polarizing plate 360b, a circularly polarizing plate or a general linear polarizing plate may be used as the polarizing plate 360a. The cell gap, alignment, driving voltage, and the like of the liquid crystal element used as the liquid crystal element 370 can be controlled in accordance with the types of polarizing plates used as the polarizing plates 360a and 360b so that desirable contrast can be obtained.

The common electrode 379 is connected to a conductive layer 399, which is provided on the substrate 351 side, through a connector 397 in the region 490d. The conductive layer 399 is connected to the conductive layer 398 in an opening portion provided in the insulating layers 209 and 218. The conductive layer 399 includes a region in contact with the conductive layer 398 inside the opening portion, for example. The conductive layer 398 is connected to an FPC or an IC chip provided on the substrate 351 side, although this structure is not illustrated in FIG. 40.

Thus, a potential or a signal can be supplied from the FPC or the IC chip provided on the substrate 351 side to the common electrode 379. In the example shown in FIG. 40, the conductive layer 398 is provided in the same layer as the conductive layers 208a and 208b, i.e., formed with the same material and in the same process as the conductive layers 208a and 208b. Furthermore, in the example shown in FIG. 40, the conductive layer 399 is provided in the same layer as the pixel electrode 311, i.e., formed with the same material and in the same process as the pixel electrode 311.

As the connector 397, for example, a conductive particle can be used. As the conductive particle, a particle of an organic resin, silica, or the like coated with a metal material can be used. It is preferable to use nickel or gold as the metal material to reduce contact resistance. It is also preferable to use a particle coated with layers of two or more kinds of metal materials, such as a particle coated with nickel and further with gold. As the connector 397, a material capable of elastic deformation or plastic deformation is preferably used. In that case, as illustrated in FIG. 40, the conductive particle sometimes has a shape that is vertically crushed. This increases the contact area between the connector 397 and a conductive layer in contact with the connector 397, thereby reducing contact resistance and inhibiting generation of defects such as poor connection. The connector 397 is preferably provided to be covered with the adhesive layer 362. For example, the connectors 397 are preferably dispersed in the adhesive layer 362 before curing.

In the region 490c, the conductive layer 384 is connected to the FPC 459 through a conductive layer 386 and a connection layer 388. The conductive layer 384 can be provided in the same layer as the conductive layers 208a and 208b. Thus, the conductive layer 384 can include the same material as the conductive layers 208a and 208b and can be formed in the same process as the conductive layers 208a and 208b. For example, the conductive layers 208a, 208b, and 384 can be formed by processing the same conductive film. The conductive layer 386 can be provided in the same layer as the pixel electrode 311. Thus, the conductive layer 386 can include the same material as the pixel electrode 311 and can be formed in the same process as the pixel electrode 311. For example, the pixel electrode 311 and the conductive layer 386 can be formed by processing the same conductive film. In the region 490c, the conductive layer 386 is exposed. Thus, the conductive layer 386 and the FPC 459 can be connected to each other through the connection layer 388.

For the connection layer 388, an anisotropic conductive film (ACF), an anisotropic conductive paste (ACP), or the like can be used.

### Different Structure Example 1

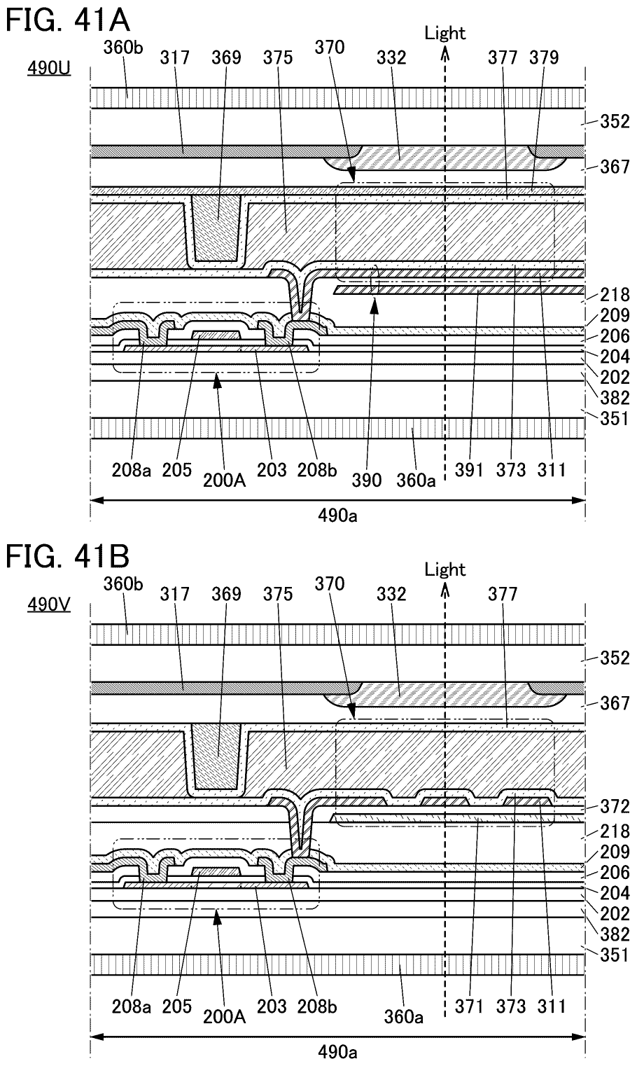

FIG. 41A is a cross-sectional view illustrating a structure example of a display apparatus 490U, which is a variation example of the display apparatus 490. The display apparatus 490U includes, in addition to the components of the display apparatus 490 described above, a conductive layer 391 embedded in the insulating layer 218 and a capacitor 390 including the conductive layer 391 and the pixel electrode 311 as a pair of electrodes, in the region 490a. The conductive layer 391 may be formed using a conductive film that transmits visible light. For example, the conductive layer 391 can include the same material as the pixel electrode 311.

The capacitor 390 can be applied to the capacitor of the pixel 161 described in Embodiment 1. For example, the capacitor 390 can be applied to the capacitor C11 of the pixel 161A described in Embodiment 1.

### Different Structure Example 2

FIG. 41B is a cross-sectional view illustrating a structure example of a display apparatus 490V, which is a variation example of the display apparatus 490. Here, the case where a liquid crystal element in a fringe field switching (FFS) mode is used as the liquid crystal element 370 in the region 490a of the display apparatus 490V is described.

The liquid crystal element 370 of the display apparatus 490V includes a common electrode 371, an insulating layer 372 over the common electrode 371, the pixel electrode 311 over the insulating layer 372, and the liquid crystal 375 over the pixel electrode 311. The pixel electrode 311 is provided to cover an opening portion that is provided in the insulating layers 209, 218, and 372 to reach the conductive layer 208b.

The insulating layer 373 is provided between the liquid crystal 375 and each of the pixel electrode 311 and the insulating layer 372. The insulating layer 377 is provided over the liquid crystal 375.

The common electrode 371 can be provided throughout the region 490a, for example. In that case, the common electrode 371 is provided with an opening portion overlapping with the opening portion provided in the insulating layers 209, 218, and 372.

In a region overlapping with the coloring layer 332, the top view shape of the pixel electrode 311 can be a shape with a slit or a comb-like shape. Thus, the common electrode 371 includes a region overlapping with the coloring layer 332 but not overlapping with the pixel electrode 311.

The common electrode 371 may be formed using a conductive film that transmits visible light. For example, the common electrode 371 can include the same material as the pixel electrode 311.

Note that the display apparatus 490V can also be regarded as including a capacitor that includes the common electrode 371 and the pixel electrode 311 as a pair of electrodes. The capacitor can be applied to, for example, the capacitor of the pixel 161 described in Embodiment 1. For example, the capacitor can be applied to the capacitor C11 of the pixel 161A described in Embodiment 1.

### <Structure Example of Light-Emitting Element>

In the case where the display apparatus includes a light-emitting element, the light-emitting element can have any of a variety of structures in one embodiment of the present invention.

Note that the structure described below can be applied to the pixel 161B[u,v] that includes the light-emitting element LD as the functional element Elm in the semiconductor device 160 described in Embodiment 1.

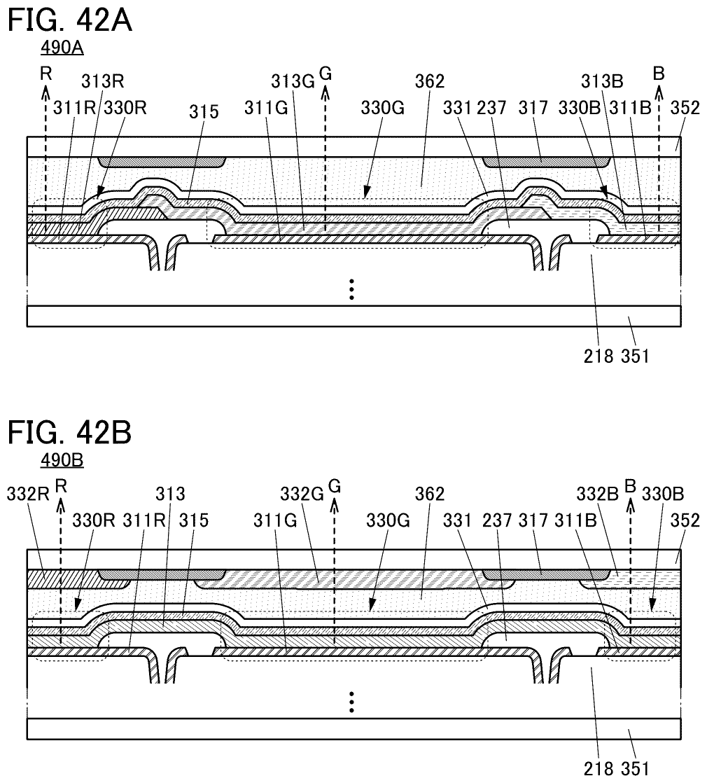

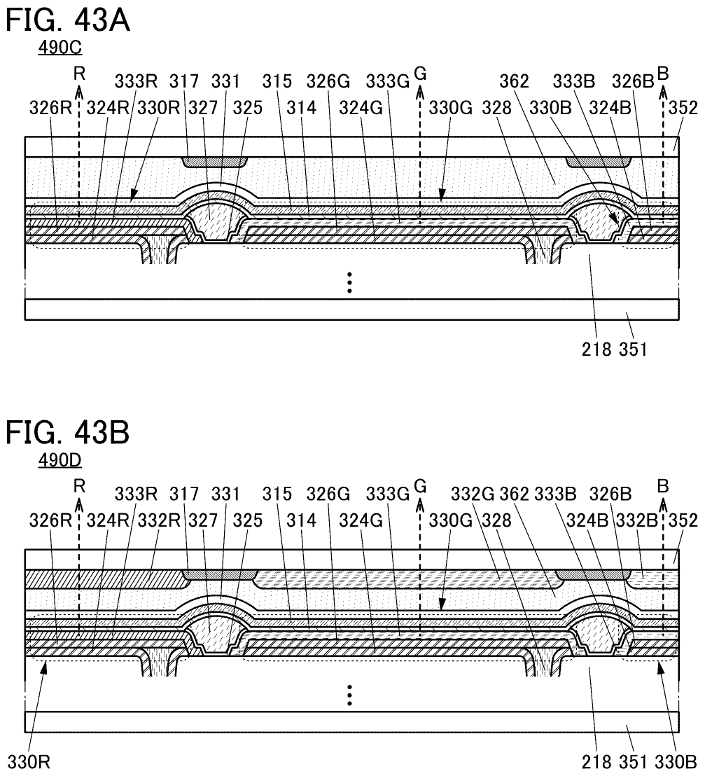

FIGS. 42A and 42B and FIGS. 43A and 43B are cross-sectional views illustrating light-emitting elements with a variety of structures.

### Structure Example 1

A display apparatus 490A illustrated in FIG. 42A includes a light-emitting element 330R, a light-emitting element 330G, a light-emitting element 330B, and the like between the substrates 351 and 352. The light-emitting elements 330R, 330G, and 330B are display elements included in the pixel that emits red light, the pixel that emits green light, and the pixel that emits blue light, respectively. Note that in description of matters common to the light-emitting elements 330R, 330G, and 330B, the light-emitting elements are sometimes simply referred to as light-emitting elements 330.

In FIG. 42A, some components between the substrate 351 and the light-emitting elements 330 and some components between the substrate 352 and the light-emitting elements 330 are not shown. The display apparatus 490A includes, between the substrate 351 and the light-emitting elements 330, a transistor included in the pixel circuit, the insulating layer 218 provided to cover the transistor, and the like.

The display apparatus 490A employs a side-by-side (SBS) structure. The SBS structure is formed using a metal mask (or a fine metal mask). This extends the freedom of choice of materials and structures of the light-emitting elements, enabling optimization of the materials and structures of the light-emitting elements. It is thus easy to increase the emission intensity and the reliability.

The display apparatus 490A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

The light-emitting elements 330R, 330G, and 330B are provided over the insulating layer 218.

The light-emitting element 330R includes a pixel electrode 311R over the insulating layer 218, an EL layer 313R over the pixel electrode 311R, and a common electrode 315 over the EL layer 313R. The light-emitting element 330R illustrated in FIG. 42A emits red (R) light. The EL layer 313R includes a light-emitting layer that emits red light.

The light-emitting element 330G includes a pixel electrode 311G over the insulating layer 218, an EL layer 313G over the pixel electrode 311G, and the common electrode 315 over the EL layer 313G. The light-emitting element 330G illustrated in FIG. 42A emits green (G) light. The EL layer 313G includes a light-emitting layer that emits green light.

The light-emitting element 330B includes a pixel electrode 311B over the insulating layer 218, an EL layer 313B over the pixel electrode 311B, and the common electrode 315 over the EL layer 313B. The light-emitting element 330B illustrated in FIG. 42A emits blue (B) light. The EL layer 313B includes a light-emitting layer that emits blue light.

Although the EL layers 313R, 313G, and 313B have the same thickness in FIG. 42A, one embodiment of the present invention is not limited thereto. The EL layers 313R, 313G, and 313B may have different thicknesses. For example, the thicknesses of the EL layers 313R, 313G, and 313B are preferably set to match an optical path length that intensifies light emitted from each EL layer. In that case, a microcavity structure is obtained, and the color purity of light emitted from each light-emitting element can be improved.

The pixel electrode 311R is connected to a transistor (not shown) included in a pixel circuit corresponding to the light-emitting element 330R in an opening portion provided in the insulating layer 218 and the like. Similarly, the pixel electrode 311G is connected to a transistor (not shown) included in a pixel circuit corresponding to the light-emitting element 330G. Similarly, the pixel electrode 311B is connected to a transistor (not shown) included in a pixel circuit corresponding to the light-emitting element 330B.

End portions of the pixel electrodes 311R, 311G, and 311B are covered with an insulating layer 237. The insulating layer 237 functions as a partition. The insulating layer 237 can have a single-layer structure or a stacked-layer structure including one or both of an inorganic insulating material and an organic insulating material. The insulating layer 237 can be formed using a material that can be used for the insulating layer 218, for example. The insulating layer 237 can insulate the pixel electrode and the common electrode from each other. Furthermore, the insulating layer 237 can insulate adjacent light-emitting elements from each other.

The common electrode 315 is one continuous film shared by the light-emitting elements 330R, 330G, and 330B. Although not shown, in a region where no light-emitting elements are provided, the common electrode 315 shared by the light-emitting elements is connected to a conductive layer formed with the same material and in the same process as the pixel electrodes 311R, 311G, and 311B.

A conductive film that transmits visible light is preferably used for either the pixel electrodes or the common electrode through which light is extracted (here, the common electrode 315). A conductive film reflecting visible light is preferably used for either the pixel electrodes or the common electrode through which light is not extracted (here, the pixel electrodes 311R, 311G, and 311B).

A conductive film that transmits visible light may be used also for the electrode through which light is not extracted. In that case, a reflective layer may be provided to face the EL layer with the conductive film therebetween. Thus, light emitted from the EL layer may be reflected by the reflective layer to be extracted to outside the display apparatus.

As the material of the pair of electrodes (the pixel electrode and the common electrode) of the light-emitting element, a metal, an alloy, a conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide, indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table (e.g., lithium, cesium, calcium, or strontium), a rare earth metal such as europium or ytterbium, an alloy containing an appropriate combination of any of these elements, and graphene.

The light-emitting element preferably employs a microcavity structure. It is thus preferable that, for example, one electrode of the light-emitting element (here, the common electrode 315) be an electrode having properties of transmitting and reflecting visible light (also referred to as transflective electrode), and the other electrode of the light-emitting element (here, the pixel electrode 311R, 311G, or 311B) be an electrode having a property of reflecting visible light (also referred to as reflective electrode). When the light-emitting element has a microcavity structure, light emitted by the light-emitting layer can be resonated between the electrodes, whereby light emitted from the light-emitting element can be intensified.

For example, the transflective electrode has a visible light (light with a wavelength greater than or equal to 400 nm and less than 750 nm) transmittance higher than or equal to 40%. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than 100%, preferably higher than or equal to 70% and lower than 100%. These electrodes preferably have a resistivity lower than or equal to 1×10⁻² Ωcm.

The EL layers 313R, 313G, and 313B are each provided to have an island shape. In FIG. 42A, end portions of the EL layers 313R and 313G adjacent to each other overlap with each other, and end portions of the EL layers 313G and 313B adjacent to each other overlap with each other. Although not shown, end portions of the EL layers 313R and 313B adjacent to each other overlap with each other. When island-shaped EL layers are formed using a metal mask (or a fine metal mask), end portions of the EL layers adjacent to each other may overlap with each other as illustrated in FIG. 42A; however, the present invention is not limited thereto. That is, it is also possible that the EL layers adjacent to each other do not overlap with each other and are apart from each other. There may be both a portion where the EL layers adjacent to each other overlap with each other and a portion where the EL layers adjacent to each other do not overlap with each other and are apart from each other.

Each of the EL layers 313R, 313G, and 313B includes at least a light-emitting layer. The light-emitting layer includes one or more kinds of light-emitting substances. As the light-emitting substance, a substance whose emission color is blue, violet, bluish violet, green, yellowish green, yellow, orange, red, or the like can be used as appropriate. Alternatively, as the light-emitting substance, a substance that emits near-infrared light can be used.

Examples of the light-emitting substance include a fluorescent material, a phosphorescent material, a TADF material, and a quantum dot material.

The light-emitting layer may include one or more kinds of organic compounds (e.g., a host material or an assist material) in addition to the light-emitting substance (a guest material). As the one or more kinds of organic compounds, one or both of a substance with a good hole-transport property (a hole-transport material) and a substance with a good electron-transport property (an electron-transport material) can be used. As the one or more kinds of organic compounds, a substance with a bipolar property (a substance with a good electron-transport property and a good hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (the phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer including a substance having a good hole-injection property (a hole-injection layer), a layer including a hole-transport material (a hole-transport layer), a layer including a substance having a good electron-blocking property (an electron-blocking layer), a layer including a substance having a good electron-injection property (an electron-injection layer), a layer including an electron-transport material (an electron-transport layer), and a layer including a substance having a good hole-blocking property (a hole-blocking layer). The EL layer may further include one or both of a bipolar substance and a TADF material.

Either a low molecular compound or a high molecular compound can be used in the light-emitting element, and an inorganic compound may also be included. Each layer included in the light-emitting element can be formed by any of the following methods: an evaporation method (e.g., a vacuum evaporation method), a transfer method, a printing method (e.g., an inkjet method), a coating method (e.g., a spin coating method), and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. A tandem structure enables a light-emitting element capable of emitting light with high emission intensity. Furthermore, the amount of current needed for obtaining a predetermined emission intensity can be smaller in a tandem structure than in a single structure; thus, a tandem structure enables higher reliability. A tandem structure can also be referred to as a stack structure.

In the case of using a tandem light-emitting element in FIG. 42A, the EL layer 313R preferably includes a plurality of light-emitting units that emit red light, the EL layer 313G preferably includes a plurality of light-emitting units that emit green light, and the EL layer 313B preferably includes a plurality of light-emitting units that emit blue light.

A protective layer 331 is provided over the light-emitting elements 330R, 330G, and 330B. The protective layer 331 and the substrate 352 are bonded to each other with the adhesive layer 362. The substrate 352 is provided with the light-blocking layer 317. A solid sealing structure, a hollow sealing structure, or the like can be employed to seal the light-emitting elements. In FIG. 42A, a solid sealing structure is employed, in which a space between the substrate 352 and the substrate 351 is filled with the adhesive layer 362. Alternatively, a hollow sealing structure may be employed, in which the space is filled with an inert gas (e.g., nitrogen or argon). In that case, the adhesive layer 362 may be provided not to overlap with the light-emitting elements. Alternatively, the space may be filled with a resin different from that of the frame-shaped adhesive layer 362.

By providing the protective layer 331 over the light-emitting elements 330R, 330G, and 330B, the reliability of the light-emitting elements can be increased.

The protective layer 331 may have a single-layer structure or a stacked-layer structure of two or more layers. There is no limitation on the conductivity of the protective layer 331. For the protective layer 331, at least one of an insulating film, a semiconductor film, and a conductive film can be used.

The protective layer 331 including an inorganic film can inhibit deterioration of the light-emitting elements by preventing oxidation of the common electrode 315 and inhibiting entry of impurities (e.g., moisture and oxygen) into the light-emitting elements, for example; thus, the reliability of the display apparatus can be improved.

An inorganic insulating film can be used for the protective layer 331. Examples of a material that can be used for the inorganic insulating film include an oxide, a nitride, an oxynitride, and a nitride oxide. Specific examples of the inorganic insulating film are as described above. In particular, the protective layer 331 preferably includes a nitride or a nitride oxide, and further preferably includes a nitride.

An inorganic film including ITO, In—Zn oxide, Ga—Zn oxide, Al—Zn oxide, IGZO, or the like can also be used for the protective layer 331. The inorganic film preferably has high resistance, specifically, higher resistance than the common electrode 315. The inorganic film may further include nitrogen.

When light emitted from the light-emitting elements is extracted to outside the display apparatus through the protective layer 331, the protective layer 331 preferably has a good visible-light-transmitting property. For example, the protective layer 331 is preferably formed using an inorganic material having a good visible-light-transmitting property such as ITO, IGZO, or aluminum oxide.

The protective layer 331 can be, for example, a stack of an aluminum oxide film and a silicon nitride film over the aluminum oxide film, or a stack of an aluminum oxide film and an IGZO film over the aluminum oxide film. Such a stacked-layer structure can inhibit entry of impurities (e.g., water and oxygen) into the EL layer.

Furthermore, the protective layer 331 may include an organic film. For example, the protective layer 331 may include both an organic film and an inorganic film. Examples of an organic film that can be used for the protective layer 331 include organic insulating films that can be used for the insulating layer 218.

The display apparatus 490A has a top-emission structure, and light from the light-emitting elements is emitted toward the substrate 352. Thus, for the substrate 352, a material having a good visible-light-transmitting property is preferably used. The pixel electrodes 311R, 311G, and 311B include a material that reflects visible light, and the counter electrode (the common electrode 315) includes a material that transmits visible light.

The light-blocking layer 317 is preferably provided on the surface of the substrate 352 facing the substrate 351. The light-blocking layer 317 can be provided over a region between adjacent light-emitting elements, for example.

Although not shown, a coloring layer such as a color filter may be provided on the surface of the substrate 352 facing the substrate 351 or over the protective layer 331. When the color filter is provided so as to overlap with the light-emitting element, the color purity of light extracted to outside the display apparatus can be increased.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer can be formed in a desired position by a printing method, an inkjet method, an etching method using a photolithography method, or the like.

Moreover, a variety of optical members can be provided on the outer surface of the substrate 352 (the surface facing away from the substrate 351). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 352. For example, a glass layer or a silica layer is preferably provided as the surface protective layer to inhibit the surface contamination and damage. The surface protective layer may be formed using diamond-like carbon (DLC), aluminum oxide, a polyester-based material, a polycarbonate-based material, or the like. For the surface protective layer, a material having a high visible light transmittance is preferably used. The surface protective layer is preferably formed using a material with high hardness.

For each of the substrates 351 and 352, glass, quartz, ceramic, sapphire, a resin, a metal, an alloy, a semiconductor, or the like can be used. The substrate through which light from the light-emitting element is extracted is preferably formed using a material that transmits the light. The substrates 351 and 352 can be formed using a flexible material. In that case, the display apparatus can have higher flexibility, achieving a flexible display (e.g., a bendable display, a foldable display, a rollable display, a slidable display, or a stretchable display). Furthermore, a polarizing plate may be used as at least one of the substrates 351 and 352.

For each of the substrates 351 and 352, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as at least one of the substrates 351 and 352.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence). Examples of a highly optically isotropic film include a triacetyl cellulose (TAC, also referred to as cellulose triacetate) film, a cycloolefin polymer (COP) film, a cycloolefin copolymer (COC) film, and an acrylic film.

The adhesive layer 362 can be formed using any of a variety of curable adhesives, e.g., a reactive curable adhesive, a thermosetting curable adhesive, an anaerobic adhesive, or a photocurable adhesive such as an ultraviolet curable adhesive. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene-vinyl acetate (EVA) resin. In particular, a material with low moisture permeability, such as an epoxy resin, is preferable. A two-component-mixture-type resin may be used. An adhesive sheet or the like may be used.

For manufacture of the light-emitting elements, a vacuum process such as an evaporation method and a solution process such as a spin coating method or an inkjet method can be used in one embodiment of the present invention. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., ink-jetting, screen printing (stencil), offset printing (planography), flexography (relief printing), gravure printing, or micro-contact printing), or the like.

### Structure Example 2

A display apparatus 490B illustrated in FIG. 42B includes the light-emitting elements 330R, 330G, and 330B, the coloring layer 332R transmitting red light, the coloring layer 332G transmitting green light, the coloring layer 332B transmitting blue light, and the like. The display apparatus 490B is different from the display apparatus 490A mainly in that the subpixels of different colors include respective coloring layers (color filters or the like) and the light-emitting elements that share an EL layer 313. Note that portions similar to those in the above-described display apparatus are not described in some cases.

The light-emitting element 330R includes the pixel electrode 311R, the EL layer 313 over the pixel electrode 311R, and the common electrode 315 over the EL layer 313. Light emitted from the light-emitting element 330R is extracted as red light to outside the display apparatus 490B through the coloring layer 332R.

The light-emitting element 330G includes the pixel electrode 311G, the EL layer 313 over the pixel electrode 311G, and the common electrode 315 over the EL layer 313. Light emitted from the light-emitting element 330G is extracted as green light to outside the display apparatus 490B through the coloring layer 332G.

The light-emitting element 330B includes the pixel electrode 311B, the EL layer 313 over the pixel electrode 311B, and the common electrode 315 over the EL layer 313. Light emitted from the light-emitting element 330B is extracted as blue light to outside the display apparatus 490B through the coloring layer 332B.

The light-emitting elements 330R, 330G, and 330B include the EL layer 313 and the common electrode 315. The number of manufacturing steps can be smaller in the case where the EL layer 313 is shared by the subpixels of different colors than in the case where the subpixels of different colors include different EL layers.

The light-emitting elements 330R, 330G, and 330B illustrated in FIG. 42B emit white light, for example. When white light emitted from the light-emitting elements 330R, 330G, and 330B passes through the coloring layers 332R, 332G, and 332B, light of desired colors can be obtained.

In the light-emitting element that emits white light, two or more light-emitting layers are preferably included. When two light-emitting layers are used to obtain white light, two light-emitting layers that emit light of complementary colors may be selected. For example, when the emission colors of the first light-emitting layer and the second light-emitting layer are made complementary, the light-emitting element can be configured to emit white light as a whole. In the case where three or more light-emitting layers are used to obtain white light, the light-emitting element may be configured to emit white light as a whole by combining emission colors of the three or more light-emitting layers.

For example, the EL layer 313 preferably includes a light-emitting layer including a light-emitting substance that emits blue light and a light-emitting layer including a light-emitting substance that emits visible light having a longer wavelength than blue light. For another example, the EL layer 313 preferably includes a light-emitting layer that emits yellow light and a light-emitting layer that emits blue light. Alternatively, the EL layer 313 preferably includes a light-emitting layer that emits red light, a light-emitting layer that emits green light, and a light-emitting layer that emits blue light, for example.

The light-emitting element that emits white light preferably has a tandem structure. The light-emitting element can employ a two-unit tandem structure including a light-emitting unit that emits yellow (Y) light and a light-emitting unit that emits blue (B) light, or a two-unit tandem structure including a light-emitting unit that emits red (R) light and green (G) light and a light-emitting unit that emits blue light, for example. Alternatively, the light-emitting element can employ a three-unit tandem structure in which a light-emitting unit that emits blue light, a light-emitting unit that emits yellow, yellow-green, or green light, and a light-emitting unit that emits blue light are stacked in this order, or a three-unit tandem structure in which a light-emitting unit that emits blue light, a light-emitting unit that emits yellow, yellow-green, or green light and red light, and a light-emitting unit that emits blue light are stacked in this order, for example. Examples of the structure of the light-emitting element, which vary in the number of stacked light-emitting units and the order of colors from the cathode side, include the following: a two-unit structure of B and Y; a two-unit structure of B and X (a light-emitting unit X); a three-unit structure of B, Y, and B; and a three-unit structure of B, X, and B. Examples of the structure of the light-emitting unit X, which vary in the number of stacked light-emitting layers and the order of colors from the cathode side, include the following: a two-layer structure of R and Y; a two-layer structure of R and G; a two-layer structure of G and R; a three-layer structure of G, R, and G; and a three-layer structure of R, G, and R. Another layer may be provided between two light-emitting layers.

In the case where the light-emitting element configured to emit white light has a microcavity structure, light with a specific wavelength (e.g., red, green, or blue) is sometimes intensified to be emitted.

Note that the light-emitting elements 330R, 330G, and 330B illustrated in FIG. 42B may emit blue light, for example. In that case, the EL layer 313 includes one or more light-emitting layers that emit blue light. In the pixel that emits blue light, blue light emitted from the light-emitting element 330B can be extracted. In each of the pixel that emits red light and the pixel that emits green light, a color conversion layer is provided between the light-emitting element 330R or 330G and the substrate 352 so that blue light emitted from the light-emitting element 330R or 330G is converted into light with a longer wavelength, whereby red light or green light can be extracted. Furthermore, it is preferable that over the light-emitting element 330R, the coloring layer 332R be provided between the color conversion layer and the substrate 352 and over the light-emitting element 330G, the coloring layer 332G be provided between the color conversion layer and the substrate 352. In some cases, part of light emitted from the light-emitting element is transmitted through the color conversion layer without being converted. Thus, when light transmitted through the color conversion layer is extracted through the coloring layer, light other than light of the intended color can be absorbed by the coloring layer, and color purity of light exhibited by a subpixel can be improved.

### Structure Example 3

A display apparatus 490C illustrated in FIG. 43A is an example of a display apparatus that includes a light-emitting element having a metal maskless (MML) structure. In other words, the display apparatus 490C includes a light-emitting element that is formed without using a metal mask (or a fine metal mask). Note that the components between the substrate 351 and the insulating layer 218 and the components between the protective layer 331 and the substrate 352 are similar to those in the display apparatus 490A; therefore, description thereof is omitted.

A light-emitting element having the MML structure can be manufactured without using a metal mask. Thus, the light-emitting element enables the display apparatus to break through the resolution limit due to alignment accuracy of the metal mask. Furthermore, the light-emitting element can eliminate the need for the manufacturing facilities and washing process for metal masks. This enables mass production of display apparatuses.

Furthermore, employing the MML structure enables minute light-emitting elements to be integrated in the display apparatus. Without a pseudo improvement in resolution by employing a unique pixel arrangement such as a PenTile arrangement, the display apparatus can achieve resolution higher than or equal to 500 ppi, higher than or equal to 1000 ppi, higher than or equal to 2000 ppi, higher than or equal to 3000 ppi, or higher than or equal to 5000 ppi while having what is called a stripe arrangement where R, G, and B are arranged in one direction.

In the light-emitting element having the MML structure, a layer including a light-emitting layer is formed not by using a metal mask but by forming the layer including the light-emitting layer on the entire surface and processing the layer by a photolithography method. For example, in the case where the display apparatus includes three kinds of light-emitting elements, which are a light-emitting element emitting blue light, a light-emitting element emitting green light, and a light-emitting element emitting red light, three kinds of island-shaped light-emitting layers can be formed by repeating formation of a light-emitting layer and processing by photolithography three times. Accordingly, a high-resolution display apparatus or a display apparatus with a high aperture ratio, which has been difficult to form so far, can be obtained. Moreover, light-emitting layers can be formed separately for the respective colors, enabling the display apparatus to perform extremely clear display with high contrast and high display quality. Moreover, providing a sacrificial layer over the light-emitting layer can reduce damage to the light-emitting layer in the manufacturing process of the display apparatus, resulting in an increase in reliability of the light-emitting element.

In FIG. 43A, the light-emitting elements 330R, 330G, and 330B are provided over the insulating layer 218.

The light-emitting element 330R includes a conductive layer 324R over the insulating layer 218, a conductive layer 326R over the conductive layer 324R, a layer 333R over the conductive layer 326R, a common layer 314 over the layer 333R, and the common electrode 315 over the common layer 314. The light-emitting element 330R illustrated in FIG. 43A emits red (R) light. The layer 333R includes a light-emitting layer that emits red light. In the light-emitting element 330R, the layer 333R and the common layer 314 can be collectively referred to as an EL layer. One or both of the conductive layer 324R and the conductive layer 326R can be referred to as a pixel electrode.

The light-emitting element 330G includes a conductive layer 324G over the insulating layer 218, a conductive layer 326G over the conductive layer 324G, a layer 333G over the conductive layer 326G, the common layer 314 over the layer 333G, and the common electrode 315 over the common layer 314. The light-emitting element 330G illustrated in FIG. 43A emits green (G) light. The layer 333G includes a light-emitting layer that emits green light. In the light-emitting element 330G, the layer 333G and the common layer 314 can be collectively referred to as an EL layer. One or both of the conductive layer 324G and the conductive layer 326G can be referred to as a pixel electrode.

The light-emitting element 330B includes a conductive layer 324B over the insulating layer 218, a conductive layer 326B over the conductive layer 324B, a layer 333B over the conductive layer 326B, the common layer 314 over the layer 333B, and the common electrode 315 over the common layer 314. The light-emitting element 330B illustrated in FIG. 43A emits blue (B) light. The layer 333B includes a light-emitting layer that emits blue light. In the light-emitting element 330B, the layer 333B and the common layer 314 can be collectively referred to as an EL layer. One or both of the conductive layer 324B and the conductive layer 326B can be referred to as a pixel electrode.

In this specification and the like, in the EL layers included in the light-emitting elements, the island-shaped layer provided in each light-emitting element is referred to as the layer 333B, 333G, or 333R, and the layer shared by the light-emitting elements is referred to as the common layer 314. Note that in this specification and the like, only the layers 333R, 333G, and 333B are sometimes referred to as island-shaped EL layers, EL layers formed in an island shape, or the like, in which case the common layer 314 is not included in the EL layer.

The layers 333R, 333G, and 333B are island-shaped EL layers that are apart from each other. Thus, a current can be inhibited from flowing between adjacent light-emitting elements. This can prevent crosstalk-induced unintended light emission, so that the display apparatus can achieve extremely high contrast.

Although the layers 333R, 333G, and 333B have the same thickness in FIG. 43A, the present invention is not limited thereto. The layers 333R, 333G, and 333B may have different thicknesses.

The conductive layer 324R is connected to a transistor (not shown) included in a pixel circuit corresponding to the light-emitting element 330R in an opening portion provided in the insulating layer 218 and the like. Similarly, the conductive layer 324G is connected to a transistor (not shown) included in a pixel circuit corresponding to the light-emitting element 330G. Similarly, the conductive layer 324B is connected to a transistor (not shown) included in a pixel circuit corresponding to the light-emitting element 330B.

The conductive layers 324R, 324G, and 324B are formed to cover the opening portions provided in the insulating layer 218 and the like. A layer 328 is embedded in each of the depressions of the conductive layers 324R, 324G, and 324B.

The layer 328 has a function of filling the depressions of the conductive layers 324R, 324G, and 324B. Over the conductive layers 324R, 324G, and 324B and the layer 328, the conductive layers 326R, 326G, and 326B that are in contact with the conductive layers 324R, 324G, and 324B are provided. Thus, regions overlapping with the depressions of the conductive layers 324R, 324G, and 324B can also be used as the light-emitting regions, increasing the aperture ratio of the pixels.

The layer 328 may be an insulating layer or a conductive layer. Any of a variety of inorganic insulating materials, organic insulating materials, and conductive materials can be used for the layer 328 as appropriate. Specifically, the layer 328 is preferably formed using an insulating material and is particularly preferably formed using an organic insulating material. For the layer 328, an organic insulating material that can be used for the insulating layer 237 can be used, for example.

Although the top surface of the layer 328 includes a flat portion in the example illustrated in FIG. 43A, the shape of the layer 328 is not particularly limited. The top surface of the layer 328 may include at least one of a convex surface, a concave surface, and a flat surface.

The level of the top surface of the layer 328 and the level of the top surface of the conductive layer 324R may be the same or may be different from each other. For example, the level of the top surface of the layer 328 may be either lower or higher than the level of the top surface of the conductive layer 324R.

An end portion of the conductive layer 326R may be aligned with an end portion of the conductive layer 324R or may cover the side surface of the end portion of the conductive layer 324R. The end portions of the conductive layers 324R and 326R each preferably have a tapered shape. Specifically, the end portions of the conductive layers 324R and 326R each preferably have a tapered shape with a taper angle greater than 0° and less than 90°. In the case where an end portion of the pixel electrode has a tapered shape, the layer 333R provided along the side surface of the pixel electrode has an inclined portion. When the side surface of the pixel electrode has a tapered shape, coverage with an EL layer provided along the side surface of the pixel electrode can be improved.

As each of the conductive layers 324R and 326R, a conductive layer functioning as a reflective electrode is preferably used.

Since the conductive layers 324G and 326G and the conductive layers 324B and 326B are similar to the conductive layers 324R and 326R, the detailed description thereof is omitted.

The top and side surfaces of the conductive layer 326R are covered with the layer 333R. Similarly, the top and side surfaces of the conductive layer 326G are covered with the layer 333G, and the top and side surfaces of the conductive layer 326B are covered with the layer 333B. Accordingly, regions provided with the conductive layers 326R, 326G, and 326B can be entirely used as the light-emitting regions of the light-emitting elements 330R, 330G, and 330B, thereby increasing the aperture ratio of the pixels.

Between adjacent light-emitting elements, the side surface and part of the top surface of each of the layers 333R, 333G, and 333B are covered with an insulating layer 325 and an insulating layer 327. The common layer 314 is provided over the layers 333R, 333G, and 333B and the insulating layers 325 and 327, and the common electrode 315 is provided over the common layer 314. The common layer 314 and the common electrode 315 are each one continuous film shared by a plurality of light-emitting elements.

In FIG. 43A, an insulating layer functioning as a barrier (which corresponds to the insulating layer 237 illustrated in FIG. 42A and the like) is not provided between the conductive layer 326R and the layer 333R. That is, the display apparatus 490C is not provided with an insulating layer (also referred to as a partition wall, a bank, a spacer, or the like) that is in contact with the pixel electrode and covers an end portion of the top surface of the pixel electrode. Thus, the interval between adjacent light-emitting elements can be extremely short. Accordingly, the display apparatus can have high resolution and high definition. In addition, a mask (e.g., a photomask) for forming the insulating layer is not needed, which leads to a reduction in manufacturing cost of the display apparatus.

As described above, the layers 333R, 333G, and 333B each include a light-emitting layer. The layers 333R, 333G, and 333B each preferably include a light-emitting layer and a carrier-transport layer (an electron-transport layer or a hole-transport layer) over the light-emitting layer. Alternatively, the layers 333R, 333G, and 333B each preferably include a light-emitting layer and a carrier-blocking layer (a hole-blocking layer or an electron-blocking layer) over the light-emitting layer. Alternatively, the layers 333R, 333G, and 333B each preferably include a light-emitting layer, a carrier-blocking layer over the light-emitting layer, and a carrier-transport layer over the carrier-blocking layer. Since surfaces of the layers 333R, 333G, and 333B are exposed in the manufacturing process of the display apparatus, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 314 includes, for example, an electron-injection layer or a hole-injection layer. Alternatively, the common layer 314 may be a stack of an electron-transport layer and an electron-injection layer, or may be a stack of a hole-transport layer and a hole-injection layer. The common layer 314 is shared by the light-emitting elements 330R, 330G, and 330B.

The side surfaces of the layers 333R, 333G, and 333B are each covered with the insulating layer 325. The insulating layer 327 covers the side surfaces of the layers 333R, 333G, and 333B with the insulating layer 325 therebetween.

The side surfaces and part of the top surfaces of the layers 333R, 333G, and 333B are covered with at least one of the insulating layer 325 and the insulating layer 327. Accordingly, the common layer 314 and the common electrode 315 can be inhibited from being in contact with the side surfaces of the pixel electrodes and the layers 333R, 333G, and 333B to cause a short circuit between a pair of electrodes of the light-emitting elements. Thus, the reliability of the light-emitting elements can be increased.

The insulating layer 325 is preferably in contact with the side surfaces of the layers 333R, 333G, and 333B. The insulating layer 325 in contact with the layers 333R, 333G, and 333B can prevent film separation of the layers 333R, 333G, and 333B, whereby the reliability of the light-emitting elements can be increased.

The insulating layer 327 is provided over the insulating layer 325 to fill a depression of the insulating layer 325. The insulating layer 327 preferably covers at least part of the side surface of the insulating layer 325.

The insulating layers 325 and 327 provided in this manner can fill a region between adjacent island-shaped EL layers. Thus, the insulating layers 325 and 327 can reduce a large level difference on the formation surface of the layers (e.g., the carrier-injection layer and the common electrode) provided over the island-shaped EL layers and can make the formation surface flat. Consequently, coverage with the carrier-injection layer, the common electrode, and the like can be improved.

The common layer 314 and the common electrode 315 are provided over the layers 333R, 333G, and 333B and the insulating layers 325 and 327. Before the insulating layers 325 and 327 are provided, a step is generated due to a level difference between a region where the pixel electrode and the island-shaped EL layer are provided and a region where neither the pixel electrode nor the island-shaped EL layer is provided (a region between the light-emitting elements). In the display apparatus of one embodiment of the present invention, the step can be eliminated with the insulating layers 325 and 327, and the coverage with the common layer 314 and the common electrode 315 can be improved. Thus, poor connection caused by step disconnection can be inhibited. In addition, an increase in electrical resistance, which is caused by local thinning of the common electrode 315 due to the step, can be inhibited.

The top surface of the insulating layer 327 preferably has a shape with higher flatness. The top surface of the insulating layer 327 may include at least one of a flat surface, a convex surface, and a concave surface. For example, the top surface of the insulating layer 327 preferably has a convex shape with a large radius of curvature.

An inorganic insulating film can be used for the insulating layer 325. Examples of a material that can be used for the inorganic insulating film include an oxide, a nitride, an oxynitride, and a nitride oxide. Specific examples of the inorganic insulating film are as described above. The insulating layer 325 may have a single-layer structure or a stacked-layer structure. A preferable example of the inorganic insulating film that can be used for the insulating layer 325 is an aluminum oxide film. An aluminum oxide film has high selectivity with respect to the EL layer in etching and has a function of protecting the EL layer in forming the insulating layer 327 which is to be described later. In particular, when an inorganic insulating film such as an aluminum oxide film, a hafnium oxide film, or a silicon oxide film is formed by an ALD method as the insulating layer 325, the insulating layer 325 can have few pinholes and an excellent function of protecting the EL layer. The insulating layer 325 may have a stacked-layer structure of a film formed by an ALD method and a film formed by a sputtering method. The insulating layer 325 may have a stacked-layer structure of an aluminum oxide film formed by an ALD method and a silicon nitride film formed by a sputtering method, for example.

The insulating layer 325 preferably has a function of a barrier insulating layer against at least one of water and oxygen. That is, the insulating layer 325 preferably has a function of inhibiting diffusion of at least one of water and oxygen. Alternatively, the insulating layer 325 preferably has a function of capturing or fixing (also referred to as gettering) at least one of water and oxygen.

When the insulating layer 325 has a function of the barrier insulating layer, entry of impurities (typically, at least one of water and oxygen) that would be diffused into the light-emitting elements from the outside can be inhibited. With this structure, a highly reliable light-emitting element and a highly reliable display apparatus can be provided.

The insulating layer 325 preferably has a low impurity concentration. Accordingly, degradation of the EL layer due to entry of impurities from the insulating layer 325 into the EL layer can be inhibited. In addition, when having a low impurity concentration, the insulating layer 325 can have a good barrier property against at least one of water and oxygen. For example, the insulating layer 325 preferably has a sufficiently low hydrogen concentration or a sufficiently low carbon concentration, and further preferably has both a sufficiently low hydrogen concentration and a sufficiently low carbon concentration.

The insulating layer 327 provided over the insulating layer 325 has a function of reducing a large level difference on the insulating layer 325, which is formed between the adjacent light-emitting elements. In other words, the insulating layer 327 has an effect of improving the flatness of the formation surface of the common electrode 315.

As the insulating layer 327, an insulating layer including an organic material can be used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymers in a broad sense in some cases.

The insulating layer 327 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. The insulating layer 327 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive resin. As the photosensitive organic resin, either a positive-type material or a negative-type material may be used.

The insulating layer 327 may be formed using a material absorbing visible light. When the insulating layer 327 absorbs light emitted from the light-emitting element, light leakage (stray light) to the adjacent light-emitting element through the insulating layer 327 can be suppressed. Thus, the display quality of the display apparatus can be improved. Since no polarizing plate is required to improve the display quality of the display apparatus, the weight and thickness of the display apparatus can be reduced.

Examples of the material absorbing visible light include a material containing a pigment of black or any other color, a material containing a dye, a light-absorbing resin material (e.g., polyimide), and a resin material that can be used for color filters (a color filter material). Using a resin material obtained by stacking or mixing color filter materials of two or three or more colors is particularly preferred to enhance the effect of blocking visible light. In particular, mixing color filter materials of three or more colors enables formation of a black or nearly black resin layer.

### Structure Example 4

A display apparatus 490D illustrated in FIG. 43B includes the light-emitting elements 330R, 330G, and 330B, the coloring layer 332R transmitting red light, the coloring layer 332G transmitting green light, the coloring layer 332B transmitting blue light, and the like. The display apparatus 490D is different from the display apparatus 490C mainly in that the subpixels of different colors include respective coloring layers (color filters or the like) and the light-emitting elements including the layers 333R, 333G, and 333B. Note that portions similar to those in the above-described display apparatus are not described in some cases.

Light emitted from the light-emitting element 330R is extracted as red light to outside the display apparatus 490D through the coloring layer 332R. Similarly, light emitted from the light-emitting element 330G is extracted as green light to outside the display apparatus 490D through the coloring layer 332G. Light emitted from the light-emitting element 330B is extracted as blue light to outside the display apparatus 490D through the coloring layer 332B.

The light-emitting elements 330R, 330G, and 330B include the layers 333R, 333G, and 333B, respectively. The layers 333R, 333G, and 333B are formed using the same material in the same process. The layers 333R, 333G, and 333B are separated from each other. When the EL layer is provided to have an island shape for each light-emitting element, a current can be inhibited from flowing between adjacent light-emitting elements. This can prevent crosstalk-induced unintended light emission, so that the display apparatus can achieve extremely high contrast.

The light-emitting elements 330R, 330G, and 330B illustrated in FIG. 43B emit white light, for example. When white light emitted from the light-emitting elements 330R, 330G, and 330B passes through the coloring layers 332R, 332G, and 332B, respectively, light of desired colors can be obtained.

Note that the light-emitting elements 330R, 330G, and 330B illustrated in FIG. 43B may emit blue light, for example. In that case, the layers 333R, 333G, and 333B each include one or more light-emitting layers that emit blue light. In the pixel that emits blue light, blue light emitted from the light-emitting element 330B can be extracted. In each of the pixel that emits red light and the pixel that emits green light, a color conversion layer is provided between the light-emitting element 330R or 330G and the substrate 352 so that blue light emitted from the light-emitting element 330R or 330G is converted into light with a longer wavelength, whereby red light or green light can be extracted. Furthermore, it is preferable that over the light-emitting element 330R, the coloring layer 332R be provided between the color conversion layer and the substrate 352 and over the light-emitting element 330G, the coloring layer 332G be provided between the color conversion layer and the substrate 352. In some cases, part of light emitted from the light-emitting element is transmitted through the color conversion layer without being converted. Thus, when light transmitted through the color conversion layer is extracted through the coloring layer, light other than light of the intended color can be absorbed by the coloring layer, and color purity of light exhibited by a subpixel can be improved.

### <Structure Example of Light-Receiving Element>

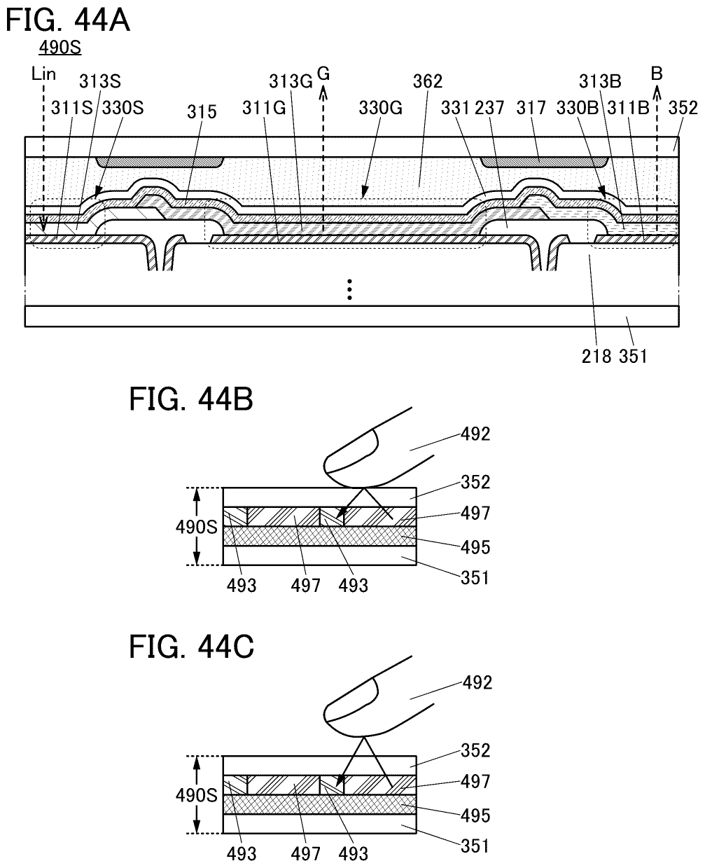

A display apparatus 490S illustrated in FIG. 44A is different from the display apparatus 490A mainly in including a light-receiving element 330S.

Note that the structure described below can be applied to the pixel 161C[u,v] that includes the light-receiving element PD as the functional element Elm in the semiconductor device 160 described in Embodiment 1.

The display apparatus 490S includes light-emitting elements and a light-receiving element in a pixel. In the display apparatus 490S, organic EL elements are preferably used as the light-emitting elements and an organic photodiode is preferably used as the light-receiving element. The organic EL elements and the organic photodiode can be formed over the same substrate. Thus, the organic photodiode can be incorporated in a display apparatus including the organic EL elements.

In the display apparatus 490S including the light-emitting elements and the light-receiving element in each pixel, the pixel has a light-receiving function; thus, the display apparatus can detect the touch or proximity of an object while displaying an image. For example, an image can be displayed by using all the subpixels included in the display apparatus 490S; alternatively, light can be emitted by some of the subpixels as a light source, light can be detected by some other subpixels, and an image can be displayed by using the remaining subpixels.

Accordingly, a light-receiving portion and a light source do not need to be provided separately from the display apparatus 490S; hence, the number of components of an electronic device can be reduced. For example, a biometric authentication device or a capacitive touch panel for scroll operation or the like is not necessarily provided separately in the electronic device. Thus, with the use of the display apparatus 490S, the electronic device can be provided at lower manufacturing costs.

Accordingly, the display portion 452 of the display apparatus 400 described above can have one or both of an image capturing function and a sensing function in addition to a function of displaying an image.

When the light-receiving elements are used for an image sensor, the display apparatus 490S can capture an image using the light-receiving elements. For example, image capturing for personal authentication with the use of a fingerprint, a palm print, the iris, the shape of a blood vessel (including the shape of a vein and the shape of an artery), a face, or the like is possible by using the image sensor.

The light-receiving element can be used in a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display apparatus and the object come in direct contact with each other. Furthermore, the contactless sensor can detect the object even when the object is not in contact with the display apparatus.

The light-receiving element 330S includes a pixel electrode 311S over the insulating layer 218, a functional layer 313S over the pixel electrode 311S, and the common electrode 315 over the functional layer 313S. The functional layer 313S is irradiated with light Lin coming from outside the display apparatus 490S.

The pixel electrode 311S is connected to a transistor (not shown) included in a pixel circuit corresponding to the light-receiving element 330S in an opening portion provided in the insulating layer 218 and the like.

An end portion of the pixel electrode 311S is covered with the insulating layer 237.

The common electrode 315 is one continuous film shared by the light-receiving element 330S and the light-emitting elements 330R (not shown), 330G, and 330B. In a region where no light-emitting elements are provided, the common electrode 315 shared by the light-emitting elements and the light-receiving element is connected to a conductive layer formed with the same material and in the same process as the pixel electrodes 311S, 311R (not shown), 311G, and 311B.

The functional layer 313S includes at least an active layer (also referred to as a photoelectric conversion layer). The active layer includes a semiconductor. Examples of the semiconductor include an inorganic semiconductor such as silicon and an organic semiconductor including an organic compound. In this example, an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

In addition to the active layer, the functional layer 313S may further include a layer including a substance with a good hole-transport property, a substance with a good electron-transport property, a substance with a bipolar property, or the like. Without limitation to the above, the functional layer 313S may further include a layer including a substance with a good hole-injection property, a hole-blocking material, a substance with a good electron-injection property, an electron-blocking material, or the like. The functional layer 313S can be formed using a material that can be used for the light-emitting element.

Either a low molecular compound or a high molecular compound can be used in the light-receiving element, and an inorganic compound may also be included. Each layer included in the light-receiving element can be formed by any of the following methods: an evaporation method (including a vacuum evaporation method), a transfer method, a printing method, an inkjet method, a coating method, and the like.

In FIGS. 44B and 44C, the display apparatus 490S includes a layer 493 including a light-receiving element, a circuit layer 495, and a layer 497 including a light-emitting element, between the substrates 351 and 352.

The layer 493 includes the light-receiving element 330S, for example. The layer 497 includes the light-emitting elements 330R, 330G, and 330B, for example.

The circuit layer 495 includes a circuit for driving the light-receiving element and a circuit for driving the light-emitting element. The circuit layer 495 includes the transistor 200A described in Embodiment 2, for example. The circuit layer 495 can further include one or more of a switch, a capacitor, a resistor, a wiring, a terminal, and the like.

FIG. 44B illustrates an example where the light-receiving element 330S is used for a touch sensor. As illustrated in FIG. 44B, light emitted from the light-emitting element in the layer 497 is reflected by a finger 492 that is in contact with the display apparatus 490S. Then, the reflected light is detected by the light-receiving element in the layer 493. Thus, the touch of the finger 492 on the display apparatus 490S can be detected.

FIG. 44C illustrates an example where the light-receiving element 330S is used for a contactless sensor. As illustrated in FIG. 44C, light emitted from the light-emitting element in the layer 497 is reflected by the finger 492 that is in proximity to (i.e., that is not in contact with) the display apparatus 490S. Then, the reflected light is detected by the light-receiving element in the layer 493.

An appropriate combination of the descriptions in this embodiment can be implemented. An appropriate combination of a description in this embodiment and a description in any of the other embodiments or the like can be implemented.

### Embodiment 6

In this embodiment, a display apparatus of one embodiment of the present invention is described.

### <Structure Example of Display Apparatus>

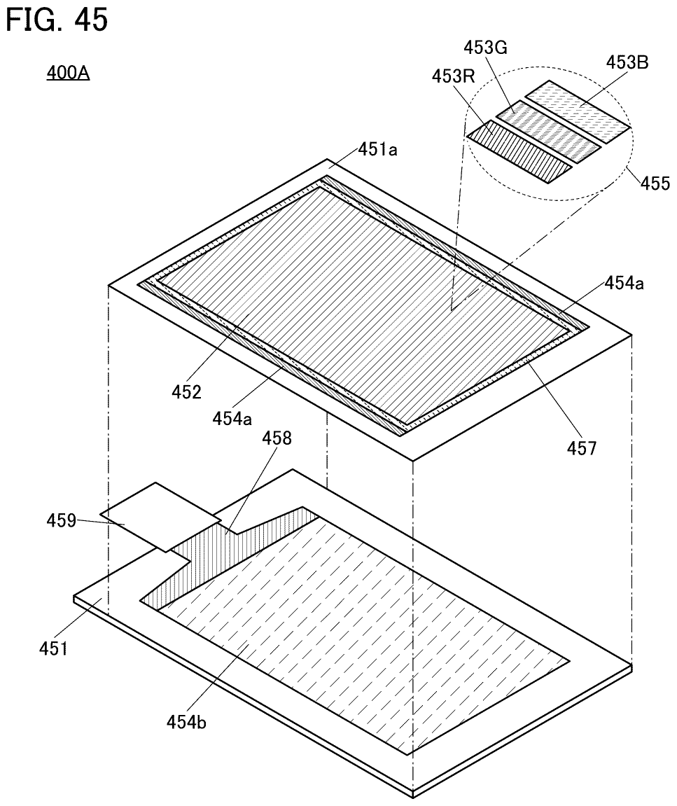

FIG. 45 is a perspective view illustrating a structure example of a display apparatus 400A, which is a variation example of the display apparatus 400 described in Embodiment 5 with reference to FIGS. 39A to 39F. Note that some components are not shown, because differences of the display apparatus 400A from the display apparatus 400 are mainly described here. Therefore, the above description can be referred to as appropriate.

The display apparatus 400A includes a layer 451a over the substrate 451. The substrate 451 is provided with the circuit portion 454b including a source driver, the wiring portion 458, and the like. The layer 451a is provided with the display portion 452 including pixels, the circuit portion 454a including a gate driver, the connection portion 457, and the like. The display portion 452, the circuit portion 454a, and the connection portion 457 are connected to the circuit portion 454b and the wiring portion 458, although the connection is not shown.

The substrate 451 is a silicon substrate, for example. Thus, the circuit portion 454b provided on the substrate 451 may include a Si transistor whose channel formation region includes part of the silicon substrate. The layer 451a includes an oxide semiconductor layer, for example. Thus, the display portion 452 and the circuit portion 454a provided in the layer 451a may each include an OS transistor whose channel formation region includes the oxide semiconductor layer.

Note that at least part of the circuit portion 454b may be provided in the layer 451a. The display portion 452 and at least part of the circuit portion 454a may be provided on the substrate 451.

In the display apparatus 400A, the circuit portion 454b can include a variety of circuits for controlling the operation of the display apparatus 400A, for example, in addition to the source driver. For example, the circuit portion 454b can be provided with a circuit that generates a signal and power to be supplied to the pixel, the gate driver, the source driver, and the like.

The circuit portion 454b may include a memory portion and an arithmetic portion, for example. The memory portion has a function of storing image data or the like, for example. The arithmetic portion has a function of processing image data, for example.

The circuit portion 454b may perform processing in which the characteristics of the transistors in the pixels are obtained and image data is corrected in accordance with the obtained data in order to reduce the influence of variation in the characteristics of the transistors, for example. Processing such as upconversion may be performed on image data input from outside the display apparatus, for example. Examples of a technique for upconverting image data include artificial intelligence (AI) technology such as a convolutional neural network (CNN).

The memory portion includes at least one of a volatile memory and a nonvolatile memory. Examples of the volatile memory include a dynamic random access memory (DRAM) and a static random access memory (SRAM). Examples of the nonvolatile memory include a resistive random access memory (ReRAM, also referred to as a resistance-change memory), a phase-change random access memory (PRAM), a ferroelectric random access memory (FeRAM), a magnetoresistive random access memory (MRAM, also referred to as a magnetoresistive memory), and a flash memory.

The memory portion can include one or both of an OS transistor and a Si transistor. The memory portion may include at least one of a NOSRAM (registered trademark) and a DOSRAM (registered trademark).

Note that “NOSRAM” is an abbreviation for “nonvolatile oxide semiconductor random access memory (RAM)”. A NOSRAM is a memory in which its memory cell is a two-transistor (2T) or three-transistor (3T) gain cell, and its transistor is an OS transistor. In an OS transistor, a current that flows between the source and the drain in an off state, that is, an off-state current is extremely low. A NOSRAM can be used as a nonvolatile memory by retaining electric charge corresponding to data in memory cells with the use of the characteristic of an extremely low off-state current. In particular, a NOSRAM is capable of reading retained data without destruction (non-destructive reading), and thus is suitable for arithmetic processing in which only data reading operations are repeated many times. A NOSRAM can have large data capacity when stacked in layers, and thus, a semiconductor device in which a NOSRAM is used for a large-scale cache memory, a large-scale main memory, or a large-scale storage memory can have higher performance.

“DOSRAM” is an abbreviation for “dynamic oxide semiconductor RAM” and refers to a RAM including a one-transistor (1T) and one-capacitor (1C) memory cell. A DOSRAM is a DRAM formed using an OS transistor and temporarily stores information sent from the outside. A DOSRAM is a memory utilizing a low off-state current of an OS transistor.

The arithmetic portion can include, for example, an arithmetic circuit. The arithmetic portion can include, for example, a central processing unit (CPU). The arithmetic portion can include a graphics processing unit (GPU). The arithmetic portion can include a neural processing unit (NPU). The arithmetic portion can include a tensor processing unit (TPU).

The arithmetic portion may include a microprocessor such as a digital signal processor (DSP). The microprocessor may be configured with a programmable logic device (PLD) such as a field programmable gate array (FPGA) or a field programmable analog array (FPAA). The arithmetic portion may include a quantum processor. The arithmetic portion can interpret and execute instructions from various programs with the use of a processor to process various kinds of data and control programs. The programs to be executed by the processor are stored in at least one of the memory portion and a memory region of the processor.

The arithmetic portion may include a main memory. The main memory includes at least one of a volatile memory such as a random access memory (RAM) and a nonvolatile memory such as a read only memory (ROM). The main memory may include at least one of the above-described NOSRAM and DOSRAM.

For example, a DRAM, an SRAM, or the like is used as the RAM, and a virtual memory space is assigned and utilized as a working space of the arithmetic portion. An operating system, an application program, a program module, program data, a look-up table, and the like that are stored in the memory portion are loaded into the RAM for execution. The data, program, and program module that are loaded into the RAM are each directly accessed and operated by the arithmetic portion.

The ROM can store a basic input/output system (BIOS), firmware, and the like for which rewriting is not needed. Examples of the ROM include a mask ROM, a one-time programmable read only memory (OTPROM), and an erasable programmable read only memory (EPROM). Examples of an EPROM include an ultra-violet erasable programmable read only memory (UV-EPROM) which can erase stored data by irradiation with ultraviolet rays, an electrically erasable programmable read only memory (EEPROM), and a flash memory.

The arithmetic portion can include one or both of an OS transistor and a Si transistor.

The arithmetic portion preferably includes an OS transistor. Since the OS transistor has an extremely low off-state current, a long data retention period can be ensured with the use of the OS transistor as a switch for retaining electric charge (data) that has flowed into a capacitor functioning as a memory element. When this feature is imparted to at least one of a register and a cache memory included in the arithmetic portion, the arithmetic portion can be operated only when needed, and otherwise can be off while information processed immediately before turning off the arithmetic portion is stored in the memory element. In this case, when a memory element including an OS transistor is provided for each flip-flop included in the register, the arithmetic portion is capable of performing fine-grained power gating for each register. In other words, normally-off computing is possible, and power consumption can be reduced.

Note that in the case where the memory portion and the arithmetic portion each include an OS transistor, the OS transistor may be provided in the layer 451a or in a layer added between the substrate 451 and the layer 451a and including an oxide semiconductor layer.

In the display apparatus 490A, the circuit portion 454b can be provided below the display portion 452. This allows the aperture ratio of the pixel 455 to be extremely high. For example, the aperture ratio of the pixel 455 can be higher than or equal to 40% and lower than 100%, preferably higher than or equal to 50% and lower than or equal to 95%, and further preferably higher than or equal to 60% and lower than or equal to 95%. Furthermore, the pixels 455 can be arranged extremely densely, and the display portion 452 can have significantly high resolution. For example, the pixels 455 are preferably arranged in the display portion 452 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

The display apparatus 490A as described above has extremely high resolution and thus can be suitably used for a device capable of spatial computing (also referred to as a spatial computing device, a spatial computer, or the like), a device for VR such as a head-mounted display, or a glasses-type device for AR. For example, even in the case of a structure in which the display portion of the display apparatus 490A is viewed through a lens, pixels of the extremely-high-resolution display portion 452 included in the display apparatus 490A are not seen when the display portion is enlarged by the lens, so that display providing a high sense of immersion can be performed. Without being limited thereto, the display apparatus 490A can be suitably used for electronic devices including a relatively small display portion. For example, the display apparatus 490A can be suitably used in a display portion of a wearable electronic device, such as a wrist watch.

In the display apparatus 490A, the display portion 452 can be divided into a plurality of regions, and the circuit portion 454b placed under the display portion 452 can be provided with a gate driver and a source driver for each region. In that case, the driving frequency (e.g., frame frequency, frame rate, or refresh rate) at the time of displaying an image can be set individually for each region. Thus, by a combination with gaze measurement (eye tracking) or the like, foveated rendering, which is a kind of drawing in which the frame rate is made different between regions in accordance with the user's gaze, can be employed. Thus, an image with excellent display quality can be output with a small load.

### <Cross-Sectional Structure Example of Display Apparatus>

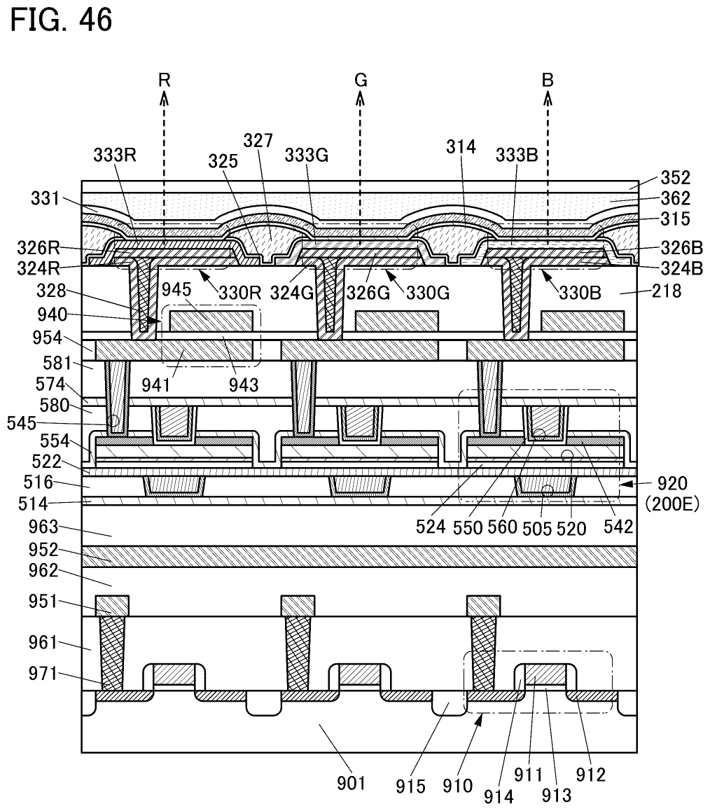

FIG. 46 is a cross-sectional view illustrating a structure example applicable to the display apparatus 490A described above. In the structure illustrated in FIG. 46, a transistor 910 whose channel is formed in a substrate 901, a transistor 920 whose channel is formed in a semiconductor layer including a metal oxide, and the light-emitting elements 330 (the light-emitting elements 330R, 330G, and 330B) are stacked.

The substrate 901 corresponds to the substrate 451 in the display apparatus 490A. A region where the transistor 920 and the light-emitting elements 330 are provided corresponds to the layer 451a in the display apparatus 490A.

Note that the transistor 920 can have any of a variety of structures as described in Embodiment 2. In the example described here, the transistor 920 has a structure similar to that of the transistor 200E illustrated in FIGS. 34A to 34C. Therefore, the above description can be appropriately referred to, and detailed description is sometimes omitted here.

The light-emitting elements 330 can have any of a variety of structures as described in Embodiment 5. In the example described here, the light-emitting elements 330 each have a structure similar to that of the light-emitting elements 330 of the display apparatus 490C illustrated in FIG. 43A. Therefore, the above description can be appropriately referred to, and detailed description is sometimes omitted here.

The transistor 910 includes a channel formation region in the substrate 901. As the substrate 901, a semiconductor substrate such as a single crystal silicon substrate can be used, for example. The transistor 910 includes part of the substrate 901, a conductive layer 911, a pair of low-resistance regions 912, an insulating layer 913, and an insulating layer 914. The conductive layer 911 functions as a gate electrode. The insulating layer 913 is positioned between the substrate 901 and the conductive layer 911 and functions as a gate insulating film. The pair of low-resistance regions 912 are regions where the substrate 901 is doped with an impurity. One of the pair of low-resistance regions 912 functions as one of a source and a drain, and the other of the pair of low-resistance regions 912 functions as the other of the source and the drain. The insulating layer 914 is provided to cover the side surface of the conductive layer 911.

An element isolation layer 915 is provided so as to be embedded in the substrate 901 between two of the transistors 910 that are adjacent to each other.

An insulating layer 961 is provided to cover the transistor 910, and a conductive layer 951 is provided over the insulating layer 961. The conductive layer 951 is connected to the one of the source and the drain of the transistor 910 through a plug 971 embedded in the insulating layer 961. An insulating layer 962 is provided to cover the conductive layer 951, and a conductive layer 952 is provided over the insulating layer 962. The conductive layer 951 and the conductive layer 952 each function as a wiring. An insulating layer 963 and the insulating layer 514 are provided to cover the conductive layer 952, and the transistor 920 is provided over the insulating layer 514.

The insulating layer 581 is provided to cover the transistor 920. Over the insulating layer 581, a capacitor 940 is provided. The capacitor 940 and the transistor 920 are connected to each other with the conductive layer 545 functioning as a plug.

The capacitor 940 includes a conductive layer 941, a conductive layer 945, and an insulating layer 943 between the conductive layers 941 and 945. The conductive layer 941 functions as one electrode of the capacitor 940, the conductive layer 945 functions as the other electrode of the capacitor 940, and the insulating layer 943 functions as a dielectric of the capacitor 940.

The conductive layer 941 is provided over the insulating layer 581 and is embedded in an insulating layer 954. The conductive layer 941 is connected to one of a source and a drain of the transistor 920 through the conductive layer 545 embedded in the insulating layer 581 and the like and functioning as the plug. The insulating layer 943 is provided to cover the conductive layer 941. The conductive layer 945 is provided in a region overlapping with the conductive layer 941 with the insulating layer 943 therebetween.

The insulating layer 218 is provided to cover the capacitor 940, and the light-emitting elements 330 are provided over the insulating layer 218.

With such a structure, a driver circuit and the like including the transistor 910 and the like can be formed directly under the pixels including the transistors 920, the light-emitting elements 330, and the like. Thus, the display apparatus can be downsized as compared with the case where the driver circuit and the like are provided around the display portion.

An appropriate combination of the descriptions in this embodiment can be implemented. An appropriate combination of a description in this embodiment and a description in any of the other embodiments or the like can be implemented.

### Embodiment 7

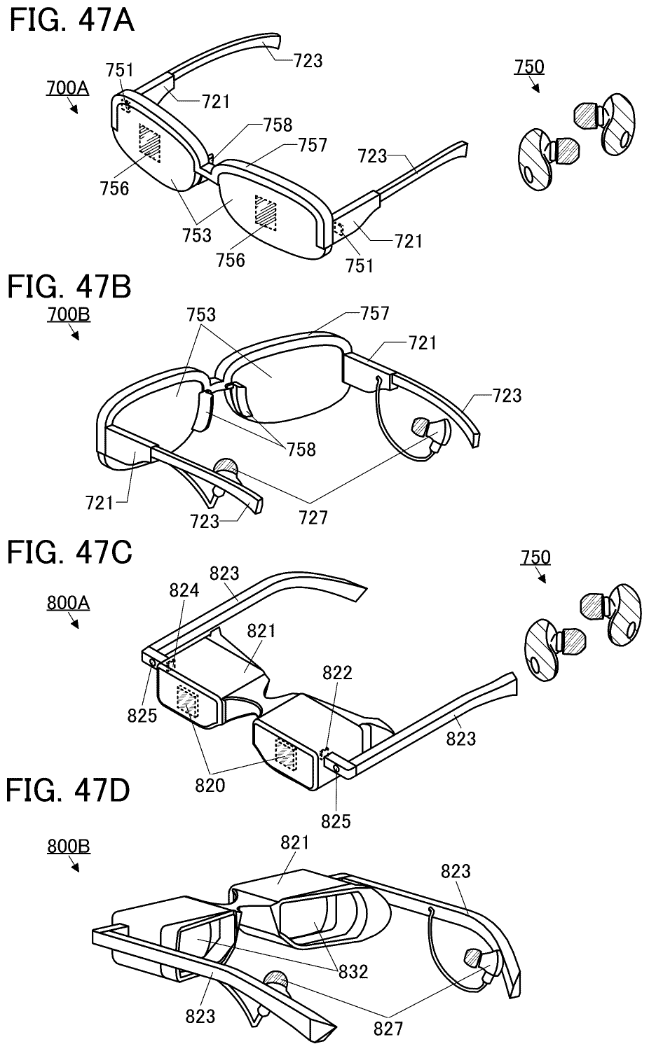

In this embodiment, electronic devices of embodiments of the present invention will be described with reference to FIGS. 47A to 47D, FIGS. 48A to 48F, and FIGS. 49A to 49G.

In the electronic device described in this embodiment, a display portion includes the display apparatus of one embodiment of the present invention or the display apparatus including the semiconductor device of one embodiment of the present invention. The display apparatus of one embodiment of the present invention can be easily increased in resolution and definition. Thus, the display apparatus of one embodiment of the present invention can be used for a display portion of a variety of electronic devices.

A semiconductor device of one embodiment of the present invention can also be applied to any other portion of an electronic device than a display portion. For example, the semiconductor device of one embodiment of the present invention is preferably used for a control portion or the like of an electronic device to enable lower power consumption.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer and the like, digital signage, and a large game machine such as a pachinko machine.

In particular, the display apparatus of one embodiment of the present invention can have a high resolution, and thus can be used for an electronic device having a relatively small display portion. Examples of such an electronic device include wearable devices capable of being worn on a wrist, such as watch-type and bracelet-type information terminal devices; and wearable devices capable of being worn on a head, such as a VR device like a head-mounted display, a glasses-type AR device, a substitutional reality (SR) device, a mixed reality (MR) device, and a device capable of spatial computing like a spatial computer.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display apparatus of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display apparatus having one or both of such high definition and high resolution can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device described in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device described in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIGS. 47A to 47D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 47A and an electronic device 700B illustrated in FIG. 47B each include a pair of display panels 751, a pair of housings 721, a communication portion (not shown), a pair of wearing portions 723, a control portion (not shown), an image capturing portion (not shown), a pair of optical members 753, a frame 757, and a pair of nose pads 758.

The display apparatus of one embodiment of the present invention can be used for the display panels 751. Thus, the electronic devices are capable of performing ultrahigh-resolution display.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are capable of AR display.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic devices 700A and 700B are each provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 47C and an electronic device 800B illustrated in FIG. 47D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic devices are capable of performing ultrahigh-resolution display. Such electronic devices provide a high sense of immersion to the user.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user who wears the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be worn on the user's head with the wearing portions 823. FIG. 47C and the like illustrate examples where the wearing portion 823 has a shape like a temple of glasses; however, one embodiment of the present invention is not limited thereto. The wearing portion 823 may have a shape of a helmet or a band so that the user can wear the electronic device.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portion 825 is provided is shown here, a range sensor (hereinafter also referred to as a sensing portion) capable of measuring a distance between the user and an object may be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as a bone-conduction earphone. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic devices 800A and 800B may each include an input terminal. To the input terminal, a cable for supplying a video signal from a video output device or the like, power for charging the battery provided in the electronic device, and the like can be connected.

The electronic device may have a function of performing wireless communication with earphones 750. The earphones 750 include a communication portion (not shown) and have a wireless communication function. The earphones 750 can receive information (e.g., audio data) from the electronic device with the wireless communication function. For example, the electronic device 700A in FIG. 47A has a function of transmitting information to the earphones 750 with the wireless communication function. For another example, the electronic device 800A in FIG. 47C has a function of transmitting information to the earphones 750 with the wireless communication function.

The electronic device may include an earphone portion. The electronic device 700B in FIG. 47B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B in FIG. 47D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 700A and 700B) and the goggles-type device (e.g., the electronic devices 800A and 800B) are preferable as the electronic device described in this embodiment.

The electronic device described in this embodiment can transmit information to earphones by wire or wirelessly.

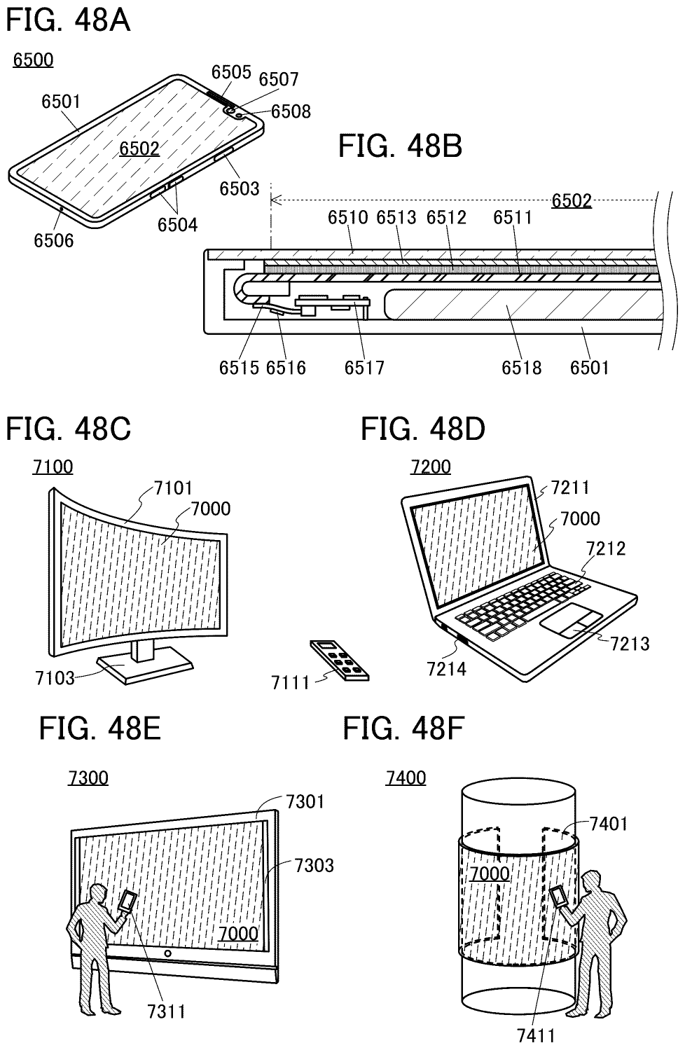

An electronic device 6500 illustrated in FIG. 48A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502.

FIG. 48B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not shown).

Part of the display panel 6511 is folded back in a region outside the display portion 6502, and an FPC 6515 is connected to the part that is folded back. An IC chip 6516 is mounted on the FPC 6515. The FPC 6515 is connected to a terminal provided on the printed circuit board 6517.

The display apparatus of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 48C illustrates an example of a television device. In a television device 7100, a display portion 7000 is incorporated in a housing 7101. Here, the housing 7101 is supported by a stand 7103.

The display apparatus of one embodiment of the present invention can be used in the display portion 7000.

Operation of the television device 7100 illustrated in FIG. 48C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (only from a transmitter to a receiver) or two-way (between a transmitter and a receiver or between receivers, for example) information communication can be performed.

FIG. 48D illustrates an example of a notebook computer. A notebook computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000.

FIGS. 48E and 48F illustrate examples of digital signage.

Digital signage 7300 illustrated in FIG. 48E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 48F illustrates digital signage 7400 attached to a cylindrical pillar 7401. The digital signage 7400 includes the display portion 7000 provided along a curved surface of the pillar 7401.

The display apparatus of one embodiment of the present invention can be used in the display portion 7000 illustrated in each of FIGS. 48E and 48F.

A larger area of the display portion 7000 allows a larger amount of information to be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 48E and 48F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

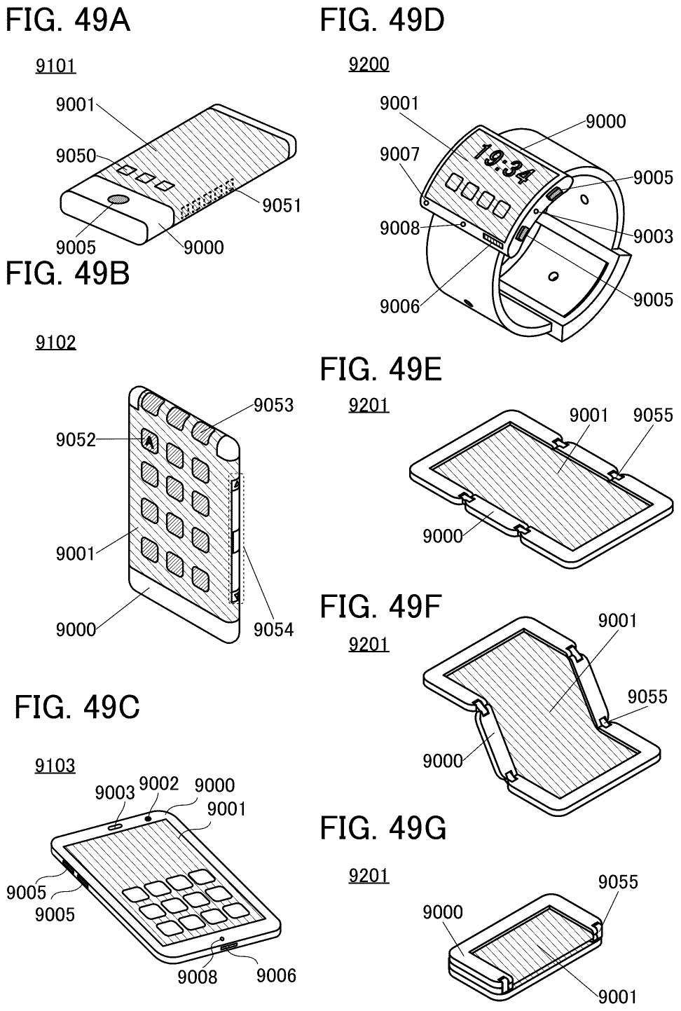

Electronic devices illustrated in FIGS. 49A to 49G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

In FIGS. 49A to 49G, the display apparatus of one embodiment of the present invention can be used in the display portion 9001.

The electronic devices illustrated in FIGS. 49A to 49G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image and storing the captured image in a storage medium (an external storage medium or a storage medium incorporated in the camera), a function of displaying the captured image on the display portion, and the like.

The electronic devices in FIGS. 49A to 49G will be described in detail below.

FIG. 49A is a perspective view of a portable information terminal 9101. The portable information terminal 9101 can be used as a smartphone, for example. The portable information terminal 9101 may include the speaker 9003, the connection terminal 9006, the sensor 9007, and the like. The portable information terminal 9101 can display text and image information on its plurality of surfaces. FIG. 49A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like; the title, the sender, and the date and time of an e-mail, an SNS message, or the like; the time; the remaining battery; and the radio field intensity. Alternatively, the icon 9050 or the like may be displayed at the position where the information 9051 is displayed.

FIG. 49B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 49C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 49D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 49E to 49G are perspective views of a foldable portable information terminal 9201. FIG. 49E is a perspective view illustrating the portable information terminal 9201 that is opened. FIG. 49G is a perspective view illustrating the portable information terminal 9201 that is folded. FIG. 49F is a perspective view illustrating the portable information terminal 9201 that is shifted from one of the states in FIGS. 49E and 49G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

An appropriate combination of the descriptions in this embodiment can be implemented. An appropriate combination of a description in this embodiment and a description in any of the other embodiments or the like can be implemented.

### Notes on Description of this Specification and the Like

The following are notes on the description of the foregoing embodiments and the structures in the embodiments.

The expression “connection” in this specification includes “electrical connection”, for example. When the expression “electrical connection” is used to specify the connection relation of a circuit element as an object, “electrical connection” includes “direct connection” and “indirect connection”, for example. The expression “A and B are directly connected” means that A and B are connected to each other without a circuit element (e.g., a transistor or a switch; a wiring is not a circuit element) therebetween, for example. Meanwhile, the expression “A and B are indirectly connected” means that A and B are connected to each other with at least one circuit element therebetween, for example. Note that A, B, and later-described C each denote an object such as an element, a circuit, a wiring, an electrode, a terminal, a semiconductor layer, or a conductive layer.

Here, in the case where a connection relation is specified as “A and B are indirectly connected”, the following connection relations are included, for example. That is, on the assumption that a circuit is in operation, the circuit can be specified as “A and B are indirectly connected” as an object when electric signal transmission and reception, potential interaction, or the like between A and B occurs at some point during the operation period of the circuit. Note that even when neither electric signal transmission and reception nor potential interaction between A and B occurs at some point during the operation of the circuit, the circuit can be specified as “A and B are indirectly connected” as long as electric signal transmission and reception or potential interaction between A and B occurs at another point during the operation period of the circuit. Note that the expression “A and B are indirectly connected” specifies the connection relation of a circuit element as an object. Thus, even when a circuit is not supplied with a power supply voltage and is not in operation, for example, the circuit can be specified as “A and B are indirectly connected” as an object (note that this specification is limited to, for example, the case where electric signal transmission and reception, potential interaction, or the like between A and B occurs during the operation period of the circuit when the circuit is supplied with a power supply voltage to be in operation).

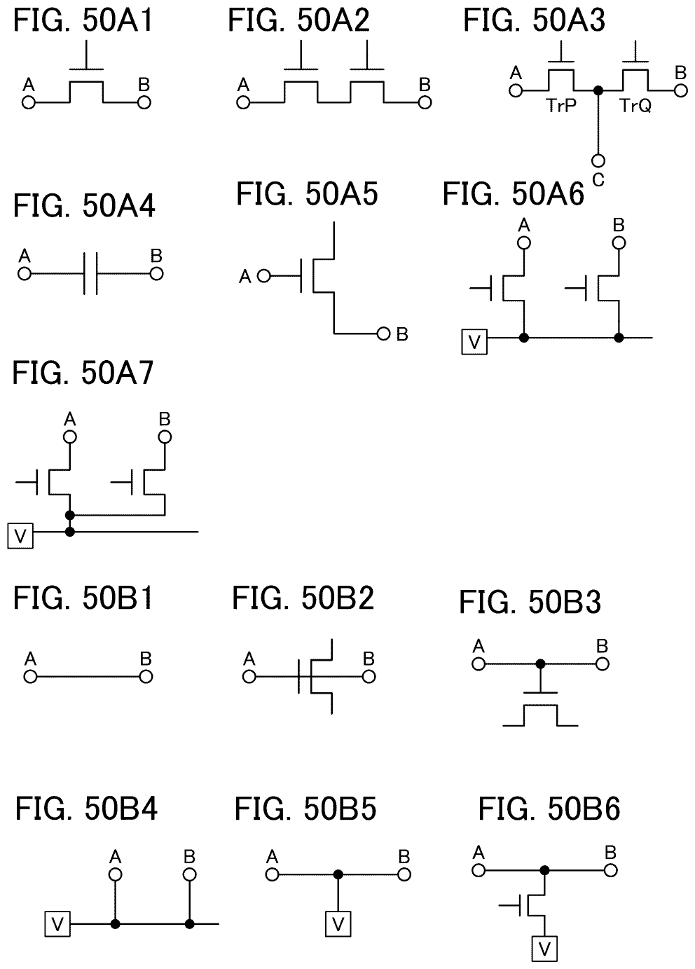

Specific examples of the case of “indirect connection” are described below. First, examples of the case where the expression “A and B are indirectly connected” can be used include the case where A and B are connected to each other through a source and a drain of at least one transistor as in FIGS. 50A1 and 50A2. Another example thereof is the case where A and B are connected to each other with at least one switch therebetween. In the case where the expression “A and B are indirectly connected” can be used, one transistor between A and B is brought into an on state, a conduction state, or a state where a current can flow at least once on the assumption that a circuit is in operation. The case where the expression “A and B are indirectly connected” can be used may include a period in which the one transistor between A and B is brought into an off state or a non-conduction state. In the case where the expression “A and B are indirectly connected” can be used, each of a plurality of transistors between A and B is brought into an on state, a conduction state, or a state where a current can flow at least once when the plurality of transistors are connected between A and B on the assumption that a circuit is in operation. That is, in the case where the expression “A and B are indirectly connected” can be used, it is not necessary that all of the plurality of transistors be brought into an on state, a conduction state, or a state where a current can flow at the same time. Accordingly, in the case where the expression “A and B are indirectly connected” can be used, the plurality of transistors between A and B may be brought into an off state or a non-conduction state at the same time or at different times. For another example, when A and C are connected to each other through a source and a drain of a transistor TrP and B and C are connected to each other through a source and a drain of a transistor TrQ as illustrated in FIG. 50A3, it can be specified as “A and C are indirectly connected”, “B and C are indirectly connected”, or “A and B are indirectly connected”. Note that in the case where a constant potential V is supplied to C from a power source, GND, or the like as described later, the expression “A and C are indirectly connected” or “B and C are indirectly connected” can be used; however, the expression “A and B are indirectly connected” cannot be used.

The examples of the cases where the expression “indirect connection” can be used and cannot be used are described above, and another example of the case where the expression “indirect connection” cannot be used is described below. Even when electric signal transmission and reception, potential interaction, or the like between A and B occurs during the operation period of the circuit, the expression “A and B are indirectly connected” cannot be used in some cases exceptionally. Examples of the exceptional case include the case where A and B are connected to each other with an insulator therebetween. That is, in the case where A and B are connected to each other with an insulator therebetween, the expression “A and B are indirectly connected” cannot be used. A specific example of the case where A and B are connected to each other with an insulator therebetween is the case where a capacitor is connected between A and B as in FIG. 50A4. Another example thereof is the case where there is a gate insulating film of a transistor or the like between A and B as in FIG. 50A5. In this case, the expression “A (a gate of the transistor) and B (a source or a drain of the transistor) are indirectly connected” cannot be used.

Another example of the case where the expression “A and B are indirectly connected” cannot be used is the case where neither electric signal transmission and reception nor potential interaction between A and B occurs. For example, a plurality of transistors are connected through their sources and drains on the path from A to B and a constant potential V is supplied from a power source, GND, or the like to a node between one of the transistors and another one of the transistors as in FIGS. 50A6 and 50A7. In this case, the expression “A and B are indirectly connected” cannot be used; however, the expression “A and V are indirectly connected” or “B and V are indirectly connected” can be used. Note that in FIG. 50A3, when A and C are connected to each other through the source and the drain of the transistor TrP, B and C are connected to each other through the source and the drain of the transistor TrQ, and a constant potential V is supplied to C from a power source, a GND, or the like, the same connection relation as that in FIGS. 50A6 and 50A7 is established; thus, the expression “A and B are indirectly connected” cannot be used; however, the expression “A and C are indirectly connected” or “B and C are indirectly connected” can be used.

The examples of “indirect connection” are described above. The specification of “indirect connection” is included in the specification of “electrical connection”, for example; thus, in the case where the expression “A and B are indirectly connected” is used, the expression “A and B are electrically connected” can also be used.

Next, specific examples of the case of “direct connection” are described. Examples of the case where the expression “A and B are directly connected” can be used include the case where A and B are connected to each other without a circuit element therebetween as in FIGS. 50B1, 50B2, and 50B3. When A and B are connected to a power source, GND, or the like from which a constant potential V is supplied without a circuit element therebetween as in FIGS. 50B4 and 50B5, the expression “A and B are directly connected”, “A and V are directly connected”, or “B and V are directly connected” can be used. Note that when A (or B) is connected to a constant potential V through a source and a drain of a transistor as in FIG. 50B6, the expression “A and B are directly connected” can also be used. Note that A and V or B and V are connected to each other through the source and the drain of the transistor, and thus, they cannot be regarded as being in direct connection, and the expression “A and V are indirectly connected” or “B and V are indirectly connected” can be used.

The examples of “direct connection” are described above. The specification of “direct connection” is included in the specification of “electrical connection”, for example; thus, in the case where the expression “A and B are directly connected” is used, the expression “A and B are electrically connected” can also be used.

Even when independent components are connected to each other in a circuit diagram, one component has functions of a plurality of components in some cases. For example, when part of a wiring also serves as an electrode, one conductive film has functions of both components: a function of the wiring and a function of the electrode. Thus, “connection” in this specification and the like includes in its category such a case where one conductive film has functions of a plurality of components.

In this specification and the like, a “resistor element” can be, for example, a circuit element, a wiring, or the like having a resistance higher than 0Ω. Therefore, in this specification and the like, a “resistor element” includes a wiring having a resistance, a transistor in which a current flows from the drain to the source, a diode, and a coil, for example. Thus, the term “resistor element” can be replaced with the term “resistor”, “load”, or “region having a resistance”; conversely, the term “resistor”, “load”, or “region having a resistance” can be sometimes replaced with the term “resistor element”, for example. The resistance can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. For another example, the resistance may be higher than or equal to 1Ω and lower than or equal to 1×10⁹Ω.

In the case where a wiring is used as a resistor, the resistivity is sometimes determined depending on the length of the wiring. Alternatively, a conductor with resistivity different from that of a conductor used as a wiring is sometimes used as a resistor. Alternatively, in the case where a semiconductor is used as a resistor, the resistivity of the resistor is sometimes determined by doping a semiconductor with an impurity.

In this specification and the like, a “capacitor” can be, for example, a circuit element having a capacitance higher than 0 F, a region of a wiring having a capacitance higher than 0 F, parasitic capacitance, or gate capacitance of a transistor. Therefore, a “capacitor” in this specification and the like is not limited to a circuit element that has a pair of electrodes and a dielectric sandwiched between the electrodes. The “capacitor” includes parasitic capacitance generated between wirings or gate capacitance generated between a gate and one of a source and a drain in a transistor, for example. The term “capacitor”, “parasitic capacitance”, or “gate capacitance” can be replaced with the term “capacitance”, for example; conversely, the term “capacitance” can be replaced with the term “capacitor”, “parasitic capacitance”, or “gate capacitance”, for example. The terms “pair of electrodes”, “pair of wirings”, “pair of terminals”, “pair of conductive layers”, “pair of conductors”, “pair of conductive regions”, “pair of regions”, and the like of the “capacitor” may be replaced with each other. Note that the capacitance value can be higher than or equal to 0.05 fF and lower than or equal to 10 pF, for example. For example, the capacitance value may be higher than or equal to 1 pF and lower than or equal to 10 ρF.

A transistor in this specification and the like has three terminals called a gate (also referred to as a gate terminal, a gate region, or a gate electrode), a source (also referred to as a source terminal, a source region, or a source electrode), and a drain (also referred to as a drain terminal, a drain region, or a drain electrode). The transistor has a region where a channel is formed (also referred to as a channel formation region) between the drain and the source. The transistor enables a current to flow between the source and the drain through the channel formation region. That is, the transistor enables transmission and reception of an electric signal, an interaction of potentials, or the like to occur between the source and the drain through the channel formation region. The channel formation region refers to a region through which a current mainly flows. The gate is a control terminal controlling the amount of current flowing through the channel formation region. Two terminals serving as the source and the drain are input/output terminals to and from which the current flowing through the channel formation region is input and output.

Functions of the two input/output terminals of the transistor depend on the conductivity type (n-channel type or p-channel type) of the transistor and the levels of potentials applied to the three terminals of the transistor, and one of the two terminals serves as the source and the other serves as the drain. In some cases, functions of the source and the drain are replaced with each other when the direction of current flow is changed in circuit operation, for example. Therefore, the terms “source” and “drain” can be used interchangeably in this specification and the like. In this specification and the like, the terms “one of a source and a drain” (or a first electrode or a first terminal) and “the other of the source and the drain” (or a second electrode or a second terminal) are used to describe the connection relation of a transistor.

Depending on the structure, a transistor may include a terminal called a back gate (also referred to as a back gate terminal, a back gate region, or a back gate electrode) in addition to the above three terminals. In that case, in this specification and the like, one of the gate and the back gate of the transistor may be referred to as a first gate and the other of the gate and the back gate of the transistor may be referred to as a second gate. In some cases, the terms “gate” and “back gate” can be replaced with each other in one transistor. In the case where a transistor includes three or more gates, the gates may be referred to as a first gate, a second gate, and a third gate, for example, in this specification and the like.

In this specification and the like, a transistor with a multi-gate structure having two or more gate electrodes can be used as a transistor. In the transistor with a multi-gate structure, channel formation regions are connected in series; accordingly, a plurality of transistors are connected in series. The transistor with a multi-gate structure can thus have a lower off-state current and a higher breakdown voltage (improved reliability). In the transistor with a multi-gate structure, the current between the drain and the source does not change much even if the voltage between the drain and the source changes at the time of operation in a saturation region, so that a flat slope of voltage-current characteristics can be obtained. A transistor having the voltage-current characteristics with a flat slope can achieve an ideal current source circuit or an active load having an extremely high resistance. Accordingly, the transistor having the voltage-current characteristics with a flat slope can be used to achieve a differential circuit, a current mirror circuit, or the like having excellent properties.

In this specification and the like, a single circuit element shown in a circuit diagram may include a plurality of circuit elements. For example, a single resistor shown in a circuit diagram may be two or more resistors connected to each other in series. For another example, a single capacitor shown in a circuit diagram may be two or more capacitors connected to each other in parallel. For another example, a single transistor shown in a circuit diagram may be two or more transistors which are connected to each other in series and whose gates are connected to each other. For another example, a single switch shown in a circuit diagram may be a switch including two or more transistors which are connected to each other in series or in parallel and whose gates are connected to each other.

In this specification and the like, a “node” can be referred to as a “terminal”, a “wiring”, an “electrode”, a “conductive layer”, a “conductor”, or an “impurity region” depending on the circuit structure and the device structure, for example. For example, a “terminal”, a “wiring”, or the like can be referred to as a “node”.

In this specification and the like, a “voltage” and a “potential” can be replaced with each other as appropriate. The term “voltage” refers to a potential difference from a reference potential. When the reference potential is a ground potential, for example, a “voltage” can be replaced with a “potential”. Note that the ground potential does not necessarily mean 0 V. A potential has a relative value. In other words, a potential supplied to a wiring, a potential applied to a circuit and the like, or a potential output from a circuit and the like, for example, changes depending on the reference potential.

In this specification and the like, the terms “high-level potential” (also referred to as “H potential” or “H”) and “low-level potential” (also referred to as “L potential” or “L”) do not represent a particular potential. For example, in the case where two wirings are both described as “functioning as a wiring for supplying a high-level potential”, the levels of the high-level potentials that these wirings supply are not necessarily equal to each other. Similarly, in the case where two wirings are both described as “functioning as a wiring for supplying a low-level potential”, the levels of the low-level potentials that these wirings supply are not necessarily equal to each other.

In this specification and the like, a “current” means an electric charge transfer phenomenon (electrical conduction). For example, the expression “electrical conduction of positively charged particles is caused” can be rephrased as “electrical conduction of negatively charged particles is caused in the opposite direction”. Therefore, unless otherwise specified, a “current” in this specification and the like refers to an electric charge transfer phenomenon (electrical conduction) caused by carrier movement. Examples of the carrier here include an electron, a hole, an anion, a cation, and a complex ion. Note that the type of the carrier differs between systems where a current flows (e.g., a semiconductor, a metal, an electrolyte solution, and a vacuum). The “direction of a current” in a wiring or the like, for example, refers to the direction in which a positive carrier moves, and the amount of a current is expressed as a positive value. In other words, the direction in which a negative carrier moves is opposite to the direction of a current, and the amount of negative carriers is expressed as a negative current amount. Thus, in the case where the polarity of a current (or the direction of a current) is not specified in this specification and the like, the expression “a current flows from an element A to an element B” can be replaced with the expression “a current flows from an element B to an element A”, for example. The expression “a current is input to an element A” can be replaced with the expression “a current is output from an element A”, for example,

Ordinal numbers such as “first”, “second”, and “third” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments, claims, or the like. For another example, a “first” component in one embodiment in this specification and the like can be omitted in other embodiments, claims, or the like.

In this specification and the like, terms for describing arrangement, such as “over”, “under”, “above”, and “below”, are sometimes used for convenience to describe the positional relation between components with reference to drawings, for example. The positional relation between components is changed as appropriate in accordance with the direction in which the components are described. Thus, the terms for describing arrangement used in this specification and the like can be, without limitation thereto, replaced with other terms as appropriate. For example, the expression “an insulator over (on) a top surface of a conductor” can be replaced with the expression “an insulator on a bottom surface of a conductor” when the direction of a diagram showing these components is rotated by 180°. Moreover, the expression “an insulator over (on) a top surface of a conductor” can be replaced with the expression “an insulator on a left surface (or a right surface) of a conductor” when the direction of a diagram showing these components is rotated by 90°.

The term “over” or “under” does not necessarily mean that a component is placed directly over and in contact with or directly under and in contact with another component. For example, the expression “an electrode B over an insulating layer A” does not necessarily mean that the electrode B is over and in direct contact with the insulating layer A, and can mean the case where another component is provided between the insulating layer A and the electrode B. Thus, the term “over” may be replaced with the term “above”, “on an upper side”, or “in an upper layer”, and the term “under” may be replaced with the term “below”, “on a lower side”, or “in a lower layer”, for example.

In this specification and the like, components arranged in a matrix and their positional relation are sometimes described using terms such as “row” and “column”, for example. The positional relation between components is changed as appropriate in accordance with the direction in which the components are described. Thus, for example, the terms such as “row” and “column” used in this specification and the like can be, without limitation thereto, replaced with other terms as appropriate. For example, the term “row direction” can be replaced with the term “column direction” when the direction of the diagram is rotated by 90°.

The term “overlap”, for example, in this specification and the like does not limit a state such as the stacking order of components. For example, the expression “the electrode B overlapping with the insulating layer A” is not limited to the state where the electrode B is formed over the insulating layer A. For example, the expression “the electrode B overlapping with the insulating layer A” includes the case where the electrode B is formed under the insulating layer A and the case where the electrode B is formed on the right (or left) side of the insulating layer A.

The term “adjacent” or “proximity” in this specification and the like does not necessarily mean that a component is directly in contact with another component. For example, the expression “the electrode B adjacent to the insulating layer A” does not necessarily mean that the electrode B is formed in direct contact with the insulating layer A and can mean the case where another component is provided between the insulating layer A and the electrode B.

In this specification and the like, the terms “film” and “layer”, for example, can be interchanged with each other in some cases. For example, the term “conductive layer” can be changed to the term “conductive film” in some cases. For example, the term “insulating film” can be changed into the term “insulating layer” in some cases. For example, the term “film” or “layer” can be replaced with a word not including the term in some cases. For example, the term “conductive layer” or “conductive film” can be changed into the term “conductor” in some cases. Furthermore, the term “conductor” can be changed into the term “conductive layer” or “conductive film” in some cases. For example, in some cases, the term “insulating layer” or “insulating film” can be changed into the term “insulator” in some cases. Furthermore, the term “insulator” can be changed into the term “insulating layer” or “insulating film” in some cases.

In this specification and the like, for example, the terms “electrode”, “wiring”, and “terminal” do not have functional limitations. For example, an “electrode” is used as part of a “wiring” in some cases, and vice versa. Furthermore, the term “electrode” or “wiring” includes the case where a plurality of “electrodes” or “wirings” are formed in an integrated manner, for example. For another example, a “terminal” is used as part of a “wiring” or an “electrode” in some cases, and vice versa. Furthermore, the term “terminal” includes the case where a plurality of “electrodes”, “wirings”, “terminals”, or the like are formed in an integrated manner, for example. Thus, for example, an “electrode” can be part of a “wiring” or a “terminal”. Furthermore, a “terminal” can be part of a “wiring” or an “electrode”. Moreover, the terms “electrode”, “wiring”, and “terminal” are sometimes replaced with the term “region”, for example.

In this specification and the like, for example, the term “signal line”, “power supply line”, or the like can be changed into the term “wiring” in some cases. For example, the term “potential” that is applied to a wiring can be changed into the term “signal” or the like in some cases. Inversely, for example, the term “signal” or the like can be changed into the term “potential” in some cases.

In this specification and the like, a “switch” refers to a circuit element that includes a plurality of terminals and has a function of switching (selecting) electrical continuity and discontinuity between the terminals. In other words, a switch has a function of controlling whether to make a current flow between a plurality of terminals or a function of controlling whether to cause transmission and reception of an electric signal, an interaction of potentials, or the like between a plurality of terminals, for example. For example, in the case where a switch includes two terminals and the two terminals can be regarded as being short-circuited, the switch is in a “conduction state” or an “on state”. In the case where the two terminals can be regarded as being electrically disconnected, the switch is in a “non-conduction state” or an “off state”. Note that switching to one of a conduction state and a non-conduction state or maintaining one of a conduction state and a non-conduction state is sometimes referred to as “controlling a conduction state”.

That is, a switch has a function of controlling whether a current flows therethrough or not. Alternatively, a switch has a function of selecting and changing a current path. As the switch, an electrical switch or a mechanical switch can be used, for example. That is, a switch is not limited to a particular element.

Note that as a kind of a switch, there is a switch which is normally in a non-conduction state and brought into a conduction state by controlling a conduction state; such a switch is referred to as an “A contact” in some cases. Furthermore, as another kind of a switch, there is a switch which is normally in a conduction state and brought into a non-conduction state by controlling a conduction state; such a switch is referred to as a “B contact” in some cases.

Examples of an electrical switch include a transistor (e.g., a bipolar transistor and a MOS transistor), a diode (e.g., a PN diode, a PIN diode, a Schottky diode, a metal-insulator-metal (MIM) diode, a metal-insulator-semiconductor (MIS) diode, and a diode-connected transistor), and a logic circuit in which such elements are combined. In the case where a transistor operates just as a switch, there is no particular limitation on the polarity (conductivity type) of the transistor.

An example of a mechanical switch is a switch using a microelectromechanical systems (MEMS) technology. Such a switch includes an electrode that can be moved mechanically, and its conduction state or non-conduction state is selected with movement of the electrode.

The “channel length” of a transistor in this specification and the like sometimes refers to the distance between the source and the drain in a region where the channel is formed or a region where the gate overlaps with the semiconductor (or a portion of the semiconductor where a current flows when the transistor is in an on state), for example.

The “channel width” of a transistor in this specification and the like sometimes refers to the length of a portion where the source and the drain face each other in a region where the channel is formed or a region where the gate overlaps with the semiconductor (or a portion of the semiconductor where a current flows when the transistor is in an on state), for example.

In this specification and the like, the term “substrate”, “wafer”, “die”, or the like does not limit a function of a component, for example. The terms “substrate”, “wafer”, “die”, and the like can be interchanged with each other depending on the case, for example.

In this specification and the like, the term “parallel” does not necessarily refer to the case where components are exactly parallel. Hence, for example, the term “parallel” can be replaced with the term “substantially parallel”, “roughly parallel”, “practically parallel”, or the like as appropriate. Unless otherwise specified, the term “parallel”, “substantially parallel”, “roughly parallel”, or “practically parallel” may be used in the case where the angle between two straight lines or planes is greater than or equal to −5° and less than or equal to 5°, greater than or equal to −10° and less than or equal to 10°, or greater than or equal to −30° and less than or equal to 30°. Accordingly, “parallel” sometimes means “parallel or roughly parallel”, for example. Similarly, the term “perpendicular” does not necessarily refer to the case where components are exactly perpendicular to each other. Hence, for example, the term “perpendicular” can be replaced with the term “substantially perpendicular”, “roughly perpendicular”, “practically perpendicular”, or the like as appropriate. Unless otherwise specified, the term “perpendicular”, “substantially perpendicular”, “roughly perpendicular”, or “practically perpendicular” may be used in the case where the angle between two straight lines or planes is greater than or equal to 850 and less than or equal to 95°, greater than or equal to 80° and less than or equal to 100°, or greater than or equal to 60° and less than or equal to 120°. Accordingly, “perpendicular” sometimes means “perpendicular or roughly perpendicular”, for example.

Note that in this specification and the like, the expression “level with” indicates components having the same level from a reference surface (e.g., a flat surface such as a substrate surface) in a cross-sectional view. For example, when planarization treatment is performed in a manufacturing process of a semiconductor device, the surface(s) of a single layer or a plurality of layers are exposed in some cases. In this case, the surfaces on which the planarization treatment is performed are at the same level from the reference surface. However, the surfaces of the plurality of layers on which the planarization treatment is performed are at the levels that are not exactly the same depending on a treatment apparatus, a treatment method, or a material of the surfaces, used for the planarization treatment in some cases. This case is also described with the expression “level with” in this specification and the like. For example, the expression “level with” also includes the case where two layers (here, given as a first layer and a second layer) whose levels with respect to the reference surface are different from each other are provided to have a difference between the top-surface level of the first layer and the top-surface level of the second layer of less than or equal to 20 nm. Accordingly, “level with” sometimes means “level with or roughly level with”, for example.

In this specification and the like, the expression “an end portion is aligned with another end portion” means that at least outlines of stacked layers partly overlap with each other in a top view. For example, the expression includes the case of processing the upper layer and the lower layer with use of the same mask pattern or mask patterns that are partly the same in a manufacturing process of a semiconductor device. The expression “an end portion is aligned with another end portion” also includes the case where the outlines do not completely overlap with each other; for instance, the outline of the upper layer may be positioned inside or outside the outline of the lower layer. This case is also the structure meant by the expression “an end portion is aligned with another end portion” in this specification and the like. Accordingly, “an end portion is aligned with another end portion” sometimes means “an end portion is aligned or roughly aligned with another end portion”, for example.

In this specification and the like, the terms “identical”, “the same”, “equal”, “concurrent”, “align”, “uniform” and the like (including synonyms thereof) used in describing, for example, calculation values and measurement values or in describing objects, methods, events, and the like that can be converted into calculation values or measurement values allow for a margin of error. Thus, these terms may allow for a margin of error of ±10% or ±20% unless otherwise specified. Therefore, “identical” means “identical or roughly identical”, “the same” means “the same or roughly the same”, “equal” means “equal or roughly equal”, “concurrent” means “concurrent or roughly concurrent”, “align” means “align or roughly align”, and “uniform” means “uniform or roughly uniform” in some cases.

In this specification and the like, an impurity in a semiconductor refers to, for example, an element other than the main component of the semiconductor. For example, an element with a concentration lower than 0.1 atomic % is an impurity. By containing an impurity, a semiconductor may have increased density of defect states, decreased carrier mobility, or decreased crystallinity, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen (contained also in water), lithium, sodium, silicon, boron, phosphorus, carbon, and nitrogen. Entry of an impurity may cause oxygen vacancies in an oxide semiconductor, for example.

In this specification and the like, a metal oxide means an oxide of a metal in a broad sense. Metal oxides are classified into an oxide insulator, an oxide conductor (including a transparent oxide conductor), an oxide semiconductor (also simply referred to as an OS), and the like, for example. For example, a metal oxide used as a semiconductor including a channel formation region of a transistor is referred to as an oxide semiconductor in some cases. That is, a metal oxide included in a channel formation region of a transistor that has at least one of an amplifying function, a rectifying function, and a switching function can be referred to as a metal oxide semiconductor. The term “OS transistor” can be replaced with a transistor including a metal oxide or an oxide semiconductor.

In this specification and the like, a metal oxide containing nitrogen is also called a metal oxide in some cases. In addition, a metal oxide containing nitrogen may be referred to as a metal oxynitride.

In the drawings for this specification and the like, arrows indicating the X direction, the Y direction, and the Z direction are shown in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

This application is based on Japanese Patent Application Serial No. 2024-003156 filed with Japan Patent Office on Jan. 12, 2024, Japanese Patent Application Serial No. 2024-024282 filed with Japan Patent Office on Feb. 21, 2024, and Japanese Patent Application Serial No. 2024-028509 filed with Japan Patent Office on Feb. 28, 2024, the entire contents of which are hereby incorporated by reference.

What is claimed is:

1. A semiconductor device comprising:
a driver circuit comprising a first circuit and a second circuit,
wherein the first circuit comprises a first transistor, a second transistor, and a first capacitor,
wherein the second circuit comprises a third transistor, a fourth transistor, a fifth transistor, and a second capacitor,
wherein a first terminal of the first transistor is electrically connected to a first terminal of the second transistor, a first terminal of the third transistor, a first terminal of the first capacitor, a first terminal of the second capacitor, and a first signal line,
wherein a second terminal of the first transistor is electrically connected to a second signal line,
wherein a gate of the first transistor is electrically connected to a second terminal of the first capacitor and a first wiring,
wherein a second terminal of the second transistor is electrically connected to a second wiring,
wherein a gate of the second transistor is electrically connected to a third wiring,
wherein a second terminal of the third transistor is electrically connected to a first terminal of the fourth transistor, a gate of the fourth transistor, and a third signal line,
wherein a gate of the third transistor is electrically connected to a second terminal of the fourth transistor, a first terminal of the fifth transistor, and a second terminal of the second capacitor,
wherein a second terminal of the fifth transistor is electrically connected to a fourth wiring, and
wherein a gate of the fifth transistor is electrically connected to the second signal line.

2. The semiconductor device according to claim 1,
wherein the first circuit is configured to supply a first potential from the second signal line to the first signal line, and
wherein the second circuit is configured to supply a second potential from the third signal line to the first signal line in a period different from a period in which the first potential is supplied.

3. The semiconductor device according to claim 1, wherein a channel width of the third transistor is larger than a channel width of the fourth transistor.

4. The semiconductor device according to claim 1, wherein a channel width of the first transistor is larger than a channel width of the fifth transistor.

5. The semiconductor device according to claim 1, wherein a width of the third signal line is larger than a width of the second signal line.

6. The semiconductor device according to claim 2, further comprising:
a pixel,
wherein the pixel comprises a sixth transistor and a functional element,
wherein a gate of the sixth transistor is electrically connected to the first signal line,
wherein a first terminal of the sixth transistor is electrically connected to the functional element,
wherein a second terminal of the sixth transistor is electrically connected to a fourth signal line, and
wherein the first potential and the second potential are each capable of turning on the sixth transistor.

7. The semiconductor device according to claim 6, wherein the functional element is a liquid crystal element.

8. A semiconductor device comprising:
a driver circuit comprising a first circuit and a second circuit,
wherein the first circuit comprises a first transistor, a second transistor, and a first capacitor,
wherein the second circuit comprises a third transistor, a fourth transistor, a fifth transistor, and a second capacitor,
wherein a first terminal of the first transistor is electrically connected to a first terminal of the second transistor, a first terminal of the third transistor, a first terminal of the first capacitor, a first terminal of the second capacitor, and a first signal line,
wherein a second terminal of the first transistor is electrically connected to a second signal line,
wherein a gate of the first transistor is electrically connected to a second terminal of the first capacitor and a first wiring,
wherein a second terminal of the second transistor is electrically connected to a second wiring,
wherein a gate of the second transistor is electrically connected to a third wiring,
wherein a second terminal of the third transistor is electrically connected to a first terminal of the fourth transistor, a gate of the fourth transistor, and a third signal line,
wherein a gate of the third transistor is electrically connected to a second terminal of the fourth transistor, a first terminal of the fifth transistor, and a second terminal of the second capacitor,
wherein a second terminal of the fifth transistor is electrically connected to a fourth wiring, and
wherein a gate of the fifth transistor is electrically connected to the gate of the first transistor.

9. The semiconductor device according to claim 8,
wherein the first circuit is configured to supply a first potential from the second signal line to the first signal line, and
wherein the second circuit is configured to supply a second potential from the third signal line to the first signal line in a period different from a period in which the first potential is supplied.

10. The semiconductor device according to claim 8, wherein a channel width of the third transistor is larger than a channel width of the fourth transistor.

11. The semiconductor device according to claim 8, wherein a channel width of the first transistor is larger than a channel width of the fifth transistor.

12. The semiconductor device according to claim 8, wherein a width of the third signal line is larger than a width of the second signal line.

13. The semiconductor device according to claim 9, further comprising:
a pixel,
wherein the pixel comprises a sixth transistor and a functional element,
wherein a gate of the sixth transistor is electrically connected to the first signal line,
wherein a first terminal of the sixth transistor is electrically connected to the functional element,
wherein a second terminal of the sixth transistor is electrically connected to a fourth signal line, and
wherein the first potential and the second potential are each capable of turning on the sixth transistor.

14. The semiconductor device according to claim 13, wherein the functional element is a liquid crystal element.

15. A semiconductor device comprising:
a driver circuit comprising m first circuits and m second circuits,
wherein the m first circuits each comprise a first transistor, a second transistor, and a first capacitor,
wherein the m second circuits each comprise a third transistor, a fourth transistor, a fifth transistor, and a second capacitor,
wherein a first terminal of the first transistor is electrically connected to a first terminal of the second transistor, a first terminal of the third transistor, a first terminal of the first capacitor, a first terminal of the second capacitor, and a first signal line,
wherein a second terminal of the first transistor is electrically connected to a second signal line,
wherein a gate of the first transistor is electrically connected to a second terminal of the first capacitor and a first wiring,
wherein a second terminal of the second transistor is electrically connected to a second wiring,
wherein a gate of the second transistor is electrically connected to a third wiring,
wherein a second terminal of the third transistor is electrically connected to a first terminal of the fourth transistor, a gate of the fourth transistor, and a third signal line,
wherein a gate of the third transistor is electrically connected to a second terminal of the fourth transistor, a first terminal of the fifth transistor, and a second terminal of the second capacitor,
wherein a second terminal of the fifth transistor is electrically connected to a fourth wiring,
wherein the m first circuits are configured to sequentially supply a first potential to the m first signal lines,
wherein the m second circuits are configured to concurrently supply a second potential to the m first signal lines, in a period different from a period in which the first potential is sequentially supplied, and
wherein m is an integer greater than or equal to two.

16. The semiconductor device according to claim 15, wherein a gate of the fifth transistor is electrically connected to the second signal line.

17. The semiconductor device according to claim 15, wherein a gate of the fifth transistor is electrically connected to the gate of the first transistor.

18. The semiconductor device according to claim 15, wherein a channel width of the third transistor is larger than a channel width of the fourth transistor.

19. The semiconductor device according to claim 15, wherein a channel width of the first transistor is larger than a channel width of the fifth transistor.

20. The semiconductor device according to claim 15, wherein a width of the third signal line is larger than a width of the second signal line.

21. The semiconductor device according to claim 15, further comprising:
m pixels,
wherein the m pixels each comprise a sixth transistor and a functional element,
wherein a gate of the sixth transistor is electrically connected to the first signal line,
wherein a first terminal of the sixth transistor is electrically connected to the functional element,
wherein a second terminal of the sixth transistor is electrically connected to a fourth signal line, and
wherein the first potential and the second potential are each capable of turning on the sixth transistor.

22. The semiconductor device according to claim 21, wherein the functional element is a liquid crystal element.
